(19) United States
(12) Patent Application Publication
(10) Pub. No.: US 2012/0064461 A1
(43) Pub. Date: Mar. 15, 2012

(54) MOVABLE BODY APPARATUS, EXPOSURE APPARATUS, DEVICE MANUFACTURING METHOD, FLAT-PANEL DISPLAY MANUFACTURING METHOD, AND OBJECT EXCHANGE METHOD

(75) Inventor: Yasuo AOKI, Zushi-shi (JP)

(73) Assignee: NIKON CORPORATION, Tokyo (JP)

(21) Appl. No.: 13/228,115

(22) Filed: Sep. 8, 2011

Related U.S. Application Data
(60) Provisional application No. 61/382,141, filed on Sep. 13, 2010.
(60) Provisional application No. 61/382,130, filed on Sep. 13, 2010.
(60) Provisional application No. 61/382,114, filed on Sep. 13, 2010.
(60) Provisional application No. 61/382,077, filed on Sep. 13, 2010.

(51) Int. Cl. G03F 7/20; G03B 27/00; B65G 49/05

(52) U.S. Cl. 430/320; 414/749.1; 414/800; 430/325; 355/18

(57) ABSTRACT

On a +X side of a first air floating unit which supports a substrate subject to carry-out, a second air floating unit which supports a substrate subject to carry-in is placed, and a third air floating unit is placed tilted in a θy direction below the second air floating unit. After the first air floating unit has been tilted in the θy direction and the substrate has been carried from above the first air floating unit onto the third air floating unit, the first air floating unit is made horizontal and another substrate is carried from above the second air floating unit onto the first air floating unit. Specifically, a carry-in path and a carry-out path of the substrate with respect to the first air floating unit are different. Accordingly, exchange of the substrate above the first air floating unit can be performed quickly.

### CROSS-REFERENCE TO RELATED APPLICATIONS

This non-provisional application claims the benefit of Provisional Application No. 61/382,114, filed Sep. 13, 2010, Provisional Application No. 61/382,130, filed Sep. 13, 2010, Provisional Application No. 61/382,141, filed Sep. 13, 2010, and Provisional Application No. 61/382,077 filed Sep. 13, 2010, the disclosures of which are hereby incorporated herein by reference in their entirety.

### BACKGROUND OF THE INVENTION

1. Field of the Invention

The present invention relates to movable body apparatuses, exposure apparatuses, device manufacturing methods, flat-panel display manufacturing methods, and object exchange methods, and more particularly to a movable body apparatus equipped with a movable body which is movable in a predetermined range within a predetermined two-dimensional plane parallel to a horizontal plane along with an object, an exposure apparatus equipped with the movable body apparatus, a device manufacturing method using the exposure apparatus, a flat-panel display manufacturing method which uses the exposure apparatus, and an object exchange method on an object supporting device which supports the object from below.

2. Description of the Background Art

Conventionally, in a lithography process for manufacturing electron devices (microdevices) such as liquid crystal display elements or semiconductor devices (integrated circuits or the like), an exposure apparatus is used such as a projection exposure apparatus by a step-and-scan method that, while synchronously moving a mask or a reticle (hereinafter, generically referred to as a “mask”) and an object such as a glass plate or a wafer (hereinafter, generically referred to as a “substrate”) along a predetermined scanning direction (scan direction), transfers a pattern formed on the mask onto the substrate via a projection optical system (refer to, for example, U.S. Patent Application Publication No. 2010/0018950).

In this type of the exposure apparatus, the substrate subject to exposure is carried in onto a substrate stage by a predetermined substrate exchange device, and after exposure processing has been completed, the substrate is carried out from the substrate stage by the substrate exchange device. Then, onto the substrate stage, another substrate is carried in by the substrate exchange device. In the exposure apparatus, the exposure processing is consecutively performed to a plurality of substrates by repeatedly performing the carry-in and the carry-out of the substrate as described above. Consequently, when the plurality of substrates are consecutively exposed, it is desirable to quickly perform the carry-in and the carry-out of the substrate onto/from the substrate stage.

### SUMMARY OF THE INVENTION

According to a first aspect of the present invention, there is provided a movable body apparatus, comprising: a movable body which holds an edge of an object, and is movable with the object at least in a predetermined range within a predetermined two-dimensional plane parallel to a horizontal plane; an object support device which has a first member having a surface whose tilt angle with respect to the two-dimensional plane is changeable in at least two steps including zero degrees, and supports the object moving with the movable body in the predetermined range from below; a first support device which has a surface forming a first movement plane that forms a first angle with respect to the two dimensional plane together with the surface of the first member in a first state where the surface forms the first angle with respect to the two-dimensional plane, and can support the object from below; a second support device which has a surface forming a second movement plane that forms a second angle with respect to the two dimensional plane together with the surface of the first member in a second state where the surface forms the second angle with respect to the two-dimensional plane, and can support the object from below; and a carrier system including a first carrier system which moves the object along the first movement plane and a second carrier system which moves the object along the second movement plane, wherein the object is carried out from above the object support device by one of the first and second carrier systems, and another object is carried in onto the object support device by the other of the first and second carrier systems. The first angle and the second angle, here, can be different, or the same.

According to this apparatus, the edge of the object is held by the movable body within the predetermined range of the predetermined two-dimensional plane, and is movable along the predetermined two-dimensional plane in a state supported from below by the object support device. Further, the object is carried out from above the object support device by moving along one of the first and second movable plane, and another object is carried in onto the object support device by moving along the other of the first and second movement plane. In other words, the carry-in path and the carry-out path of the object with respect to the object support device are different. Accordingly, the exchange of the object above the object support device can be performed quickly.

According to a second aspect of the present invention, there is provided a second movable body apparatus, comprising: a movable body which holds an edge of an object, and is movable with the object at least in a predetermined range within a predetermined two-dimensional plane parallel to a horizontal plane; an object support device which has a first member whose surface is parallel to the two-dimensional plane, and supports the object moving with the movable body in the predetermined range from below; a first support device and a second support device that have a surface parallel to the two-dimensional plane and can support the object, respectively, and at least one of the first movable device and the second movable device is relatively movable with respect to the first member in a direction intersecting the two-dimensional plane; and a carrier system including a first carrier system which moves the object along a first movement plane including the surface of the first member and the surface of the first support device, and a second carrier system which moves the object along a second movement plane including the surface of the first member and the surface of the second support device, wherein the object is carried out from above the object support device by one of the first and second carrier systems, and another object is carried in onto the object support device by the other of the first and second carrier systems.

According to this apparatus, the edge of the object is held by the movable body within the predetermined range of the predetermined two-dimensional plane, and is movable along the predetermined two-dimensional plane in a state supported from below by the object support device. Further, the object is carried out from above the object support device by moving along one of the first and second movable plane, and another object is carried in onto the object support device by moving along the other of the first and second movement plane. In other words, the carry-in path and the carry-out path of the object with respect to the object support device are different. Accordingly, the exchange of the object above the object support device can be performed quickly.

According to a third aspect of the present invention, there is provided a third movable body apparatus, comprising: a movable body which holds an edge of an object, and is movable with the object at least in a predetermined range within a predetermined two-dimensional plane parallel to a horizontal plane; an object support device which supports the object moving with the movable body in the predetermined range from below; a first support device which forms a first movement plane at least with a part of the object support device; a second support device which forms a second movement plane at least with a part of the object support device; and a carrier system including a first carrier system which moves the object along the first movement plane and a second carrier system which moves the object along the second movement plane, wherein the object is carried out from above the object support device by one of the first and second carrier systems, and another object is carried in onto the object support device by the other of the first and second carrier systems at least partially concurrently, and in at least one of the time of the carry-out operation of the object and the time of the carry-in operation of the another object, the movable body and at least a part of the object support device moves relatively.

According to this apparatus, the edge of the object is held by the movable body within the predetermined range of the predetermined two-dimensional plane, and is movable along the predetermined two-dimensional plane in a state supported from below by the object support device. Further, the object is carried out from above the object support device by moving along one of the first and second movable plane, and another object is carried in onto the object support device by moving along the other of the first and second movement plane. In other words, the carry-in path and the carry-out path of the object with respect to the object support device are different. Accordingly, the exchange of the object above the object support device can be performed quickly.

According to a fourth aspect of the present invention, there is provided a fourth movable body apparatus, comprising: a movable body which holds an edge of an object, and is movable with the object at least in a predetermined range within a predetermined two-dimensional plane parallel to a horizontal plane; an object support device which has a surface opposing a lower surface of the object, and supports the object using the surface while moving with the movable body in the predetermined range from below; a first support device which can support the object from below, having a surface that forms a first movement plane parallel to the two-dimensional plane along with the surface of the object support device; a second support device which can support the object from below, having a surface that forms a second movement plane parallel to the two-dimensional plane along with the surface of the object support device; and a carrier system including a first carrier system which moves the object along the first movement plane, and a second carrier system which moves the object along the second movement plane, wherein the object is carried out from above the object support device by one of the first and second carrier systems, and another object is carried in onto the object support device by the other of the first and second carrier systems.

According to this apparatus, the edge of the object is held by the movable body within the predetermined range of the predetermined two-dimensional plane, and is movable along the predetermined two-dimensional plane in a state supported from below by the object support device. Further, the object is carried out from above the object support device by moving along one of the first and second movable plane, and another object is carried in onto the object support device by moving along the other of the first and second movement plane. In other words, the carry-in path and the carry-out path of the object with respect to the object support device are different . Accordingly, the exchange of the object above the object support device can be performed quickly.

According to a fifth aspect of the present invention, there is provided a first exposure apparatus, comprising: any one of the first to fourth movable body apparatus which further comprises an adjustment device which is placed within the predetermined range, and adjusts a position of a part of the object in a direction intersecting the two dimensional plane while holding the part of the object, and a patterning device which irradiates an energy beam on a part of the object held by the adjustment device and forms a predetermined pattern on the object.

According to a sixth aspect of the present invention, there is provided a second exposure apparatus that exposes an object by irradiating an energy beam, the apparatus comprising: a movable body which holds an edge of the object, and is movable with the object at least in a predetermined range within a predetermined two-dimensional plane parallel to a horizontal plane; an object support device which has a first member having a surface whose tilt angle with respect to the two-dimensional plane is changeable in at least two steps including zero degrees, and supports the object moving with the movable body in the predetermined range from below; a first support device which has a surface forming a first movement plane that forms a first angle with respect to the two dimensional plane together with the surface of the first member in a first state where the surface forms the first angle with respect to the two-dimensional plane, and can support the object from below; a second support device which has a surface forming a second movement plane that forms a second angle with respect to the two dimensional plane together with the surface of the first member in a second state where the surface forms the second angle with respect to the two-dimensional plane, and can support the object from below; a carrier system including a first carrier system which moves the object along the first movement plane and a second carrier system which moves the object along the second movement plane; and a patterning device which forms a predetermined pattern by irradiating an energy beam on the object, wherein the object is carried out from above the object support device by one of the first and second carrier systems, and another object is carried in onto the object support device by the other of the first and second carrier systems.

According to a seventh aspect of the present invention, there is provided a third exposure apparatus that exposes an object by irradiating an energy beam, the apparatus comprising: a movable body which holds an edge of the object, and is movable with the object at least in a predetermined range within a predetermined two-dimensional plane parallel to a horizontal plane; an object support device which has a first member whose surface is parallel to the two-dimensional plane, and supports the object moving with the movable body in the predetermined range from below; a first support device and a second support device that have a surface parallel to the two-dimensional plane and can support the object, respectively, and at least one of the first movable device and the second movable device is relatively movable with respect to the first member in a direction intersecting the two-dimensional plane; and a carrier system including a first carrier system which moves the object along a first movement plane including the surface of the first member and the surface of the first support device, and a second carrier system which moves the object along a second movement plane including the surface of the first member and the surface of the second support device, and a patterning device which forms a predetermined pattern by irradiating an energy beam on the object, wherein the object is carried out from above the object support device by one of the first and second carrier systems, and another object is carried in onto the object support device by the other of the first and second carrier systems.

According to an eighth aspect of the present invention, there is provided a fourth exposure apparatus that exposes an object by irradiating an energy beam, the apparatus comprising: a movable body which holds an edge of the object, and is movable with the object at least in a predetermined range within a predetermined two-dimensional plane parallel to a horizontal plane; an object support device which supports the object moving with the movable body in the predetermined range from below; a first support device which forms a first movement plane with at least a part of the object support device; a second support device which forms a second movement plane with at least a part of the object support device; a carrier system including a first carrier system which moves the object along the first movement plane and a second carrier system which moves the object along the second movement plane; and a patterning device which forms a predetermined pattern by irradiating an energy beam on the object, wherein the object is carried out from above the object support device by one of the first and second carrier systems, and with the carry-out of the object, another object is carried in onto the object support device by the other of the first and second carrier systems at least partially concurrently, and in at least one of the time of the carry-out operation of the object and the time of the carry-in operation of the another object, the movable body and at least a part of the object support device moves relatively.

According to a ninth aspect of the present invention, there is provided a fifth exposure apparatus that exposes an object by irradiating an energy beam, the apparatus comprising: a movable body which holds an edge of the object, and is movable with the object at least in a predetermined range within a predetermined two-dimensional plane parallel to a horizontal plane; an object support device which has a surface opposing a lower surface of the object, and supports the object using the surface while moving with the movable body in the predetermined range from below; a first support device which can support the object from below, having a surface that forms a first movement plane parallel to the two-dimensional plane along with the surface of the object support device; a second support device which can support the object from below, having a surface that forms a second movement plane parallel to the two-dimensional plane along with the surface of the object support device; and a carrier system including a first carrier system which moves the object along the first movement plane and a second carrier system which moves the object along the second movement plane; and a patterning device which forms a predetermined pattern by irradiating an energy beam on the object, wherein the object is carried out from above the object support device by one of the first and second carrier systems, and another object is carried in onto the object support device by the other of the first and second carrier systems.

According to a tenth aspect of the present invention, there is provided a device manufacturing method, comprising exposing the object using any one of the first and fifth exposure apparatuses described above; and developing the object that has been exposed. In this case, when a substrate used for manufacturing a flat panel display is exposed as an object, there is provided a flat panel display manufacturing method.

According to an eleventh aspect of the present invention, there is provided a first object exchange method, comprising: making a movable body which is movable along a predetermined two-dimensional plane parallel to a horizontal plane hold an edge of an object supported from below by an object support device; making the object be located above a first member that the object support device has, using the movable body; setting the first member to a first state in which a surface of the first member forms a first angle with respect to the two-dimensional plane; carrying out the object from above the object support device along a first movement plane which forms the first angle with respect to the two-dimensional plane including the surface of the first member set to the first state; setting the first member to a second state in which the surface forms a second angle with respect to the two-dimensional plane; and carrying in another object onto the object support device along a second movement plane which forms the second angle with respect to the two-dimensional plane including the surface of the first member set to the second state.

According to a twelfth aspect of the present invention, there is provided a second object exchange method, comprising: making a movable body which is movable along a predetermined two-dimensional plane parallel to a horizontal plane, hold an edge of an object supported from below by an object support device that has a first member whose surface is parallel to the two-dimensional plane and is movable in an intersecting direction with the two-dimensional plane; making the object be located above the first member which is at a first position using the movable body; carrying out the object from above the object support device along a horizontal plane including the surface of the first member located at one of the first position and a second position distanced apart in the intersecting direction with the first position; and carrying in another object onto the object support device along a horizontal plane including the surface of the first member located at a third position located distanced apart in the intersecting direction with the first position. The second position and the third position, here, can be different, or the same.

According to a thirteenth aspect of the present invention, there is provided a third object exchange method, comprising: making a movable body which is movable along a predetermined two-dimensional plane parallel to a horizontal plane, hold an edge of an object supported from below by an object support device that has a first member whose surface is parallel to the two-dimensional plane and is movable in an intersecting direction with the two-dimensional plane; making the object be located above the first member which is at a first position using the movable body; carrying out the object from above the object support device along a horizontal plane including the surface of the first member located at a second position distanced apart in the intersecting direction with the first position; and carrying in another object onto the object support device along a horizontal plane including the surface of the first member located at one of the first position and a third position located distanced apart in the intersecting direction with the first position. The second position and the third position, here, can be different, or the same.

According to a fourteenth aspect of the present invention, there is provided a fourth object exchange method, comprising: making a movable body which is movable along a predetermined two-dimensional plane parallel to a horizontal plane, hold an edge of an object supported from below by an object support device that has a surface opposing a lower surface of the object and is parallel to the horizontal plane; making the object move along the surface of the object support device using the movable body; carrying out the object from above the object support device by making the object move on a first path which is along the surface of the object support device; and carrying in another object onto the object support device by making the another object move on a second path which is different from the first path along the surface of the object support device.

According to a fifteenth aspect of the present invention, there is provided a fifth object exchange method, comprising: making a movable body which is movable along a predetermined two-dimensional plane parallel to a horizontal plane hold an edge of an object supported from below by an object support device that has a surface opposable to a lower surface of the object and is parallel to the horizontal plane; making the object be located on the surface of the object support device using the movable body; positioning a surface of a first support member that can support the object from below on a horizontal plane including the surface of the object support device; carrying out the object from above the object support device onto the first support device along a horizontal plane including the surface of the object support device and the surface of the first support device; positioning a surface of a second support member that supports another object from below on a horizontal plane including the surface of the object support device; and carrying in the another object from above the second support device onto the object support device along a horizontal plane including the surface of the second support device and the surface of the object support device.

### BRIEF DESCRIPTION OF THE DRAWINGS

In the accompanying drawings;

FIG. 1 is a view that schematically shows a configuration of a liquid crystal exposure apparatus related to a first embodiment;

FIG. 2 is a planar view of a substrate stage device which the liquid crystal exposure apparatus of FIG. 1 has;

FIG. 3 is a side view of a fixed point stage which the substrate stage device of FIG. 2 has (a sectional view of line A-A in FIG. 2),

FIG. 4A is a planar view of a substrate holding frame that the liquid crystal exposure apparatus related to the first embodiment has, and FIG. 4B is a side view that shows a drive unit to drive the substrate holding frame (a sectional view of line B-B in FIG. 4A);

FIGS. 5A to 5C are views (Nos. 1 to 3) to explain an operation of the substrate holding frame that the liquid crystal exposure apparatus related to the first embodiment has;

FIG. 6A is a side view of a substrate exchanging device which the liquid crystal exposure apparatus related to the first embodiment has, and FIG. 68 is a view that shows a substrate feeding device which the substrate exchanging device has;

FIG. 7 is a block diagram that shows an input/output relation of a main controller, which centrally configures a control system of an exposure apparatus related to a first embodiment;

FIGS. 8A to 8C are views (Nos. 1 to 3) that show the substrate stage device at the time of step-and-scan operation of the liquid crystal exposure apparatus related to the first embodiment;

FIGS. 9A to 9D are views (Nos. 1 to 4) used to explain an operation at the time of substrate exchange of the substrate exchanging device which liquid crystal exposure apparatus related to the first embodiment has;

FIG. 10 is a planar view of the substrate stage device corresponding to FIG. 9D;

FIGS. 11A to 11E are views (Nos. 1 to 5) to explain an operation at the time of substrate exchange of the substrate exchanging device which the liquid crystal exposure apparatus related to the second embodiment has;

FIG. 12 is a planar view of the substrate holding frame which the liquid crystal exposure apparatus related to the third embodiment has;

FIGS. 13A to 13C are views (Nos. 1 to 3) to explain an operation at the time of substrate exchange of the substrate exchanging device which the liquid crystal exposure apparatus related to the third embodiment has;

FIGS. 14A to 14C are views (Nos. 4 to 6) to explain an operation at the time of substrate exchange of the substrate exchanging device which the liquid crystal exposure apparatus related to the third embodiment has;

FIGS. 15A and 15B are views (Nos. 1 and 2) to explain an operation at the time of substrate exchange of the substrate exchanging device which the liquid crystal exposure apparatus related to the fourth embodiment has;

FIG. 16 is a view that schematically shows a configuration of a liquid crystal exposure apparatus related to a fifth embodiment;

FIG. 17 is a planar view of a substrate stage device which the liquid crystal exposure apparatus of FIG. 16 has;

FIG. 18 is a planar view of a substrate holding frame that the liquid crystal exposure apparatus related to the fifth embodiment has;

FIGS. 19A to 19C are views (Nos. 1 to 3) to explain an operation of the substrate holding frame that the liquid crystal exposure apparatus related to the fifth embodiment has;

FIG. 20A. is a side view of the substrate exchanging device which the liquid crystal exposure apparatus related to the fifth embodiment has, and FIG. 20B is a view that shows a substrate feeding device which the substrate exchanging device has;

FIGS. 21A to 21D are views (Nos. 1 to 4) to explain an operation at the time of substrate exchange of the substrate exchanging device which the liquid crystal exposure apparatus related to the fifth embodiment has;

FIG. 22 is a planar view of the substrate stage device corresponding to FIG. 21D;

FIGS. 23A to 23C are views (Nos. 1 to 3) to explain an operation at the time of substrate exchange of the substrate exchanging device which the liquid crystal exposure apparatus related to the sixth embodiment has;

FIGS. 24A and 24B are views (Nos. 1 and 2) to explain an operation at the time of substrate exchange of the substrate exchanging device which the substrate exchanging device related to the seventh embodiment has;

FIGS. 25A to 25C are views (Nos. 1 to 3) to explain an operation at the time of substrate exchange of the substrate exchanging device related to a modified example;

FIG. 26 is a view that schematically shows a configuration of a liquid crystal exposure apparatus related to an eighth embodiment;

FIG. 27 is a planar view of a substrate stage device which the liquid crystal exposure apparatus of FIG. 26 has;

FIGS. 28A to 28C are views (Nos. 1 to 3) to explain an operation of the substrate holding frame that the liquid crystal exposure apparatus related to the eighth embodiment has;

FIGS. 29A and 29B are side views of the substrate exchanging device which the liquid crystal exposure apparatus related to the eighth embodiment has;

FIGS. 30A to 30D are views (Nos. 1 to 4) to explain an operation at the time of substrate exchange of the substrate exchanging device which the liquid crystal exposure apparatus related to the eighth embodiment has;

FIGS. 31A to 31E are views (Nos. 1 to 5) to explain an operation at the time of substrate exchange of the substrate exchanging device which the substrate exchanging device related to the ninth embodiment has;

FIG. 32A is a planar view of a substrate holding frame that the liquid crystal exposure apparatus related to the tenth embodiment has, and FIGS. 32B and 32C are views (Nos. 1 and 2) to explain an operation at the time of substrate exchange of the substrate exchanging device which the liquid crystal exposure apparatus related to the tenth embodiment has;

FIGS. 33A and 33B are views (Nos. 1 and 2) to explain an operation at the time of substrate exchange of the substrate exchanging device which the liquid crystal exposure apparatus related to the eleventh embodiment has;

FIG. 34 is a view that schematically shows a configuration of a liquid crystal exposure apparatus related to a twelfth embodiment;

FIG. 35 is planar view of the substrate stage device and the substrate exchanging device which the liquid crystal exposure apparatus of FIG. 34 has;

FIG. 36 is a side view (a sectional view of line C-C in FIG. 35) of the fixed point stage which the substrate stage device of FIG. 35 has,

FIG. 37A is a planar view of a substrate holding frame that the liquid crystal exposure apparatus related to the twelfth embodiment has, and FIG. 37B is a side view (a sectional view of line D-D in FIG. 37A) that shows a drive unit to drive the substrate holding frame;

FIGS. 38A to 38C are views (Nos. 1 to 3) to explain an operation of the substrate holding frame that the liquid crystal exposure apparatus related to the twelfth embodiment has;

FIGS. 39A and 39B are side views of the substrate carry-out device which the liquid crystal exposure apparatus related to the twelfth embodiment has;

FIGS. 40A to 40C are views (Nos. 1 to 3) to explain an operation at the time of substrate exchange of the substrate exchanging device which the liquid crystal exposure apparatus related to the twelfth embodiment has;

FIGS. 41A to 41D are views (Nos. 1 to 4) to explain an operation at the time of substrate exchange of the substrate exchanging device which the liquid crystal exposure apparatus related to the thirteenth embodiment has;

FIGS. 42A and 42B are views (Nos. 1 and 2) to explain an operation at the time of substrate exchange of the substrate exchanging device and the substrate stage device which the liquid crystal exposure apparatus related to the fourteenth embodiment has; and

FIGS. 43A and 43B are views (Nos. 1 and 2) to explain an operation at the time of substrate exchange of the substrate exchanging device and the substrate stage device related to a modified example of the twelfth embodiment.

### DESCRIPTION OF THE EMBODIMENTS

### First Embodiment

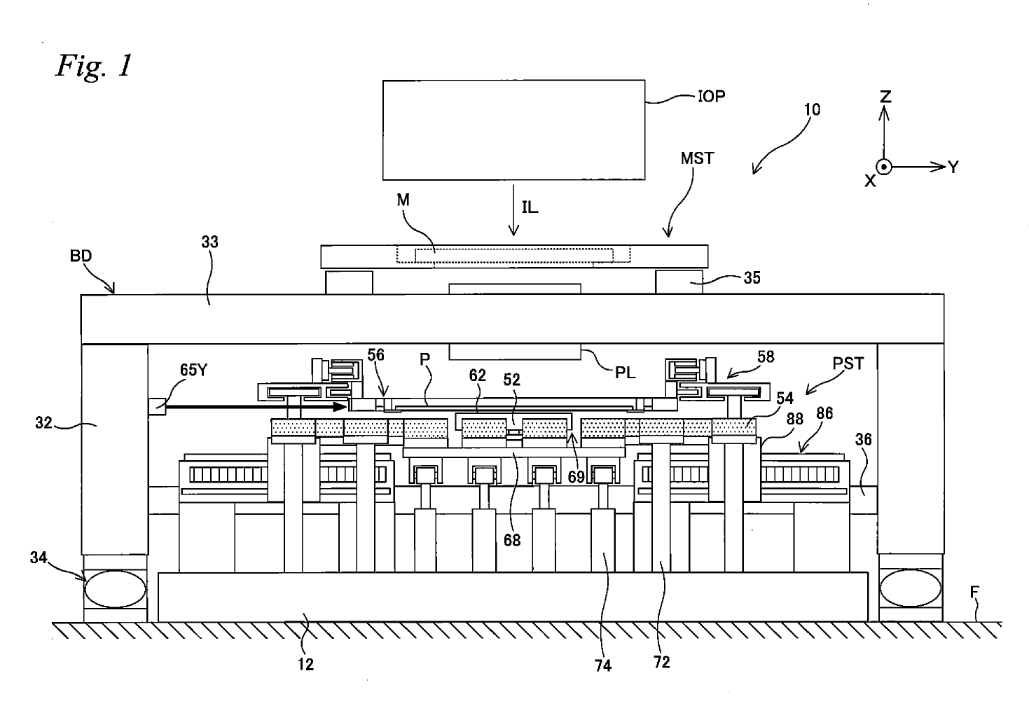

A first embodiment of the present invention is described below, with reference to FIGS. 1 to 10.

FIG. 1 schematically shows a configuration of a liquid crystal exposure apparatus 10 related to the first embodiment. Liquid crystal exposure apparatus 10 is a projection exposure apparatus by a step-and-scan method, or a so-called scanner in which a rectangular glass substrate P (hereinafter, simply referred to as a substrate P) that is used in a liquid crystal display device (flat panel display) serves as an exposure subject. The liquid crystal exposure apparatus related to each of the embodiments from the second embodiment onward described below are also the same.

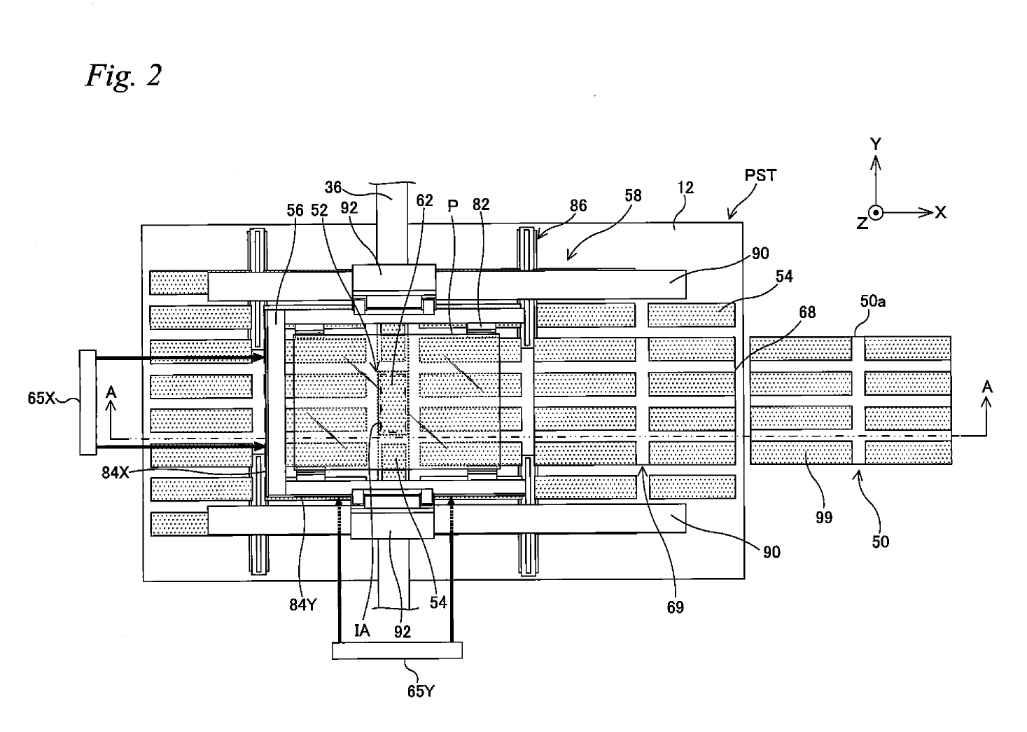

As shown in FIG. 1, liquid crystal exposure apparatus 10 is equipped with an illumination system IOP, a mask stage MST that holds a mask M, a projection optical system PL, a body BD on which mask stage MST described above and projection optical system PL and the like are mounted, a substrate stage device PST that holds a substrate P, a substrate exchanging device 50 (not illustrated in FIG. 1, see FIG. 2), and their control system and the like. In the description below, the explanation is given assuming that a direction in which mask M and substrate P are scanned relative to projection optical system PL, respectively, during exposure is an X-axis direction, a direction orthogonal to the X-axis direction within a horizontal plane is a Y-axis direction, and a direction orthogonal to the X-axis and the Y-axis is a Z-axis direction, and rotational (tilt) directions around the X-axis, Y-axis and Z-axis are θx, θy and θz directions, respectively.

Illumination system IOP is configured similar to the illumination system that is disclosed in, for example, U.S. Pat. No. 6,552,775 and the like. More specifically, illumination system IOP irradiates mask M with a light emitted from a light source that is not illustrated (e.g. a mercury lamp), as an illumination light for exposure (illumination light) IL, via a reflection mirror, a dichroic mirror, a shutter, a wavelength selecting filter, various types of lenses and the like, which are not illustrated. As illumination light IL, for example, a light such as an i-line (with a wavelength of 365 nm), a g-line (with a wavelength of 436 nm) or an h-line (with a wavelength of 405 nm) (or a synthetic light of the i-line, the g-line and the h-line described above) is used. Further, the wavelength of illumination light IL can be appropriately switched by the wavelength selecting filter, for example, according to the required resolution.

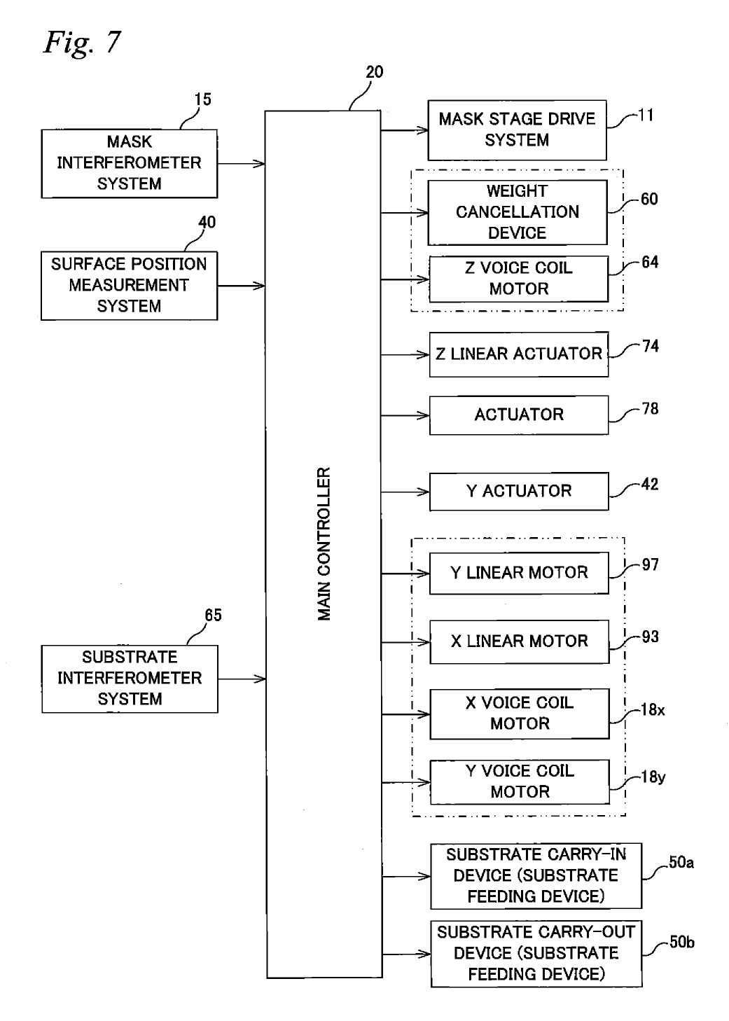

On mask stage MST, mask M having a pattern surface (the lower surface in FIG. 1) on which a circuit pattern and the like are formed is fixed by, for example, vacuum suction. Mask stage MST is mounted on a pair of mask stage guides 35 fixed on an upper surface of a barrel surface plate 33 which is a part of body BD to be described later, in a non-contact manner, for example, via an air bearing which is not illustrated. Mask stage MST is driven with predetermined strokes in a scanning direction (the X-axis direction) and also is finely driven in each of the Y-axis direction and the θz direction as needed by a mask stage driving system (not illustrated in FIG. 1, refer to FIG. 7) that includes, for example, a linear motor. Positional information (including rotation information in the θz direction) in the XY plane of mask stage MST is measured by a mask interferometer system 15 (refer to FIG. 7) that includes a laser interferometer.

Projection optical system PL is supported below mask stage MST in FIG. 1, by a barrel surface plate 33. Projection optical system PL has a configuration similar to the projection optical system disclosed in, for example, U.S. Pat. No. 6,552,775. More specifically, projection optical system PL includes a plurality of projection optical systems (multi-lens projection optical systems) whose projection areas, where a pattern image of mask M is projected, are placed in a zigzag shape, and functions equivalently to a projection optical system that has a single image field with a rectangular shape whose longitudinal direction is in the Y-axis direction. In the embodiment, as each of the plurality of projection optical systems, for example, a projection optical system that is a both-side telecentric equal-magnification system that forms an erected normal image is used. In the description below, the plurality of projection areas placed in a zigzag shape of projection optical system PL are referred to as an exposure area IA (refer to FIG. 2) as a whole.

Therefore, when an illumination area on mask M is illuminated with illumination light IL from illumination system IOP, by illumination light IL that has passed through mask M whose pattern surface is placed substantially coincident with a first plane (object plane) of projection optical system PL, a projected image (partial erected image) of a circuit pattern of mask M within the illumination area is formed on an irradiation area (exposure area) of illumination light IL, which is conjugate to the illumination area on substrate P placed on a second plane (image plane) side of projection optical system PL and whose surface is coated with a resist (sensitive agent), via projection optical system PL. Then, by moving mask M relative to the illumination area (illumination light IL) in the scanning direction (X-axis direction) and also moving substrate P relative to an exposure area (illumination light IL) in the scanning direction (X-axis direction) by a synchronous drive of mask stage MST and a substrate holding frame 56 whose configuration will be described later on that configures a part of substrate stage PST, scanning exposure of one shot area (divided area) on substrate P is performed, and a pattern of mask M (mask pattern) is transferred onto the shot area. More specifically, in the embodiment, a pattern of mask M is generated on substrate P by illumination system IOP and projection optical system PL, and the pattern is formed on substrate P by exposure of a sensitive layer (resist layer) on substrate P with illumination light IL.

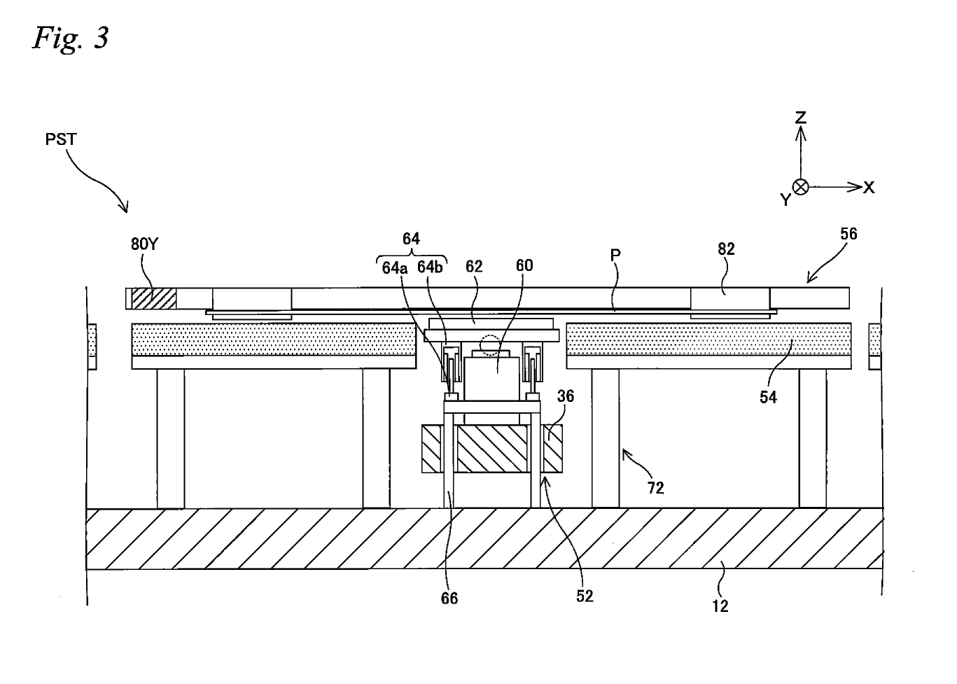

Body BD has barrel platform 33 previously described, and a pair of support walls 32 supporting the edges on the +Y side and the −Y side of barrel platform 33 from below on floor F. The pair of support walls 32 are each installed, for example, on floor surface F via a vibration isolator 34 that include air springs, and body BD and projection optical system PL are vibrationally separated from floor F. Further, in between the pair of support walls 32, a Y beam 36 consisting of a member that extends parallel to the Y-axis and has a rectangular shaped XZ section (reference) is built, as shown in FIGS. 2 and 3. Y beam 36 is placed above surface plate 12 which will be described later on spaced at a predetermined distance, and Y beam 36 and surface plate 12 are non-contact and are vibrationally separated.

Substrate stage device PST, as shown in FIG. 2, is equipped with a surface plate 12 installed on floor surface F, a fixed point stage 52 which holds substrate P from below in a non-contact manner right under exposure area IA on surface plate 12, a plurality of air floating devices 54 installed on surface plate 12, a substrate holding frame 56 which holds substrate P, and a drive unit 58 which drives substrate holding frame 56 in predetermined strokes (along the XY plane) in the X-axis direction and the Y-axis direction.

Surface plate 12 consists of a rectangular plate-shaped member whose longitudinal direction is in the X-axis direction in a planar view (when viewed from the +Z side).

Fixed point stage 52 is placed somewhat to the −X side from the center of surface plate 12. Fixed point stage 52, as shown in FIG. 3, is equipped with a weight cancellation device 60 mounted on Y beam 36, an air chuck device 62 which is supported tiltable (swingably) placed on weight cancellation device 60, and a plurality of Z voice coil motors 64 which drive air chuck device 62 in directions of three degrees of freedom, which are the Z-axis, ex, and ey directions.

Weight cancellation device 60 has a configuration similar to a weight cancellation device disclosed in, for example, U.S. Patent Application Publication No. 2010/0018950. In other words, for example, weight cancellation device 60 includes air springs which are not illustrated, and by a force whose direction of gravitational force is upward generated by the air springs, cancels the weight (a force whose direction of gravitational force is downward) of air chuck device 62, and reduces the load of the plurality of Z voice coil motors 64.

Air chuck device 62 holds the area (the part to be exposed) corresponding to exposure area IA (refer to FIG. 2) of substrate P by adsorption from the lower surface side of substrate P in a non-contact manner. The upper surface (a surface on the +Z side) of air chuck device 62, as shown in FIG. 2, is a rectangle whose longitudinal direction is in the Y-axis direction in a planar view, and the area is set slightly larger than the area of exposure area IA.

Air chuck device 62 jets pressurized gas (e.g., air) from its upper surface to the lower surface of substrate P, and also suctions the gas between the upper surface and the lower surface of substrate P. Air chuck device 62 forms a gaseous film having high stiffness between its upper surface and the lower surface of substrate P by balancing the pressure of gas jetted to the lower surface of substrate P and the negative pressure in between its upper surface and the lower surface of substrate P, and holds substrate P by suction in a non-contact manner via a substantially constant clearance (space/gap). Therefore, in substrate stage device PST related to the present embodiment, even if there was a distortion or a curve in substrate P, the shape of the part subject to exposure located right under projection optical system PL of substrate P can be corrected without fail along the upper surface of air chuck device 62. Further, because air chuck device 62 do not restrict the position of substrate P in the XY plane, substrate P can relatively move in the X-axis direction (a scanning direction) and the Y-axis direction (a stepping direction/a cross-scan direction) with respect to illumination light IL (refer to FIG. 1), even if the part subject to exposure is held by adsorption by air chuck device 62. Details of such air chuck devices (vacuum preload air bearing) are disclosed in, for example, U.S. Pat. No. 7,607,647 and the like.

The plurality of Z voice coil motors 64 each include a Z stator 64a fixed to a base frame 66 installed on surface plate 12, and a Z mover 64b fixed to air chuck device 62, as shown in FIG. 3. The plurality of Z voice coil motors 64, for example, are placed at least at three noncollinear places, and can drive air chuck device 62 in fine strokes in directions of three degrees of freedom, which are θx, θy and the Z-axis. Base frame 66 is separated from Y beam 36 vibrationally, and by using the plurality of Z voice coil motors 64, reaction force generated when air chuck device 62 is driven does not travel to weight cancellation device 60. A main controller 20 (refer to FIG. 7) controls the position of air chuck device 62 using the plurality of Z voice coil motors 64, so that the upper surface of substrate P is constantly located within the depth of focus of projection optical system PL, while measuring Z position information (surface position information) on the upper surface of substrate P by a surface position measurement system 40. As surface position measurement system 40, a multipoint focal position detection system that is disclosed in, for example, U.S. Pat. No. 5,448,332 and the like can be used.

Referring back to FIG. 2, the plurality of (e.g., 40, in the embodiment) air floating devices 54 supports substrate P (however, the area excluding the part to be exposed of substrate P held by fixed point stage 52 previously described) from below in a non-contact manner so that substrate P is roughly parallel to the horizontal plane.

In the embodiment, an air floating device group consisting of eight air floating devices 54 arranged at a predetermined distance in the Y-axis direction is placed, in five rows at a predetermined distance in the X-axis direction. In the description below, the eight air floating devices 54 configuring the air floating device group will be referred to as one to eight starting from the −Y side, for the sake of convenience. Further, the five rows of air floating device group will be referred to sequentially as one to five rows starting from the -x side, for the sake of convenience. Incidentally, because the fifth row of the air floating device group is used only when performing the carry-in and carry-out of the substrate as it will be described later on, the fifth row does not have air floating device 54 corresponding to the first and eighth devices, and is configured of a total of six air floating devices. Further, although the six air floating devices in the fifth row of the air floating device group are small when compared with other air floating devices, because the function is the same as other air floating devices 54, the same reference code 54 as other air floating devices will be used is for the sake of convenience. Further, Y beam 36 passes between the second row of the air floating device group and the third row of the air floating device group, and one each of air floating devices 54 is placed on the +Y side and −Y side of fixed point stage 52 mounted on Y beam 36.

Each of the plurality of air floating devices 54 prevents the lower surface of substrate P from being damaged when substrate P moves along the XY plane, by blowing pressurized gas (e.g., air) from the upper surface and supporting substrate P in a non-contact manner. Incidentally, the distance between the upper surface of each of the plurality of air floating devices 54 and lower surface of substrate P is set so that it is longer than the distance between the upper surface of air chuck device 62 of fixed point stage 52 described earlier and the lower surface of substrate P (refer to FIG. 1). Of the plurality of air floating device groups, the third to sixth air floating devices 54 in the air floating device group of the fourth row and the fifth row are each mounted on base member 68 (refer to FIG. 1) consisting of a tabular member. In the description below, base member 68 and the total of eight air floating devices 54 mounted on base member 68 will be described referred to together as a first air floating unit 69. The other 32 air floating devices 54 excluding the eight air floating devices 54 configuring the first air floating unit 69 are fixed on surface plate 12 via two each of columnar support members 72, as shown in FIGS. 1 and 3.

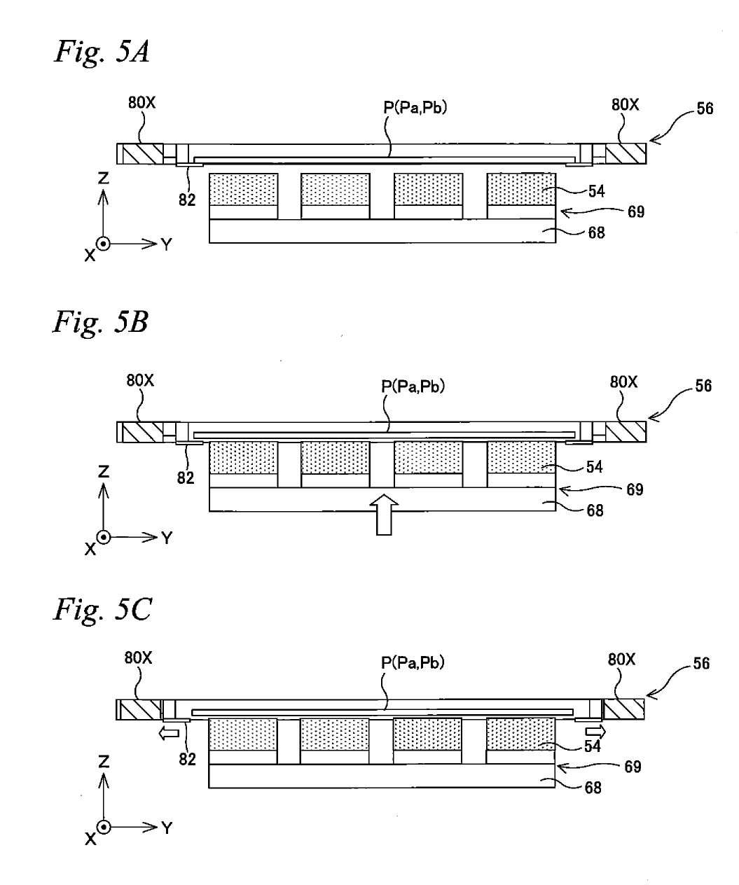

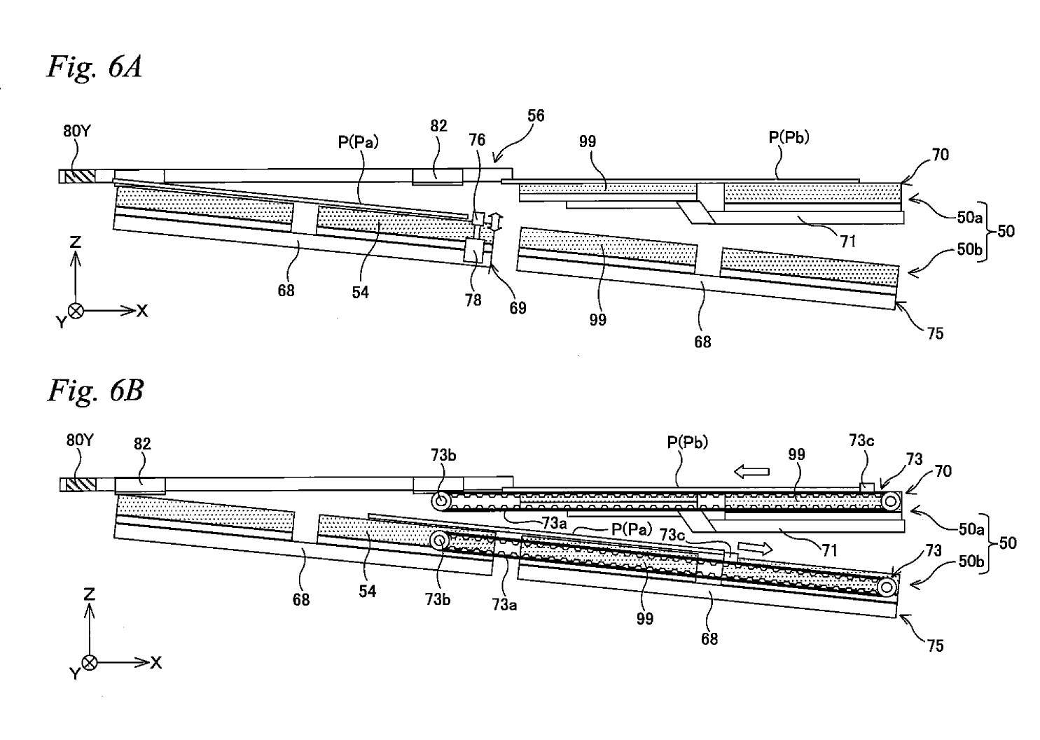

As shown in FIG. 1, the first air surfacing unit 69 is supported from below on surface plate 12 by, for example, a plurality of Z linear actuators 74 including a linear motor (or an air cylinder) and the like. The first air floating unit 69 is movable in a vertical direction (refer to FIGS. 5A to 5C) by the plurality of Z linear actuators 74 being driven (controlled) synchronously, for example, in a state where the upper surface of the eight air floating devices 54 are made parallel to a horizontal plane. Further, as shown in FIG. 6A, by the plurality of Z linear actuators 74 being appropriately driven (controlled), the first air floating unit 69 can change its attitude to a state where the position in the Z-axis direction (hereinafter referred to as Z position) on the +X side is lower than the position in the Z-axis direction on the −X side (a state where the upper surface is tilted in the θy direction with respect to the horizontal plane). In the description below, in the attitude of the first air floating unit 69, a state, for example, where the upper surface of the eight air floating devices 54 is parallel to the horizontal plane will be referred to as a horizontal state, and a state, for example, where the upper surface of the eight air floating devices 54 is tilted in the θy direction with respect to the horizontal plane will be referred to as a tilted state.

Further, as shown in FIG. 6A, the first air floating unit 69 has a stopper 76 (stopper 76 is not illustrated in drawings other than FIG. 6A). Stopper 76 is driven by actuators 78 such as air cylinders integrally attached to base member 68, for example, in a direction orthogonal to the upper surface of the eight air floating devices 54. Incidentally, although it is not illustrated in FIG. 6A because the stoppers overlap in the depth of the page surface, a plurality of stoppers 76 (and actuators 78 which drive stoppers 76) are provided in the Y-axis direction at a predetermined distance. When the first air floating unit 69 is in a tilted state, stopper 76 is driven to a position where the stopper projects out from the upper surface of air floating device 54, so as to prevent substrate P from sliding off the upper surface of the first air floating unit 69 by its self-weight. On the contrary, in a state where stopper 76 is positioned at a position lower than the upper surface of air floating device 54, substrate P becomes movable, for example, along the upper surface of the eight air floating devices 54.

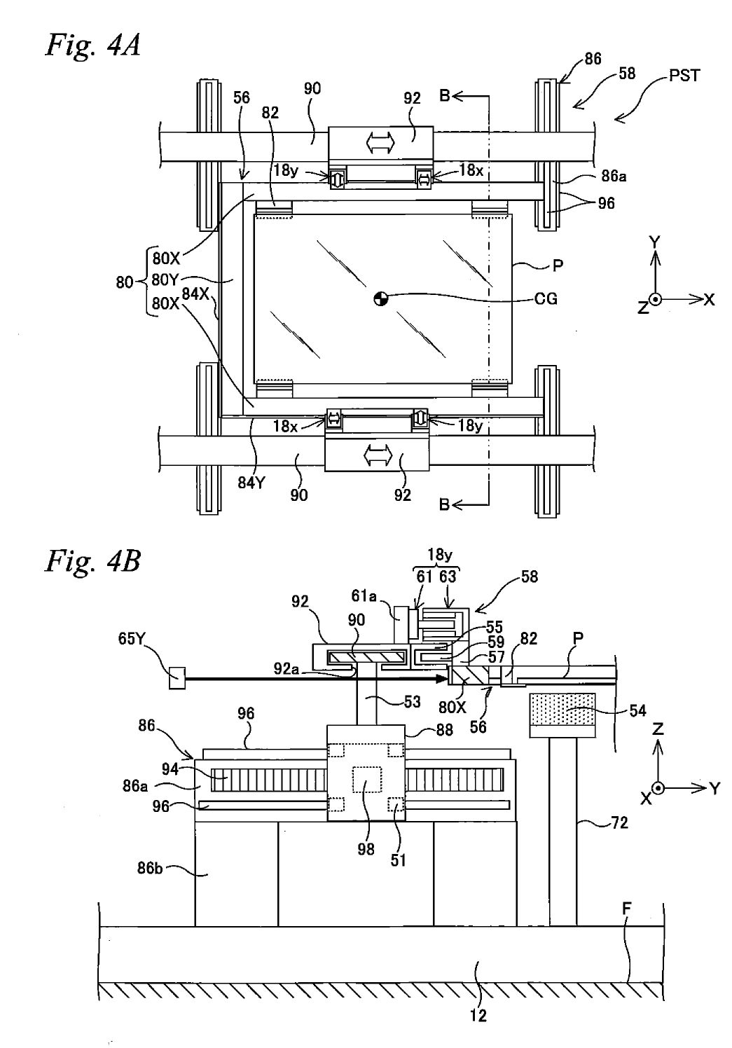

Substrate holding frame 56, as shown in FIG. 4A, includes a main section 80 consisting of a frame shaped member having a U-shape in a planar view, and a plurality of, four in the embodiment, support sections 82 which support substrate P from below. Main section 80 has a pair of X frame members 80X and one Y frame member 80Y. The pair of X frame members 80X consists of a plate shaped member parallel to the XY plane and whose longitudinal direction is in the X-axis direction, and is placed parallel at a predetermined distance (a distance larger than the dimension in the Y-axis direction of substrate P) in the Y-axis direction. Y frame member 80Y consists of a plate shaped member parallel to the XY plane and whose longitudinal direction is in the Y-axis direction, and connects the ends on the −X side of the pair of X frame members. To the side surface on the −Y side of X frame member 80X on the −Y side, a Y movable mirror 84Y having a reflection surface which is orthogonal to the Y-axis is attached, and to the side surface on the −X side of Y frame member 80Y, an X movable mirror 84 having a reflection surface orthogonal to the X-axis is attached.

Two of the four support sections 82 are attached to X frame member 80X on the −Y side, and the other two are attached to X frame member 80X on the +Y side, each spaced apart in the X-axis direction at a predetermined distance (a distance smaller than the dimension in the X-axis direction of the substrate). Support section 82 consists of a member having an L-like shape in the YZ section (refer to FIG. 5A), and supports the substrate by a portion parallel to the XY plane from below. Each support section 82 has an adsorption pad which is not illustrated on a surface which faces substrate P, and holds substrate P, for example, by vacuum suction. The four support sections 82 are each attached to X frame member 80X on the +Y side or the −Y side, via Y actuators 42 (refer to FIG. 7), respectively. Each of the four support sections 82 are movable in approaching and separating directions with respect to X frame members 80X to which each support section is attached, as shown in FIGS. 5B and 5C. The Y actuator, for example, includes a linear motor, an air cylinder and the like.

As shown in FIG. 4A, drive unit 58 includes four Y stators 86 which are placed apart in the X-axis direction and the Y-axis direction, four Y movers 88 (Y movers are not illustrated in FIG. 4A, refer to FIG. 4B) corresponding to each of the four Y stators 86, a pair of X stators 90, and a pair of X movers 92 corresponding to the pair of X stators 90 and the like.

As shown in FIG. 2, two of the four Y stators 86 are placed in between the air floating device group of the first row and the air floating device group of the second row, and the other two are placed in between the air floating device group of the third row and the air floating device group of the fourth row, in a state set apart at a predetermined distance in the Y-axis direction. As shown extracting one in FIG. 4B, each Y stator 86 includes a main section 86a consisting of a plate shaped member extending in the Y-axis direction and parallel to the YZ plane, and a pair of legs 86b which supports main section 86a from below on surface plate 12. To both of the side surfaces (the surface on one side and the other side in the X-axis direction) of main section 86a, a magnetic unit 94 including a plurality of magnets arranged at a predetermined distance in the Y-axis direction is fixed (magnetic unit 94 fixed to the surface on the −X side is not illustrated in FIG. 4B), respectively. Further, as it can be seen from FIGS. 4A and 4B, on both side surfaces and the upper surface of main section 86a, Y linear guide members 96 extending parallel to the Y-axis are fixed.

Y mover 88 consists of a member whose XZ section is an inverted U-shape, and main section 86a of Y stator 86 is inserted in between the pair of opposing surfaces . To the pair of opposing surfaces of Y mover 88, coil units 98 corresponding to the pair of magnet units 94 are attached (coil unit 98 on the −X side is not illustrated). To the pair of opposing surfaces and the ceiling plane of Y mover 88, a plurality of sliders 51 (slider 51 on the −X side is not illustrated) are fixed which slidably engage with Y linear guide members 96. The four Y movers 88 are each synchronously driven in predetermined strokes in the Y-axis direction by a Y linear motor 97 (refer to FIG. 7), using the electromagnetic force (Lorentz force) drive method consisting of coil units 98, and magnet units 94 of the corresponding Y stator 86.

As shown in FIG. 2, the pair of X stators 90 each consist of a plate shaped member parallel to the XY plane and whose longitudinal direction is in the X-axis direction, and is placed parallel at a predetermined distance (a distance larger than the dimension in the Y-axis direction of substrate holding frame 56) in the Y-axis direction. The pair of X stators 90 each have a magnet unit which is not illustrated, including a plurality of magnets arranged at a predetermined distance in the X-axis direction. As shown in FIG. 4B, of the pair of X stators 90, X stator 90 on the −Y side is supported (in FIG. 4B, of the two Y movers 88, Y movers 88 on the +X side is not illustrated) from below by columnar support members 53 each fixed to the upper surfaces of the two Y movers 88 corresponding to the two Y stators 86 on the −Y side. Further, although it is not illustrated, of the pair of X stators 90, X stator 90 on the +Y side is supported from below by the columnar support members 53 which are each fixed to the upper surface of the two Y movers 88 on the +Y side.

X mover 92, as shown in FIG. 4B, consists of a member having a rectangular frame shaped section in which an opening 92a is formed in the center of the bottom surface, and is provided extending in the X-axis direction so that its upper surface is parallel to the XY plane. X stator 90 is inserted inside X mover 92, and in opening 92a, support member 53 which supports X stator 90 on the upper surface of Y mover 88 is inserted (engages in a non-contact manner). X mover 92 has a coil unit including a coil which is not illustrated. Each of the pair of X movers 92 are driven synchronously in predetermined strokes in the X-axis direction (refer to FIG. 4A) by an X linear motor 93 (refer to FIG. 7) using an electromagnetic drive method consisting of a coil unit and a magnet unit of the corresponding X stator 90.

As shown in FIG. 4B, on the side surface on the +Y side of X mover 92 on the −Y side, a holding member 55 whose YZ sectional surface is an U-shape is fixed (a similar holding member is fixed to the surface on the −Y side of X mover 92 on the +Y side). Holding member 55 has air bearings which are not illustrated on the pair of opposing surfaces. Between the pair of opposing surfaces of holding member 55, a plate shaped member 59 is inserted, which is parallel to the XY plane and is fixed via a base member 57 on the upper surface of X frame member 80X of substrate holding frame 56. Substrate holding frame 56 is supported by X mover 92 in a non-contact manner, via base member 57 fixed to each of the pair of X frame members 80, plate shaped member 59, holding member 55 fixed to X mover 92, and air bearings provided in holding member 55.

Further, drive unit 58 has two X voice coil motors 18x, and two Y voice coil motors 18y, as shown in FIG. 4A. One of the two X voice coil motors 18x and one of the two Y voice coil motors 18y are placed on the −Y side of substrate holding frame 56, and the other of the two X voice coil motors 19x and the other of the two Y voice coil motors 18y are placed on the +Y side of substrate holding frame 56. One and other X voice coil motors 18x are placed at positions which are symmetric to each other with respect to center of gravity CG of substrate holding frame 56 and substrate P in total, and one and other y voice coil motors 18y are placed at positions which are symmetric to each other with respect to the center of gravity CG described above. As shown in FIG. 4B, one of the Y voice coil motors 18y includes a stator 61 (e.g., a coil unit including a coil) fixed to X mover 92 via a support member 61a, and a mover 63 (e.g., a magnet unit including a magnet) fixed to substrate holding frame 56 via base member 57. Incidentally, because the configuration of the other Y voice coil motor 18y and the two X voice coil motors 18x are similar to one of the Y voice coil motors 18y shown in FIG. 4B, the description thereabout will be omitted.

When main controller 20 drives the pair of X movers 92 in the X-axis direction in predetermined strokes on the pair of X stators 90 via a pair of X linear motors 93 of drive unit 58, substrate holding frame 56 is synchronously driven (driven in the same direction and the same speed as the pair of X movers 92) with respect to the pair of movers 92 using the two X voice coil motors 18x. On this drive, main controller 20 drives X voice coil motor 18x, based on measurement values of the substrate interferometer system to be described below, and positioning of substrate holding frame 56 is controlled at a high speed with a precision higher than the positioning of X mover 92 by X linear motor 93. Further, when main controller 20 drives the pair of Y movers 88 in the Y-axis direction in predetermined strokes on the four Y stators 86 via the plurality of Y linear motors 97 of drive unit 58, substrate holding frame 56 is synchronously driven (driven in the same direction and the same speed as the pair of Y movers 88) with respect to the pair of X movers 92 using the two Y voice coil motors 18y. On this drive, main controller 20 drives Y voice coil motor 18y, based on measurement values of the substrate interferometer system to be described below, and positioning of substrate holding frame 56 is controlled at a high speed with a precision higher than the positioning of Y mover 88 by Y linear motor 97. Further, main controller 20 finely drives substrate holding frame 56 appropriately around an axis (θz direction) parallel to the Z-axis that passes through center of gravity CG with respect to the pair of X stators 90, using the two X voice coil motors 18x and the two Y voice coil motors 18y.

Positional information of substrate holding frame 56, or in other words, substrate P within the XY plane (including the θz direction) is obtained by a substrate interferometer system 65 (refer to FIG. 7) including an X interferometer 65X which irradiates a measurement beam on X movable mirror 84 and a Y interferometer 65Y which irradiates a measurement beam on a Y movable mirror 84Y, as shown in FIG. 2.

Substrate exchanging device 50 is placed on the +X side of surface plate 12, as shown in FIG. 2. Substrate exchanging device 50, as shown in FIG. 6A, is equipped with a substrate carry-in device 50a and a substrate carry-out device 50b (not illustrated being hidden below substrate carry-in device 50a in FIG. 2) placed below substrate carry-in device 50a.

Substrate carry-in device 50a includes a second air floating unit 70 which has a similar configuration and function as the first air floating unit 69 described above. In other words, the second air floating unit 70 has a plurality of (e.g., eight) air floating devices 99 (refer to FIG. 2) mounted on a base member 71. Incidentally, air floating device 99 is substantially the same as air floating device 54. The upper surface of the eight air floating devices 99, for example, the second air floating unit 70 has, is parallel to the horizontal plane. Incidentally, while the thickness of the second air floating unit 70 on the −X side is actually thinner than the +X side, its function is substantially the same as the first air floating unit 69.

Further, substrate carry-in device 50a has a substrate feeding device 73 (not illustrated in drawings other than FIG. 6B) including a belt 73a, as shown in FIG. 6B. A pair of pulleys 73b to drive belt 73a is supported by a floor surface (or by base member 71 of the second air floating unit 70) via a support member which is not illustrated. Belt 73a and pulleys 73b are placed, for example, at a +Y side and the −Y side (or, between the plurality of air floating devices 99) of the second air floating unit 70. To the upper surface of belt 73a, a pad 73c is fixed. When belt 73a is driven in a state where substrate P is mounted on the second air floating unit 70, substrate carry-in device 50a pushes substrate P by pad 73c and moves substrate P, for example, along the upper surface of the eight air floating devices 99 (pushes out substrate P which is on the second air floating unit 70 on to the first air floating unit 69).

Referring back to FIG. 6A, substrate carry-out device 50b includes a third air floating unit 75 that has a similar configuration and function as the first air floating unit 69 described above. In other words, the third air floating unit 75 has a plurality of, for example, eight, air floating devices 99 mounted on base member 68. The upper surface of, for example, the eight air floating devices 99 that the third air floating unit 75 has is tilted with respect to a horizontal plane so that the Z position on the +X side is lower than the z position on the −X side. Further, substrate carry-out device 50b has substrate feeding device 73 whose configuration is similar to that of substrate carry-in device 50a described above. In substrate carry-out device 50b, because the speed of belt 73a is controlled in a state where pad 73c and substrate P are in contact, the speed of movement (sliding down) along the upper surface of, for example, the eight air floating devices 99 of substrate P by its self-weight is controlled.

FIG. 7 shows a block diagram that shows input/output relations of main controller 20 that is configured of a control system of liquid crystal exposure apparatus 10 as the central component and performs overall control of the respective components. Main controller 20 includes a workstation (or a microcomputer) and the like, and has overall control over each part of liquid crystal exposure apparatus 10.

In liquid crystal exposure apparatus 10 (refer to FIG. 1) which is configured as described above, loading of a mask on mask stage MST by a mask loader which is not illustrated, and loading of substrate P onto substrate stage device PST by substrate carry-in device 50a (not illustrated in FIG. 1, refer to FIG. 2) are performed under the control of main controller 20 (refer to FIG. 7). After that, main controller 20 executes alignment measurement using an alignment detection system that is not illustrated, and after the alignment measurement has been completed, an exposure operation by the step-and-scan method is performed.

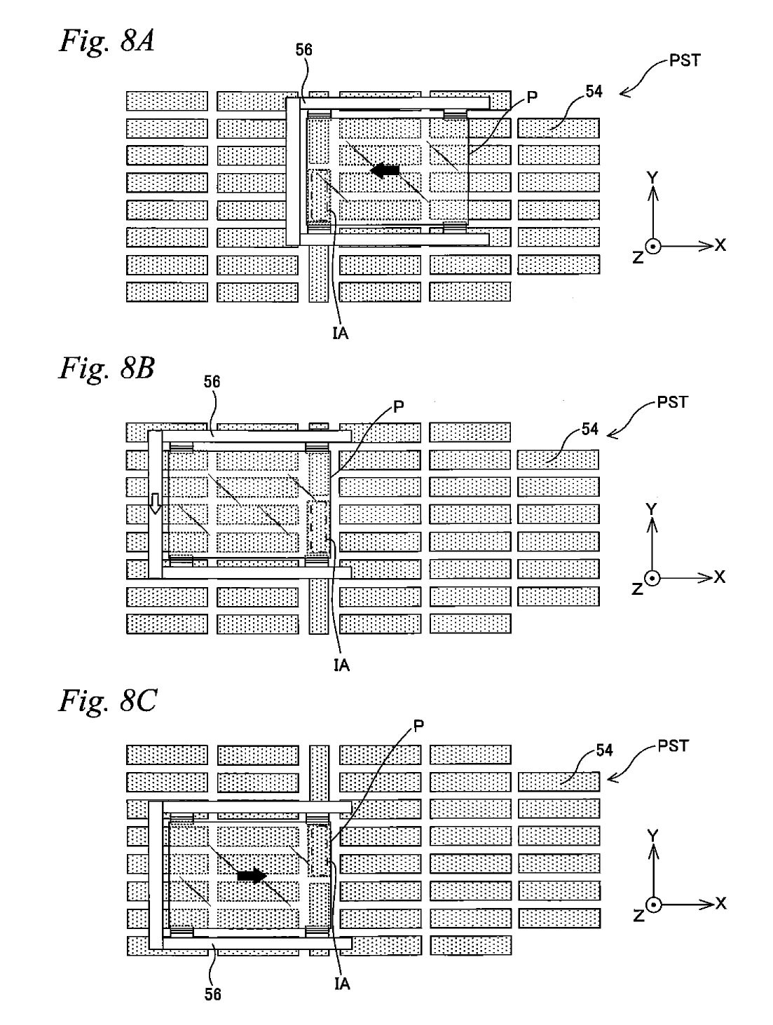

Now, an example of a movement of substrate stage device PST at the time of the exposure operation above will be described, based on FIGS. 8A to 8C. Incidentally, in FIGS. 8A to 8C, from the viewpoint of avoiding intricacy of the drawings, illustration of drive unit 58 used to drive substrate holding frame 56 is omitted.

In the embodiment, exposure is performed in the order from a −Y side area to a 1-Y side area of substrate P. First of all, substrate holding frame 56 which holds substrate P is driven (refer to the black arrow in FIG. 8A) in the −X direction with respect to exposure area IA synchronously with mask M (mask stage MST), and a scanning operation (exposure operation) is performed in the area on the −Y side of substrate P. Subsequently, as shown in FIG. 8B, by substrate holding frame 56 being driven in the −Y direction (refer to the white arrow in FIG. 8B), stepping operation is performed. After this, as shown in FIG. 8C, by substrate holding frame 56 holding substrate P being driven in the +X direction synchronously with mask M (mask stage MST), substrate P is driven in the +X direction (refer to the black arrow in FIG. 8C) with respect to exposure area IA, and a scanning operation (exposure operation) in the area on the +Y side of substrate P is performed.

While exposure operation by the step-and-scan method shown in FIGS. 8A to 8C is being performed, main controller 20 measures positional information of substrate P within the XY plane using substrate interferometer system 65, as well as measure the surface position information of the area subject to exposure of the substrate P surface using surface position measurement system 40. Then, by controlling the position (surface position) of air chuck device 88 based on the measurement values, main controller 20 performs positioning so that of the substrate surface, the surface position of the area subject to exposure located right under projection optical system PL is positioned within the depth of focus of projection optical system PL. This allows the surface position of the area subject to exposure to be positioned without fail within the depth of focus of projection optical system PL, even if, for example, the surface of substrate P was undulated or there was an error in the thickness of substrate P, and the exposure precision can be improved. As described, because liquid crystal exposure apparatus 10 related to the present embodiment controls the surface position only at a position corresponding to the exposure area of the substrate surface, the weight (especially the movable portion) can be greatly reduced when compared with a conventional stage device (e.g., refer to U.S. Patent Application Publication No. 2010/0018950) which, for example, drives substrate P on an XY two-dimensional stage where a table member (substrate holder) having an area around the same as substrate to maintain good flatness is driven (Z-leveling stage is also driven in an XY two-dimensional drive with the substrate) in the Z-axis direction and in the tilt direction. Specifically, for example, in the case of using a large-scale substrate having a side exceeding 3 m, while in the conventional stage device the gross weight of the movable portion becomes nearly 10 t, in substrate stage device PST related to the present embodiment, the gross weight of the movable portion (substrate holding frame 56, X stator 90, X mover 92, Y mover 88 and the like) can be around several hundred kg. Accordingly, for example, X linear motor 93 used to drive X mover 92 and Y linear motor 97 used to drive Y mover 88 can be motors having a small output, which can reduce running cost. Further, it is easy to improve infrastructure such as power-supply facilities and the like. Further, because the linear motor requires only a small output, initial cost can also be reduced.

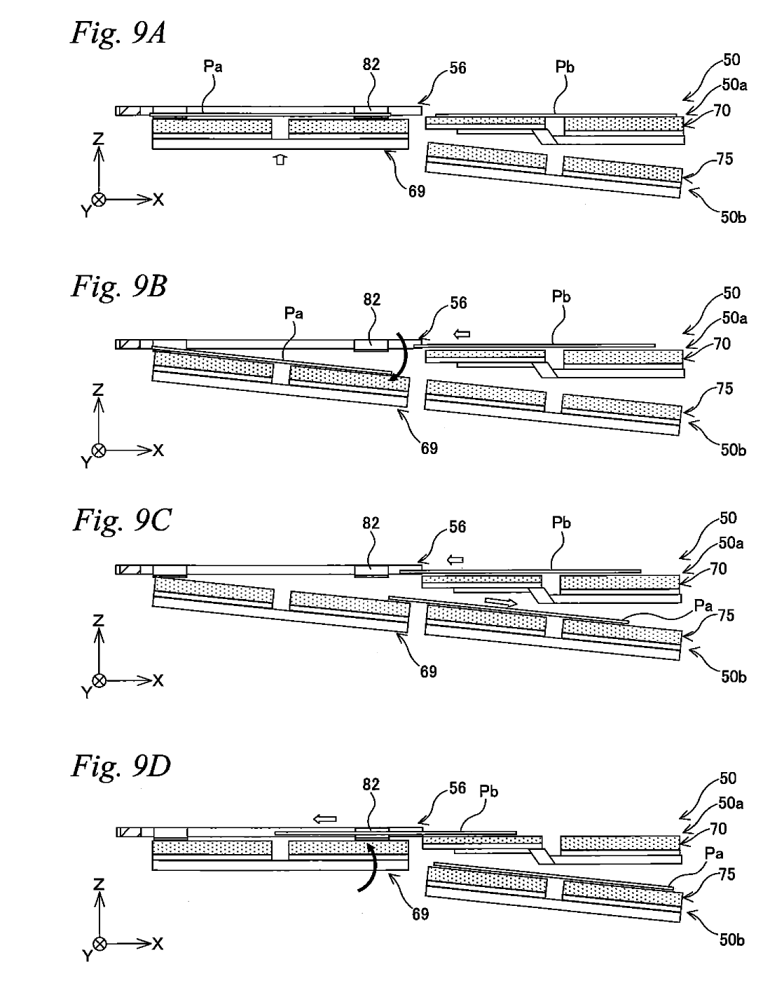

In liquid crystal exposure apparatus 10 related to the present embodiment, after the exposure operation by the step-and-scan method described above has been completed, exchange of substrate P held by substrate holding frame 56 is performed, by substrate P that has been exposed being carried out from substrate holding frame 56 and another substrate P being carried in to substrate holding frame 56. This exchange of substrate P is performed under the control of main controller 20. An example of an exchange operation of substrate P is described below, based on FIGS. 9A to 9D. Incidentally, to simplify the drawings, illustration of substrate feeding device 73 (refer to FIG. 6B) and the like is omitted in FIGS. 9A to 9D. Further, the substrate subject to carry-out from substrate holding frame 56 will be described as Pa, and the substrate subject to carry-in to substrate holding frame 56 will be described as Pb. As shown in FIG. 9A, substrate Pb is placed on the second air floating unit 70 of substrate carry-in device 50a.

After the exposure processing has been completed, by substrate holding frame 56 being driven, substrate Pa moves onto the first air floating unit 69 as shown in FIG. 9A. At this point, as shown in FIG. 5A, the position of substrate holding frame 56 in the Y-axis direction is positioned so that air floating device 54 of first air surfacing unit 69 is not located below support section 82 of substrate holding frame 56 (not overlapping in a vertical direction). Then, suction of substrate Pa by substrate holding frame 56 is canceled, and as shown in FIG. 5B, the first air floating unit 69 is finely driven in the +Z direction. By this, support section 82 is separated from substrate Pa, and in this state, support section 82 is driven in a direction separating from substrate Pa, as shown in FIG. 5C.

Subsequently, main controller 20 controls the attitude of the first air floating unit 69 so that the first air floating unit 69 is in a tilted state, as shown in FIG. 9B. At this point, main controller 20 controls the plurality of Z linear actuators 74 (refer to FIG. 1) so that a tilt angle of the upper surface of the first air floating unit 69 with respect to the horizontal plane becomes the same as a tilt angle of the upper surface of the third air floating unit 75, and the upper surface of the first air floating unit 69 is positioned flush with the upper surface of the third air floating unit 75. Further, before changing the attitude of the first air floating unit 69, main controller 20 makes stopper 76 (refer to FIG. 6A) project upward from the upper surface of air floating devices 99, so as to prevent substrate P from sliding off along the top surface of the first air floating unit 69. Further, main controller 20 positions pad 73c which substrate feeding device 73 (not illustrated in FIG. 9B, refer to FIG. 6B) of the third air floating unit 75 has to the vicinity of the edge on the +X side of substrate Pa.

Further, concurrently with changing the attitude of the first air floating unit 69, main controller 20 controls the substrate feeding device 73 (not illustrated in FIG. 9B, refer to FIG. 6B) of substrate carry-in device 50a, and finely moves substrate Pb subject to carry-in in the −X direction.

When the tilt angle of the upper surface of the first air floating unit 69 with respect to the horizontal plane becomes the same as the tilt angle of the upper surface of the third air floating unit 75 as shown in FIG. 9B, main controller 20 stops attitude control of the first air floating unit 69 and then positions stopper 76 (refer to FIG. 6A) so that stopper 76 is positioned lower than the upper surface of air floating device 99. This makes an edge (the tip in the carry-out direction) on the +X side of substrate Pa come in contact with pad 73c (refer to FIG. 6B).

Subsequently, main controller 20 carries the first substrate Pa from above the first air floating unit 69 along a tilted surface formed by the upper surface of the first and the third air floating units 69 and 75, and on to the upper surface of the third air floating unit 75, using substrate feeding device 73 (refer to FIG. 6B) of substrate carry-out device 50b, as shown in FIG. 9C. Substrate Pa carried to the third air surfacing unit 75 is carried to an external unit such as, for example, a coater developer, by a substrate carrier device which is not illustrated.

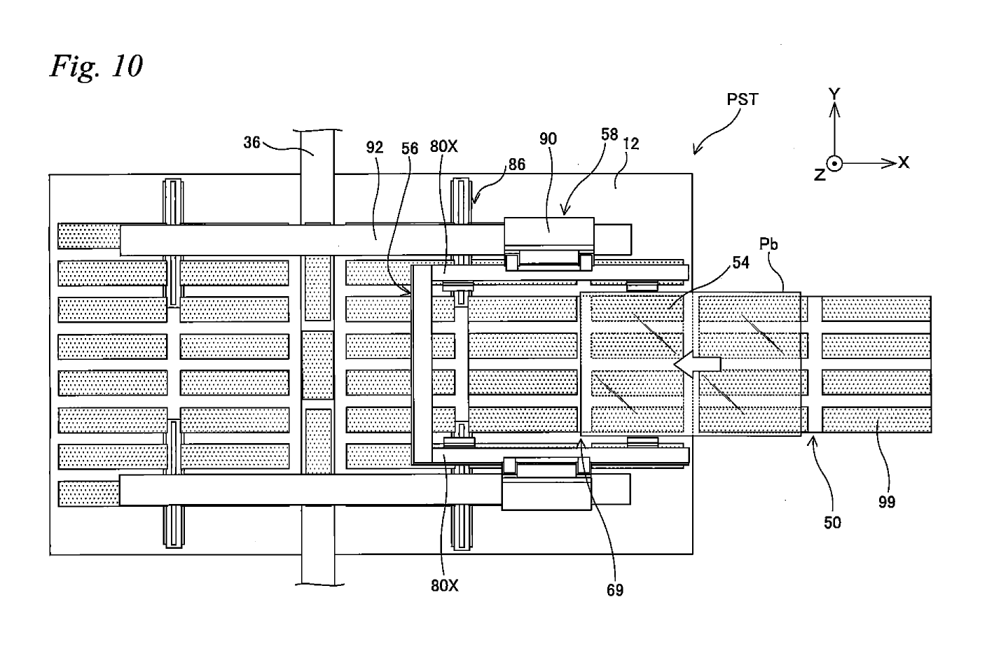

Further, when substrate Pa subject to carry-out is delivered to the third air floating unit 75, main controller 20 controls the attitude of the first air floating unit 69 and restores the first air floating unit 69 to a position where its upper surface becomes horizontal (to a horizontal state), as shown in FIG. 9D. Then, substrate Pb subject to carry-in is carried from the second air floating unit 70 to the first air floating unit 69, along a horizontal surface formed by the upper surface of the first and second air floating units 69 and 70, using substrate feeding device 73 (refer to FIG. 6B) of substrate carry-in device 50a. By this operation, substrate Pb is inserted between the pair of X frame members 80X of substrate holding frame 56, as shown in FIG. 10. After this, substrate Pb is held by substrate holding frame 56 in an order reverse to FIGS. 5A to 5C (the order of FIGS. 5C to 5A). In the liquid crystal exposure apparatus 10 related to the present embodiment, by repeatedly performing the substrate exchange operation shown in FIGS. 9A to 9D above, exposure operation and the like is performed consecutively to a plurality of substrates.

As described above, according to liquid crystal exposure apparatus 10 related to the present embodiment, because carry-out of a substrate and carry-in of another substrate are each performed using separate paths, exchange of a substrate held by substrate holding frame 56 can be performed quickly. Further, because a part of the carry-out operation of a substrate and the carry-in operation of another substrate are performed concurrently, substrate exchange can be performed more quickly than the case when carry-in of a substrate is performed after carry-out of a substrate is performed.

Further, because air floating device 99 is provided in each of substrate carry-in device 50a and substrate carry-out device 50b, and the substrate is carried in a floating state, the substrate can be moved quickly and easily. Further, the lower surface of the substrate can be prevented from being damaged.

### Second Embodiment

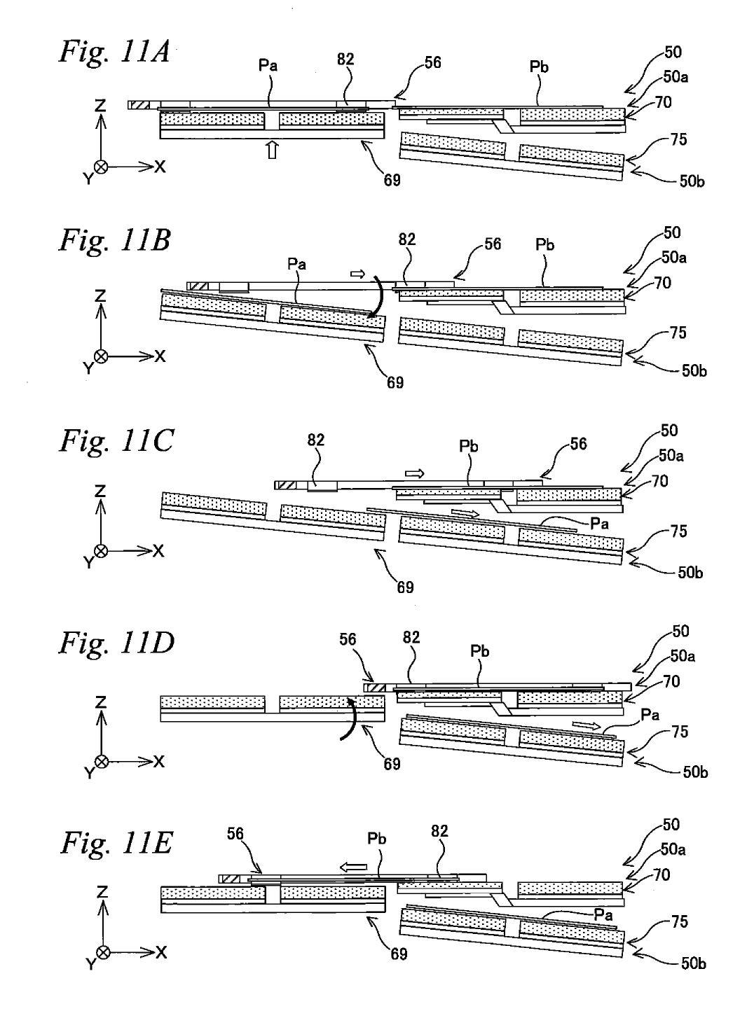

Next, a second embodiment will be described, with reference to FIGS. 11A to 11E. Here, points that are different from the first embodiment previously described will be explained, and the same reference numerals will be used for the same or similar members as in the first embodiment previously described, and a description thereabout will be simplified or omitted.

In the first embodiment described above, while substrate carry-in device 50a carried substrate Pb to substrate holding frame 56 using substrate feeding device 73, in the liquid crystal exposure apparatus related to the second embodiment, substrate holding frame 56 is driven to the area on substrate carry-in device 50a, and substrate Pb is delivered to substrate holding frame 56 on the second air floating unit 70. Therefore, although it is not illustrated, a stator of the X linear motor used to drive substrate holding frame 56 in the X-axis direction is set longer by a predetermined distance to the +X side than in the first embodiment.

In the second embodiment, in the case of substrate exchange, first of all, the adsorption and holding of substrate Pa by substrate holding frame 56 is released as in the first embodiment described above (refer to FIG. 11A) And, the attitude of the first air floating unit 69 is shifted to a tilted state (refer to FIG. 11B). In parallel with this, substrate holding frame 56 is driven (refer to FIGS. 11B and 11C) in the +X direction by X linear motor 93. Then, substrate Pa is carried along a tilted surface (movement plane) formed by the upper surface of the first and third air floating units 69 and 75. Then, after substrate Pa has been moved on the third air floating unit 75, the first air floating unit 69 is shifted from the tilted state to a horizontal state.

Subsequently, substrate holding frame 56 is moved on the second air floating unit 70 (refer to FIG. 11D). Here, although it is not illustrated, the second air floating unit 70 is configured finely movable in a vertical direction, and substrate Pb is held by substrate holding frame 56 in an order reverse to FIGS. 5A to 5C. Then, substrate holding frame 56 holding substrate Pb is driven to the −X side (refer to FIG. 11E). At this point, a part of substrate Pb held by substrate holding frame 56 moves over the first air floating unit 69 before the shift to the horizontal state along a horizontal plane which includes the upper surface of the second air floating unit 70, and at the point where the first air floating unit 69 has shifted to the horizontal state, substrate Pb is carried along the horizontal plane (movement plane) formed by the upper surface of each of the first and second air floating units 69 and 70. Hereinafter, alignment measurement and exposure operation by the step-and-scan method are performed.

According to the second embodiment, because substrate Pb is carried toward the area on the first air floating unit 69 in a state where substrate Pb is held by substrate holding frame 56 on the second air floating unit 70, a part of substrate Pb can be carried on the first air floating unit 69 along a horizontal plane including the upper surface of the second air floating unit 70 before the first air floating unit 69 that has been tilted becomes horizontal. Accordingly, the cycle time of substrate exchange can be reduced when compared with the first embodiment.

Further, by using substrate holding frame 56 for carriage of substrate Pb from the second air floating unit 70 onto the first air floating unit 69, substrate Pb can be moved more quickly (in the first embodiment above, carriage at a high speed is difficult because substrate Pb is carried in a state where substrate Pb is simply mounted on belt 73a, or in other words, in a state where substrate Pb is not restricted in the XY direction) than when substrate feeding device 73 (by the belt drive method in the first embodiment described above) of substrate carry-in device 50a is used for the carriage.

Further, by simply extending stator 90 of the X linear motor in the X direction without changing the control system of substrate holding frame 56 and the measurement system of the first embodiment described above (in other words, while suppressing cost increase), substrate holding frame 56 can be moved onto the second air floating unit 70.

### Third Embodiment

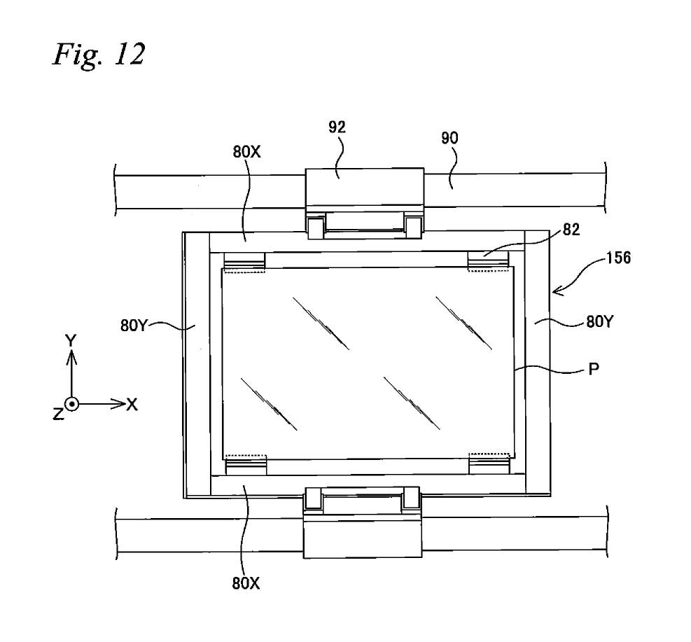

Next, a third embodiment will be described, with reference to FIGS. 12 to 14C. Here, points that are different from the first embodiment previously described will be explained, and the same or similar reference numerals will be used for the same or similar members as in the first embodiment previously described, and a description thereabout will be simplified or omitted.

The liquid crystal exposure apparatus related to the third embodiment has a substrate holding frame 156 instead of substrate holding frame 56 previously described, as shown in FIG. 12. Substrate holding frame 156 consists of a member having a rectangular frame shape in a planar view, which is configured by a pair of X frame members 80X whose ends on the +X side are connected by Y frame members 80Y. Accordingly, rigidity is higher than substrate holding frame 56 previously described. Substrate holding frame 156 supports substrate P by four support sections 82, in a state where the pair of X frame members 80X and a pair of Y frame members 80Y surround the periphery of substrate P.

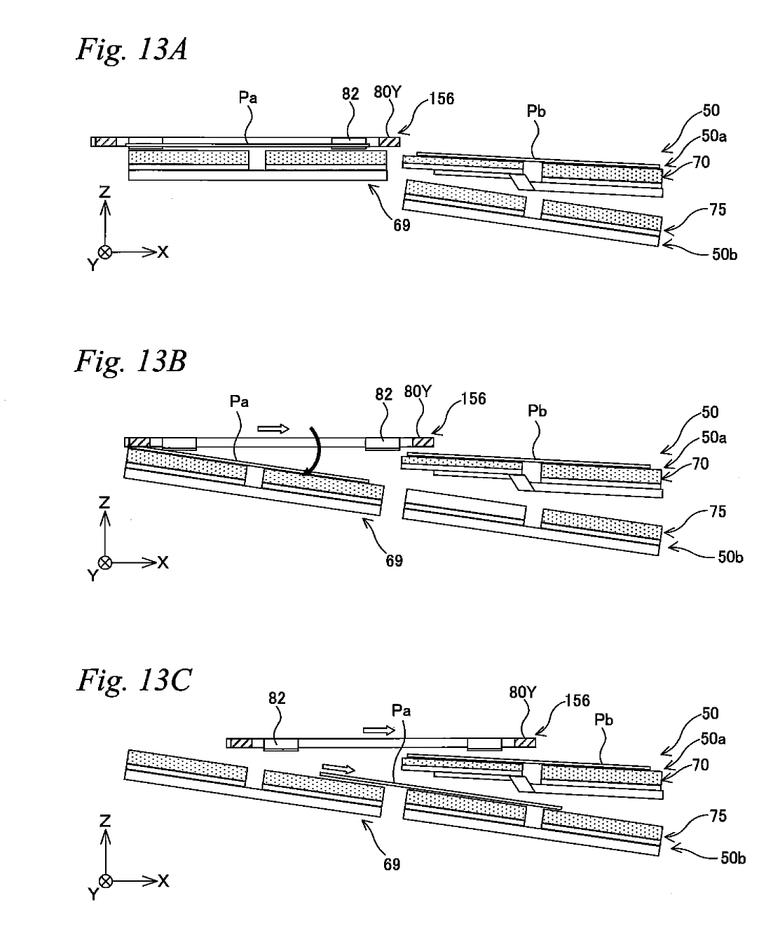

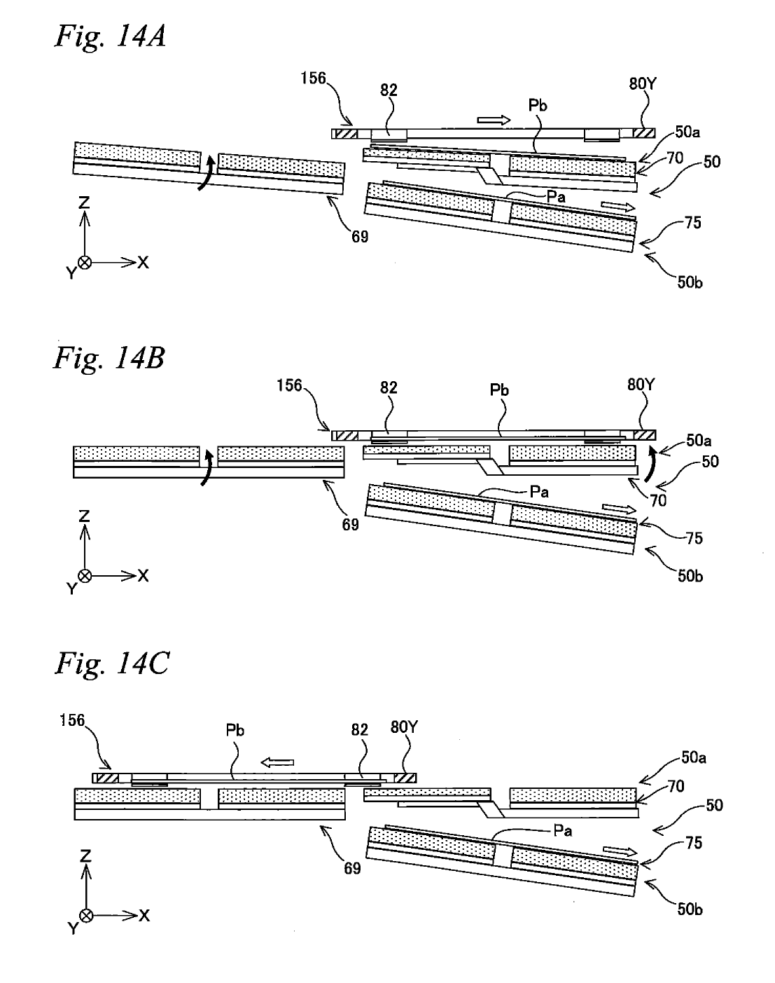

Further, in the liquid crystal exposure apparatus related to the third embodiment, the second air floating unit 70 (FIGS. 13A to 14C) of substrate carry-in device 50a is movable in the Z-axis direction as well as tiltable in the θy direction like the first air floating unit 69, by the plurality of Z linear actuators which are not illustrated.

In the third embodiment, as shown in FIG. 13A, in the case of substrate exchange, the first air surfacing unit 69 is initially in a horizontal state, and the second air surfacing unit 70 is tilted so that the edge on the +X side is lower than the edge on the −X side. In this state, the Z position of the edge on the −X side of the second air floating unit 70 and substrate Pb are at positions lower than substrate holding frame 156.

Then, as shown in FIG. 13B, the first air floating unit 69 shifts to a tilted state and substrate holding frame 156 is driven in the +X direction. Subsequently, as shown in FIG. 13C, substrate Pa is carried from above the first air floating unit 69 onto the third air floating unit 75. Subsequently, as shown in FIG. 14A, substrate holding frame 156 is moved onto the second air floating unit 70, and the first air floating unit 69 is shifted from a tilted state to a horizontal state. Subsequently, as shown in FIG. 14B, after the second air floating unit 70 has shifted to a horizontal state from the tilted state, substrate Pb is held by substrate holding frame 156 as in the second embodiment. When the second air floating unit 70 is shifted to a horizontal state, the Z position of its upper surface is controlled to be the same as the first air floating unit 69. Subsequently, as shown in FIG. 14C, substrate holding frame 156 which holds substrate Pb is driven in the −X direction, and moves from the second air floating unit 70 onto the first air floating unit 69. Hereinafter, alignment measurement and exposure operation by the step-and-scan method are performed.

According to the third embodiment, when substrate holding frame 156 is moved onto the second air floating unit 70 from the first air floating unit 69, because substrate Pb and the second air floating unit 70 are positioned beforehand at a position lower than substrate holding frame 156, namely at a position deviated from the movement path of substrate holding frame 156, this prevents Y frame member 80Y on +X side of substrate holding frame 156 from colliding or coming into contact with substrate Pb and the second air floating unit 70.

Incidentally, in the third embodiment, while the second air floating unit 70 is initially tilted, and is leveled and driven upward in the case of substrate exchange, the second air floating unit 70 can simply be driven upward (in the horizontal state), without being tilted initially.

### Fourth Embodiment

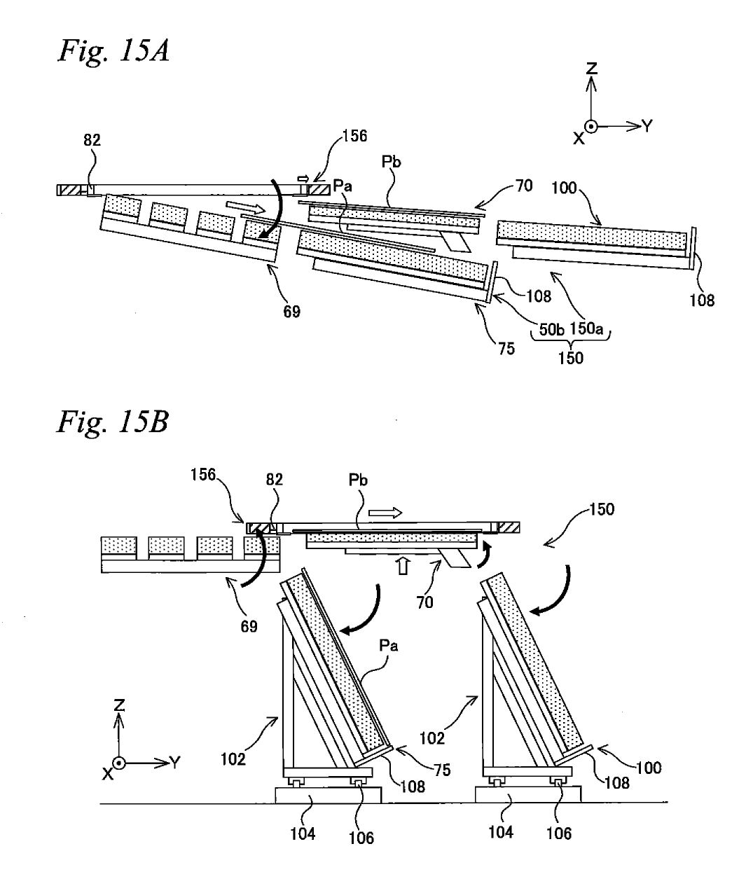

Next, a fourth embodiment will be described, with reference to FIGS. 15A and 15B. Here, points that are different from the first embodiment previously described will be explained, and the same or similar reference numerals will be used for the same or similar members as in the first embodiment previously described, and a description thereabout will be simplified or omitted.

In the liquid crystal exposure apparatus related to the fourth embodiment, as shown in FIG. 15A, the first air floating unit 69 is tiltable in the θx direction, and the second and the third air floating units 70 and 75 are placed on the +Y side of the first air floating unit 69. In a substrate exchanging device 150 that the liquid crystal exposure apparatus related to the fourth embodiment has, a substrate carry-in device 150a has a fourth air floating unit 100 successive to the second air floating unit 70 on the +Y side of the second air floating unit 70. Further, although the illustration is omitted, substrate carry-in device 150a has a substrate feeding device (the configuration is the same as substrate feeding device 73 related to each of the first to third embodiments) which carries a substrate from the fourth air floating unit 100 to the second air floating unit 70.

The operation at the time of substrate exchange of the liquid crystal exposure apparatus related to the fourth embodiment is substantially similar to the third embodiment described above, except for the movement direction of the substrate and substrate holding frame 156. However, in the fourth embodiment, the first air floating unit 69 is to be tilted in the θx direction so that an edge on the +Y side of first air floating unit 69 becomes lower than the edge on the -Y side. Therefore, when substrate Pa is carried out from substrate holding frame 156, all four support sections 82 do not have to be withdrawn, and only support sections 82 on the +Y side have to be withdrawn in the +Y direction. Then, when substrate Pa is carried out, the first air floating unit 69 is tilted in the θx direction so that substrate Pa separates from support sections 82 on the −Y side.

The third and the fourth air floating units 75 and 100 are mounted individually on trucks 102, in a state each tilted in the θx direction, and being capable of running in the X-axis direction. Truck 102 is guided advancing straight in the X-axis direction by a guide member 106 extending in the X-axis direction that is fixed to a mounting 104. Incidentally, for example, truck 102 can also be capable of running in the Y-axis direction, as well as in the X-axis direction. Further, in FIG. 15B, while the tilt of the third and the fourth air floating units 75 and 100 when mounted on trucks 102 is greater than in the case of substrate exchange, the magnitude of this tilt angle is not limited in particular, and can be appropriately changed.

Further, in the fourth embodiment, as shown in FIG. 15A, to the edge in the downstream side of a substrate carry-out direction of the third air floating unit 75, a pushing member 108 which pushes the edge of the substrate is fixed, and as shown in FIG. 15B, prevents substrate Pa from sliding down the third air floating unit 75 tilted in the θx direction. Similarly, pushing member 108 is fixed to the edge in the upstream side of a substrate carry-in direction of the fourth air floating unit 100, and prevents stop substrate Pb from sliding down the fourth air floating unit 100 tilted in the θx direction.

In the fourth embodiment, after substrate Pa subject to carry-out is carried onto the third air floating unit 75 from above the first air floating unit 69 as shown in FIG. 15A, the third air floating unit 75 supporting substrate Pa is mounted on truck 102 waiting below, as shown in FIG. 15B. Then, after truck 102 has been moved to a predetermined X position (an X position different from the first air floating unit 69), substrate Pa is carried out from above the third air floating unit 75. Then, truck 102 on which the third air floating unit 75 was mounted, is moved to a position below (the same X position as the first air floating unit 69) the second air floating unit 70, and is prepared for the next carry-out of substrate Pa.

Meanwhile, substrate Pb subject to carry-in is loaded onto the fourth air floating unit 100 mounted on truck 102 at a predetermined X position (an X position different from the first air floating unit 69). Then, this truck 102 is moved to a position obliquely downward (the same X position as the first air floating unit 69) of the second air floating unit 70. Subsequently, after the fourth air floating unit 100 has been removed from truck 102, and the position of the fourth air floating unit 100 has been adjusted so that its upper surface is flush with the upper surface of the second air floating unit 70 as shown in FIG. 15A, substrate Pb is carried onto the second air floating unit 70 from above the fourth air floating unit 100. Then, substrate Pb is held by substrate holding frame 156 as in the third embodiment described above, and is carried onto the first air floating unit 69 from above the second air floating unit 70. The fourth air floating unit 100 is moved to the predetermined X position after being mounted on truck 102 waiting below, and then is prepared for the carry-in of the next substrate Pb.

According to the fourth embodiment, because substrate Pa subject to carry-out is mounted on truck 102 together with the third air floating unit 75 in a state of being supported by the third air floating unit 75, substrate Pa can be carried out quickly and easily to a predetermined position. Further, because substrate Pb subject to carry-in is carried in to the fourth air floating unit 100 mounted on truck 102 at a predetermined position, carriage preparation of substrate Pb onto the second air floating unit 70 from the fourth air floating unit 100 can be performed quickly.

Incidentally, in the fourth embodiment, while the third and the fourth air floating units 75 and 100 are each configured separately from trucks 102, for example, at least one of the third and the fourth air floating units 75 and 100 can be supported rotatable in the θx direction by truck 102.

Incidentally, the configuration of each of the first to fourth embodiments can be appropriately changed. For example, while the substrate exchanging device horizontally moves the substrate at the time of carry-in, and moves the substrate along the tilted surface at the time of carry-out of the substrate, the operation can be reversed. In this case, the next substrate Pb is prepared on the third air floating unit 75. Then, substrate Pa is carried out (substrate feeding device 73 as in the first embodiment described above can be used, or substrate holding frame 56 as in the second embodiment can be used) horizontally onto the second air floating unit 70 from above the first air floating unit 69, and subsequently, the next substrate Pb is carried (carried in) along a tilted surface (movement plane) formed by the upper surface of the first and third air floating units 69 and 75.

In each of the first to fourth embodiments described above, while the first and the third air floating unit 69 and 75 were each tilted so that the Z position on the +X side (or the +Y side) became lower than the Z position on the −X side (or the −Y side), as well as this, the substrate carry-out device can be placed above the substrate carry-in device, and the first and the third air floating units 69 and 75 can each be tilted so that the Z position on the −X side (or the −Y side) becomes lower than the Z position on the +X side (or +Y side).

In each of the first to fourth embodiments described above, while the second air floating unit 70 and the third air floating unit 75 were placed overlapping each other in the vertical direction, for example, the second air floating unit 70 can be placed on the +X side of the first air floating unit 69, and the third air floating unit 75 can be placed on the +Y side (or the −Y side) of the first air floating unit 69. In this case, the first air floating unit 69 rotates in the θx direction and the substrate which has been exposed is carried out to the third air floating unit 75 from the substrate holding frame, and an unexposed substrate is carried in from the second air floating unit 70 into the substrate holding frame. Further, the third air floating unit 75 can be placed on the +X side of the first air floating unit 69, and the second air floating unit 70 can be placed on the +Y side (or the −Y side) of the first air floating unit 69. In this case, the first air floating unit 69 rotates in the θy direction and the substrate which has been exposed is carried out to the third air floating unit 75 from the substrate holding frame, and an unexposed substrate is carried in from the second air floating unit 70 into the substrate holding frame.

In each of the first to fourth embodiments described above, while the first air floating unit 69 was driven upward when the hold of the substrate by the substrate holding frame was released in FIGS. 5A to 5C, in the substrate holding frame, the substrate can be delivered from support section 82 to the first air floating unit 69 by configuring support section 82 vertically movable, and vertically driving support section 82.

In each of the third and fourth embodiments described above, while the position of the second air floating unit 70 is located at the position deviated from the movement path of substrate holding frame 156, instead of this, or in addition to this, by making the Z position of substrate holding frame 156 adjustable, substrate holding frame 156 can be kept from colliding or coming into contact with substrate Pb and the second air floating unit 70.

In each of the first to fourth embodiments described above, while support section 82 is withdrawn in a state where the first air floating unit 69 driven upward and substrate Pa is separated from support section 82, if frictional resistance between substrate Pa and support section 82 is low (in other words, if the frictional resistance does not cause any damage to the substrate), support section 82 can be withdrawn in a state where substrate Pa is in contact with support section 82, without driving the first air floating unit 69 upward.

In each of the first and second embodiments described above, while substrate Pb on the second air floating unit 70 is carried in to substrate holding frame 56 on the first air floating unit 69, or substrate Pb held by substrate holding frame 56 on the second air floating unit 70 is carried to the first air floating unit 69 together with substrate holding frame 56 after the first air floating unit 69 has been shifted from a tilted state to a horizontal state, as well as this, for example, substrate Pb can be carried in to substrate holding frame 56 by carrying the second air floating unit 70 holding substrate Pb onto the first air floating device 69, while the first air floating unit 69 remains in a tilted state.

### Fifth Embodiment

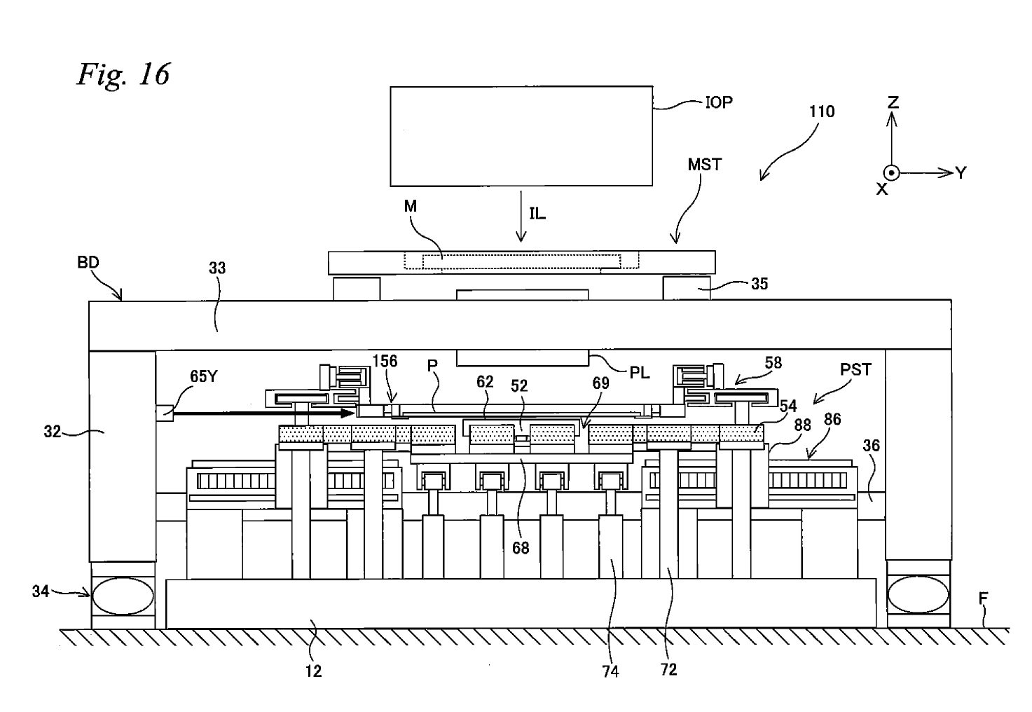

Next, a fifth embodiment will be described, with reference to FIGS. 16 to 22. Herein, the same or similar reference numerals will be used for the same or similar members as in the first embodiment described above, and a description thereabout will be simplified or omitted.

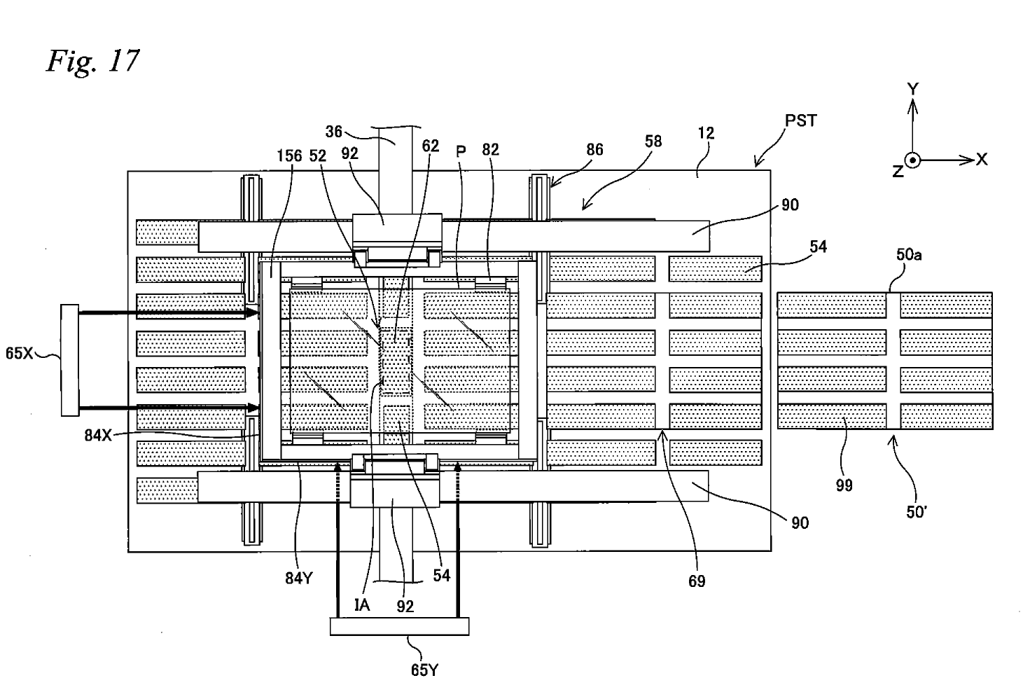

FIG. 16 schematically shows a configuration of a liquid crystal exposure apparatus 110 related to the fifth embodiment, and FIG. 17 shows a planar view of a substrate stage device which the liquid crystal exposure apparatus 110 has. As it can be seen when comparing FIGS. 16 and 17 to FIGS. 1 and 2, liquid crystal exposure apparatus 110 is generally configured similar to liquid crystal exposure apparatus 10. However, as shown in FIGS. 16 and 17, in liquid crystal exposure apparatus 110, as the substrate holding frame, a substrate holding frame 156 consisting of a frame shaped member which has a rectangular shape in a planar view and is similar to the one that the liquid crystal exposure apparatuses related to the third and fourth embodiment previously described have is provided, and corresponding to this, configuration and the like of the substrate exchange device and the like differs partially from exposure apparatus 10 of the first embodiment previously described. The description below will focus on points that differ from the first embodiment previously described.

First of all, substrate holding frame 156 will be described.

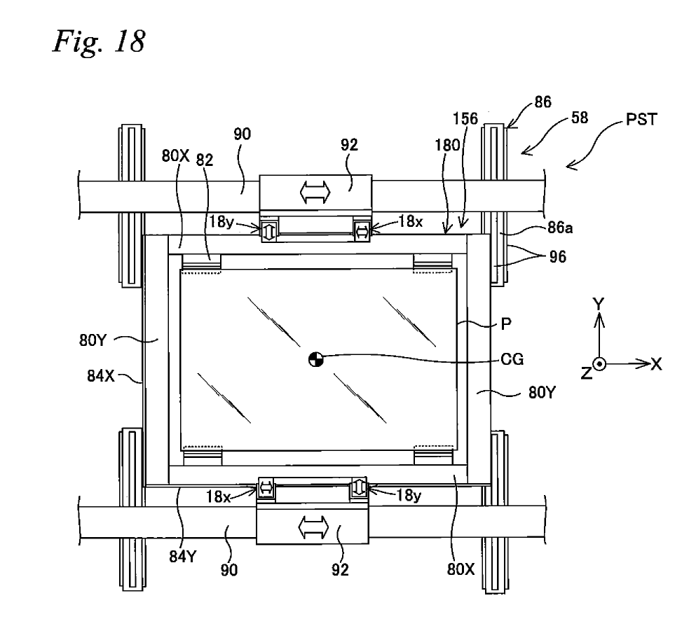

As shown in FIG. 18, substrate holding frame 156 includes a main section 180 consisting of a frame shaped member having a rectangular shape in a planar view, and a plurality of, as an example, four support sections 82 which support substrate P from below. Main section 80 has a pair of X frame members 80X and a pair of Y frame members 80Y. The pair of X frame members 80X each consist of a plate shaped member parallel to the XY plane and whose longitudinal direction is in the X-axis direction, and is placed parallel at a predetermined distance (a distance longer than the dimension in the Y-axis direction of substrate P) in the Y-axis direction. The pair of Y frame members 80Y each consist of a plate shaped member parallel to the XY plane and whose longitudinal direction is in the Y-axis direction, and is placed parallel at a predetermined distance (a distance larger than the dimension in the X-axis direction of substrate P) in the X-axis direction. Y frame member 80Y on the +X side connects the edges of the pair of X frame member 80X on the +X side, and Y frame member 80Y on the −X side connects the edges of the pair of X frame member 80X on the −X side. To the side surface on the −Y side of X frame member 80X on the −Y side, a Y movable mirror 84Y having a reflection surface which is orthogonal to the Y-axis is attached, and to the side surface on the −X side of Y frame member 80 on the −X side, an X movable mirror 84 having a reflection surface orthogonal to the X-axis is attached.

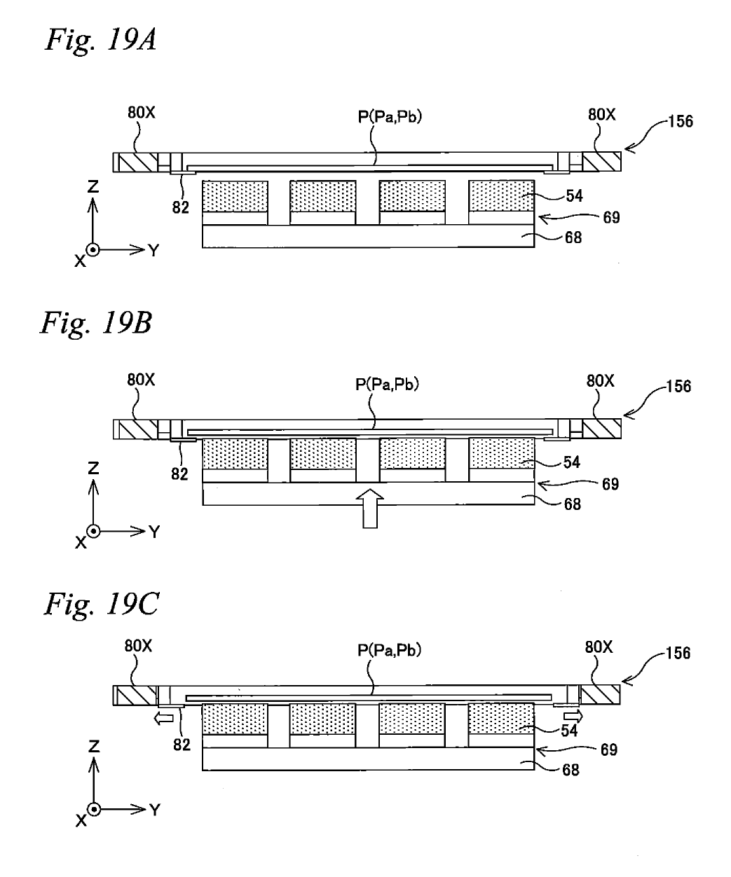

Two of the four support sections 82 are attached to X frame member 80X on the −Y side, and the other two are attached to X frame member 80X on the +Y side, each spaced apart in the X-axis direction at a predetermined distance (a distance smaller than the dimension in the X-axis direction of the substrate). Support section 82 each consist of a member having an L-like shape in the YZ section (refer to FIG. 19A), and supports the substrate by a portion parallel to the XY plane from below. Each of the four support sections 82 are configured in the same manner as in the first embodiment previously described, and are movable in approaching and separating directions with respect to X frame members 80X to which each support section is attached, as shown in FIGS. 19B and 19C via Y actuators 42 (refer to FIG. 7).

Substrate holding frame 156 configured in the manner described above supports substrate P equally by four support sections 82 as shown in FIG. 18, in a state where the pair of X frame members 80X and a pair of Y frame members 80Y surround the periphery of substrate P, for example, in the four corners (refer to FIG. 18) of substrate P. Therefore, substrate holding frame 156 can hold substrate P with good balance.

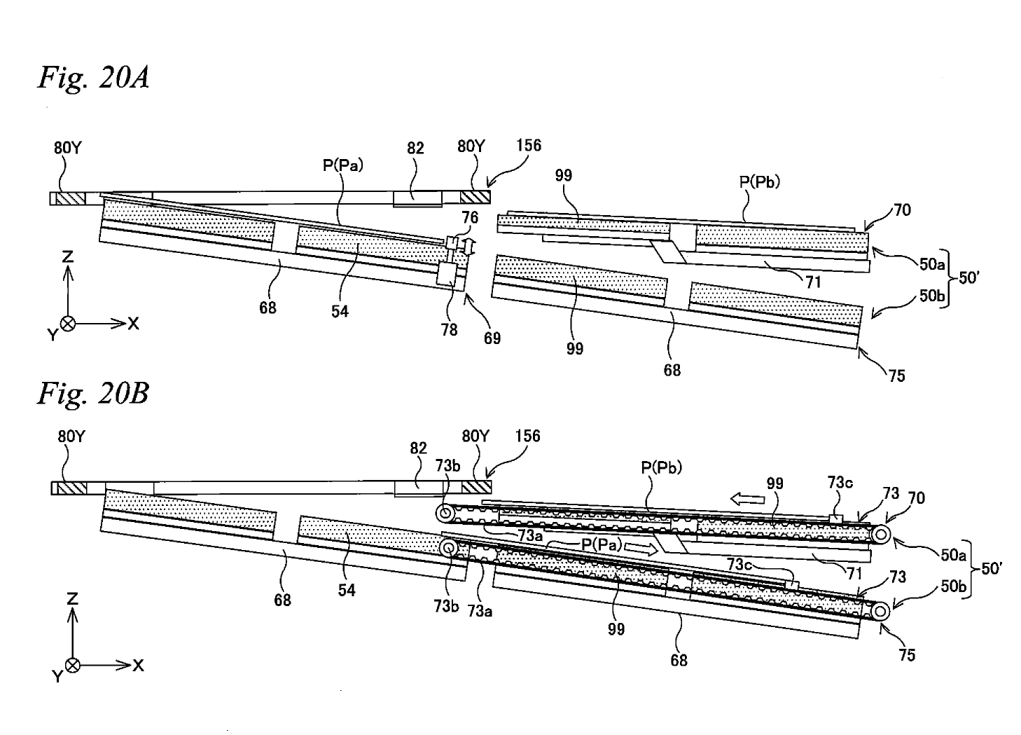

In liquid crystal exposure apparatus 110 related to the fifth embodiment, the first air floating unit 69 is configured similar to the first embodiment previously described, and is similarly movable in a vertical direction (refer to FIGS. 19A. to 19C) by the plurality of Z linear actuators 74 being driven (controlled) synchronously, for example, in a state where the upper surface of the eight air floating devices 54 are made parallel to a horizontal plane. Further, as shown in FIG. 20A, by the plurality of Z linear actuators 74 being appropriately driven (controlled), the first air floating unit 69 can change its attitude to a state where the Z position on the +X side is lower than the Z position on the −X side (a state where the upper surface is tilted in the θy direction with respect to the horizontal plane). In the description below, in the attitude of the first air floating unit 69, a state, for example, where the upper surface of the eight air floating devices 54 is parallel to the horizontal plane will be referred to as a horizontal state, and a state, for example, where the upper surface of the eight air floating devices 54 is tilted at a first angle (e.g., 15 degrees) with respect to the horizontal plane, and a second angle (e.g., 5 degrees) which is smaller than the first angle tilted in the θy direction will be referred to as a first tilted state and a second tilted stage, respectively.

Substrate exchanging device 50′ related to the fifth embodiment is placed on the +X side of surface plate 12, as shown in FIG. 17. Substrate exchanging device 50′, as shown in FIG. 20A is equipped with a substrate carry-in device 50a and a substrate carry-out device 50b (not illustrated in FIG. 17 because it is hidden under substrate carry-in device 50a) which is placed below carry-in device 50a.

Substrate carry-in device 50a includes a second air floating unit 70 having a function similar to the first air floating unit 69. The second air floating unit 70 has a plurality of (e.g., eight) air floating devices 99 (refer to FIG. 17) mounted on a base member 71. The upper surface of, for example, the eight air floating devices 99 that the second air floating unit 70 has is tilted at the second angle (e.g., degrees) to the θy direction with respect to a horizontal plane (XY plane) so that the Z position on the +X side is lower than the Z position on the −X side. Further, in a state shown in FIG. 20A, namely a state where substrate holding frame 156 is positioned on the first air floating unit 69, the second air floating unit 70 at a predetermined position obliquely downward to the +X side of substrate holding frame 156. This predetermined position and the first angle described above are set so that when substrate P mounted on the second air floating unit 70 is carried in to substrate holding frame 156 along the second air floating unit 70 as it will be described later on, substrate P is made to pass under Y frame member 80Y on the +X side and to be inserted in between the pair of X frame members 80X.

Further, as shown in FIG. 20B, substrate carry-in device 50a has a substrate feeding device 73 (not illustrated in figures other than FIG. 20B) which is configured similar to substrate carry-in device 50a related to the first embodiment previously described including belt 73a. When belt 73a is driven in a state where substrate P is mounted on the second air floating unit 70, substrate carry-in device 50a pushes substrate P by pad 73c and moves substrate P, for example, along the upper surface of the eight air floating devices 99 (pushes out substrate P which is on the second air floating unit 70 on to the first air floating unit 69).

Referring back to FIG. 20A, substrate carry-out device 50b includes a third air floating unit 75 that has a similar configuration and function as the first air floating unit 69. In other words, the third air floating unit 75 has a plurality of, for example, eight, air floating devices 99 mounted on base member 68. The upper surface of, for example, the eight air floating devices 99 that the third air floating unit 75 has is tilted at the first angle (e.g., 15 degrees) to the θy direction with respect to a horizontal plane (XY plane) so that the Z position on the +X side is lower than the Z position on the −X side. Further, as shown in FIG. 20B, substrate carry-out device 50b has substrate feeding device 73 whose configuration is similar to that of substrate carry-in device 50a described above. In substrate carry-out device 50b, because the speed of belt 73a is controlled in a state where pad 73c and substrate P are in contact, the speed of movement (sliding down) along the upper surface of, for example, the eight air floating devices 99 of substrate P by its self-weight is controlled.

In liquid crystal exposure apparatus 110 (refer to FIG. 16) which is configured as described above, loading of a mask on mask stage MST by a mask loader which is not illustrated, and loading of substrate P onto substrate stage device PST by substrate carry-in device 50a (not illustrated in FIG. 16, refer to FIG. 17) are performed under the control of main controller 20 (refer to FIG. 7). After that, main controller 20 executes alignment measurement using an alignment detection system that is not illustrated, and after the alignment measurement has been completed, an exposure operation by the step-and-scan method is performed.

Because the operation of substrate stage device PST at the time of the exposure operation described above is similar to liquid crystal exposure apparatus 10 related to the first embodiment previously described, the description thereabout is omitted.

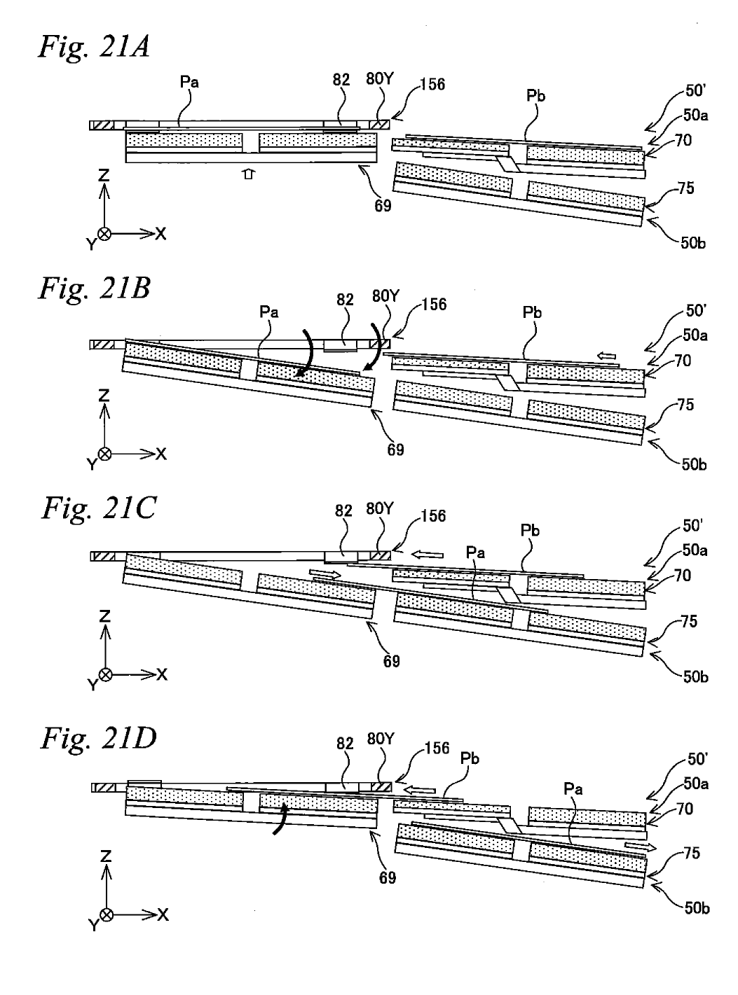

In liquid crystal exposure apparatus 110 related to the present embodiment, after the exposure operation by the step-and-scan method described above has been completed, exchange of substrate P held by substrate holding frame 156 is performed, by substrate P that has been exposed being carried out from substrate holding frame 156 and another substrate P being carried in to substrate holding frame 156. This exchange of substrate P is performed under the control of main controller 20. An example of an exchange operation of substrate P is described below, based on FIGS. 21A to 21D. Incidentally, to simplify the drawings, illustration of substrate feeding device 73 (refer to FIG. 20B) and the like is omitted in FIGS. 21A to 21D. Further, the substrate subject to carry-out from substrate holding frame 156 will be described as Pa, and the substrate subject to carry-in to substrate holding frame 156 will be described as Pb. As shown in FIG. 21A, substrate Pb is placed on the second air floating unit 70 of substrate carry-in device 50a.

After the exposure processing has been completed, by substrate holding frame 156 being driven, substrate Pa is positioned on the first air floating unit 69 as shown in FIG. 21A. At this point, as shown in FIG. 19A, the position of substrate holding frame 156 in the Y-axis direction is positioned so that air floating device 54 of first air surfacing unit 69 is not located below support section 82 of substrate holding frame 156 (not overlapping in a vertical direction). Then, substrate Pa held by suction by substrate holding frame 156 is released, and as shown in FIG. 19B, the first air floating unit 69 is finely driven in the +Z direction. By this, support section 82 is separated from substrate Pa, and in this state, support section 82 is driven in a direction separating from substrate Pa, as shown in FIG. 19C.

Subsequently, main controller 20 controls the attitude of the first air floating unit 69 so that the first air floating unit 69 shifts into the first tilted state described above, as shown in FIG. 21B. At this point, main controller 20 controls the plurality of Z linear actuators 74 (refer to FIG. 16) so that the upper surface of the first air floating unit 69 is located flush with the upper surface of the third air floating unit 75. Further, before changing the attitude of the first air floating unit 69, main controller 20 makes stopper 76 (refer to FIG. 20A) project upward from the upper surface of air floating devices 99, so as to prevent substrate P from sliding off along the top surface of the first air floating unit 69. Further, main controller 20 positions pad 73c which substrate feeding device 73 (not illustrated in FIG. 21B, refer to FIG. 20B) of the third air floating unit 75 has to the vicinity of the edge on the +X side of substrate Pa.

Further, concurrently with changing the attitude of the first air floating unit 69, main controller 20 controls the substrate feeding device 73 (not illustrated in FIG. 21B, refer to FIG. 20B) of substrate carry-in device 50a, and finely moves substrate Pb subject to carry-in in the −X direction.

When the upper surface of the first air floating unit 69 is positioned flush with the upper surface of the third air floating unit 75 as shown in FIG. 21B, main controller 20 stops attitude control of the first air floating unit 69 and then positions stopper 76 (refer to FIG. 20A) so that stopper 76 is positioned lower than the upper surface of air floating device 99. This makes an edge (the tip in the carry-out direction) on the +X side of substrate Pa come in contact with pad 73c of the third air floating unit 75 (refer to FIG. 20B).

Subsequently, main controller 20 carries the first substrate Pa from above the first air floating unit 69 along a tilted surface formed by the upper surface of the first and the third air floating units 69 and 75, and on to the upper surface of the third air floating unit 75, using substrate feeding device 73 (refer to FIG. 20B) of substrate carry-out device 50b, as shown in FIG. 21C. In other words, substrate Pa is carried out from substrate holding frame 156 obliquely downward to the +X side. Substrate Pa carried onto the third air floating unit 75 is carried to an external device such as, for example, a coater developer device by a substrate carrier device which is not illustrated.

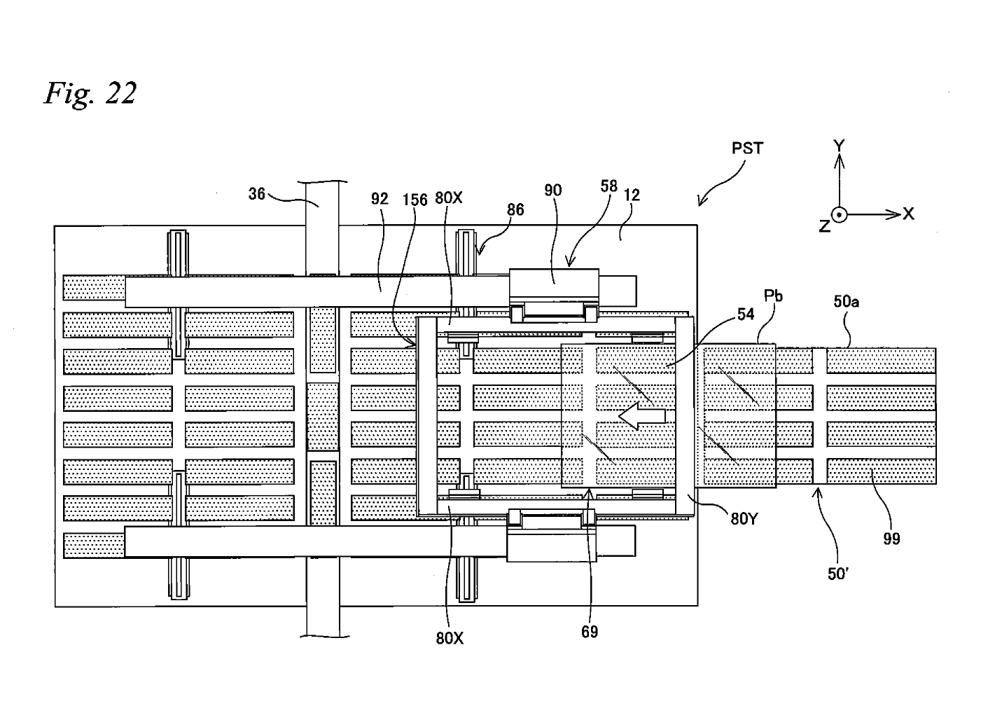

Further, when substrate Pa subject to carry-out is delivered to the third air floating unit 75, main controller 20 makes the attitude of the first air floating unit 69 shift from the first tilted state described above to the second tilted state described above, as shown in FIG. 21D. At this point, main controller 20 controls the plurality of Z linear actuators 74 (refer to FIG. 16) so that the upper surface of the first air floating unit 69 is located flush with the upper surface of the second air floating unit 70. Then, substrate Pb subject to carry-in is carried from the second air floating unit 70 to the first air floating unit 69, along a tilted surface (movement surface) formed by the upper surface of the first and second air floating units 69 and 70, using substrate feeding device 73 (refer to FIG. 203) of substrate carry-in device 50a. On this carriage, as shown in FIG. 22, substrate Pb is made to pass under Y frame member 80Y on the +Y side and to be inserted in between the pair of X frame members 80X. In other words, substrate Pb is carried in to substrate holding frame 156 obliquely from below, from the +X side. Then, after the attitude of the first air floating unit 69 has been shifted from the second tilted state described above to the horizontal state described above, substrate Pb is held by substrate holding frame 156 in a reverse order (in the order of FIGS. 19C to 19A) of FIGS. 19A to 19C. In the liquid crystal exposure apparatus 10 related to the present embodiment, by repeatedly performing the substrate exchange operation shown in FIGS. 21A to 21D above, exposure operation and the like is performed consecutively to a plurality of substrates.

As is described above, according to liquid crystal exposure apparatus 110 related to the fifth embodiment, an equivalent effect can be obtained as in the first embodiment previously described. Further, in the fifth embodiment, while substrate holding frame 156 which holds the substrate in a state surrounding the substrate on all four sides (periphery) is used, substrate Pb can be carried in into substrate holding frame 156 without substrate Pb being in contact with substrate holding frame 156, since substrate Pb is carried in within substrate holding frame 156 from the predetermined position obliquely below substrate holding frame 156 at the second angle described above. Further, because substrate Pa is carried out from within substrate holding frame 156, downward toward the predetermined direction and also at the first angle which is larger than the second angle described above with respect to the horizontal plane, substrate Pa can be carried out from substrate holding frame 156, without substrate Pa being in contact with substrate holding frame 156.

### Sixth Embodiment

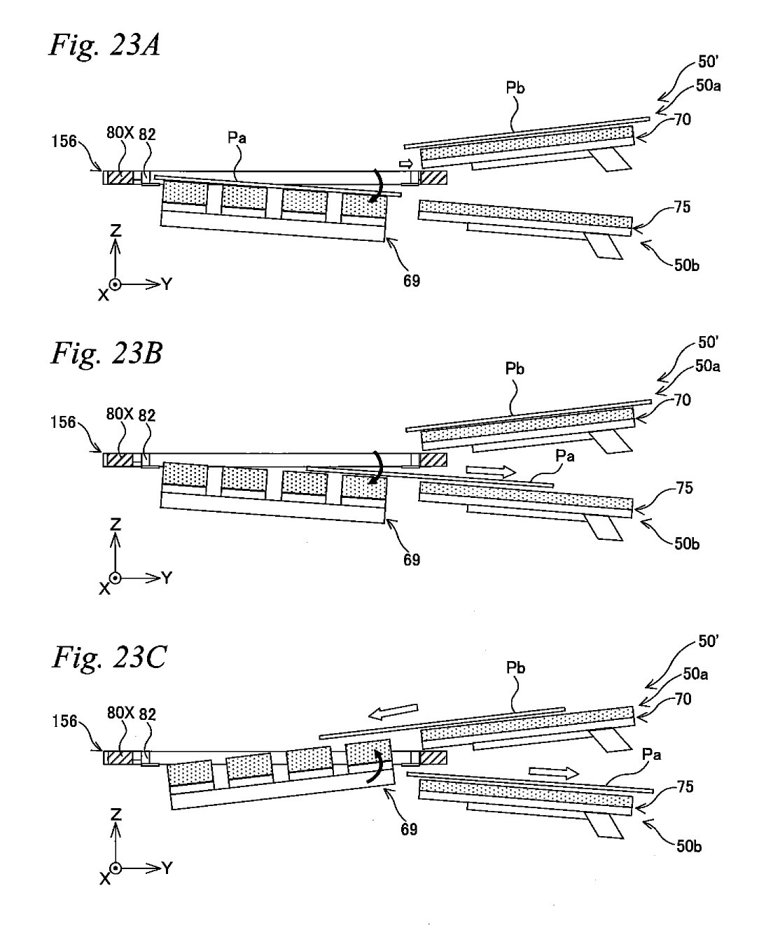

Next, a sixth embodiment will be described, with reference to FIGS. 23A to 23C. Here, points that are different from the fifth embodiment previously described will be explained, and the same or similar reference numerals will be used for the same or similar members as in the fifth embodiment previously described, and a description thereabout will be simplified or omitted.

In the fifth embodiment described above, while substrate Pa was carried out obliquely downward on the +X side from within substrate holding frame 156 and substrate Pb was carried in into substrate holding frame 156 obliquely from below on the +X side, in the sixth embodiment, substrate Pa is to be carried out obliquely downward on the +Y side from within substrate holding frame 156 and substrate Pb is to be carried in into substrate holding frame 156 obliquely from above on the +Y side.

In the liquid crystal exposure apparatus related to the sixth embodiment, the first air floating unit 69 is vertically movable by a plurality of Z linear actuators 74 (refer to FIG. 16), and as shown in FIGS. 23A to 23C, its attitude is shifted between a horizontal state (refer to the fifth embodiment described above), a third state in which the first air floating unit 69 is tilted at predetermined angle (e.g., 5 degrees) in the θx direction with respect to the horizontal plane so that the +Y side becomes lower than the −Y side, and a fourth state in which the first air floating unit 69 is tilted at predetermined angle (e.g., 5 degrees) in the θx direction with respect to the horizontal plane so that the +Y side becomes higher than the −Y side. Further, the second air floating unit 70 is placed obliquely above on the +Y side of substrate holding frame 156 which is positioned above the first air floating unit 69, in a state tilted at a predetermined angle (e.g., five degrees) to the θx direction with respect to the horizontal plane, so that the +Y side is higher than the −Y side. Further, the third air floating unit 75 is placed obliquely below on the +Y side of substrate holding frame 156 which is positioned above the first air floating unit 69, in a state tilted at a predetermined angle (e.g., five degrees) to the θx direction with respect to the horizontal plane, so that the +Y side is lower than the −Y side.

Further, to the edge (in the downstream side of a substrate carry-out direction) of the second air floating unit 70, a stopper similar to stopper 76 of the first air floating unit 69 is provided, which prevents substrate Pb from sliding down from the second air floating unit 70 at the time besides the carry-in of the substrate, and at the time when the substrate is carried in, movement of substrate Pb from the second air floating unit to the first air floating unit 69 is allowed.

In the sixth embodiment, in the case of substrate exchange, after holding by adsorption of substrate Pa subject to carry-out by substrate holding frame 156 has been released on the first air floating unit 69, as shown in FIG. 23A, the first air floating unit 69 is shifted from the horizontal state described above to the third tilted state. At this point, similar to the fifth embodiment described above, the upper surface of the first air floating unit 69 is to be located flush with the upper surface of the third air floating unit 75. Then, as shown in FIG. 23B, substrate Pa is carried from above the first air floating unit 69 onto the third air floating unit 75, as in the fifth embodiment described above. Subsequently, as shown in FIG. 23C, the first air floating unit 69 is shifted from the third tilted state described above to the fourth tilted state described above. At this point, similar to the fifth embodiment described above, the upper surface of the first air floating unit 69 is to be located flush with the upper surface of the second air floating unit 70. Then, substrate Pb subject to carry-in is carried onto the first air floating unit 69 from above the second air floating unit 70, as in the fifth embodiment described above. Then, after the attitude of the first air floating unit 69 has been shifted from the fourth tilted state described above to the horizontal state described above, substrate Pb is held by substrate holding frame 156 in a reverse order of FIGS. 19A to 19C. Then, substrate holding frame 156 holding substrate Pb is driven to the −X side. Hereinafter, alignment measurement and exposure operation by the step-and-scan method are performed.

As discussed above, according to the sixth liquid crystal exposure apparatus related to the embodiment, because substrate Pa is carried out from substrate holding frame 156 obliquely downward and substrate Pb is carried in into substrate holding frame 156 obliquely from above, the self-weight of the substrate can be utilized in either case on carry-out of substrate Pa and carry-in of substrate Pb, which reduces the drive load applied to substrate feeding device 73 of both substrate carry-in device 50a and substrate carry-out device 50b.

### Seventh Embodiment

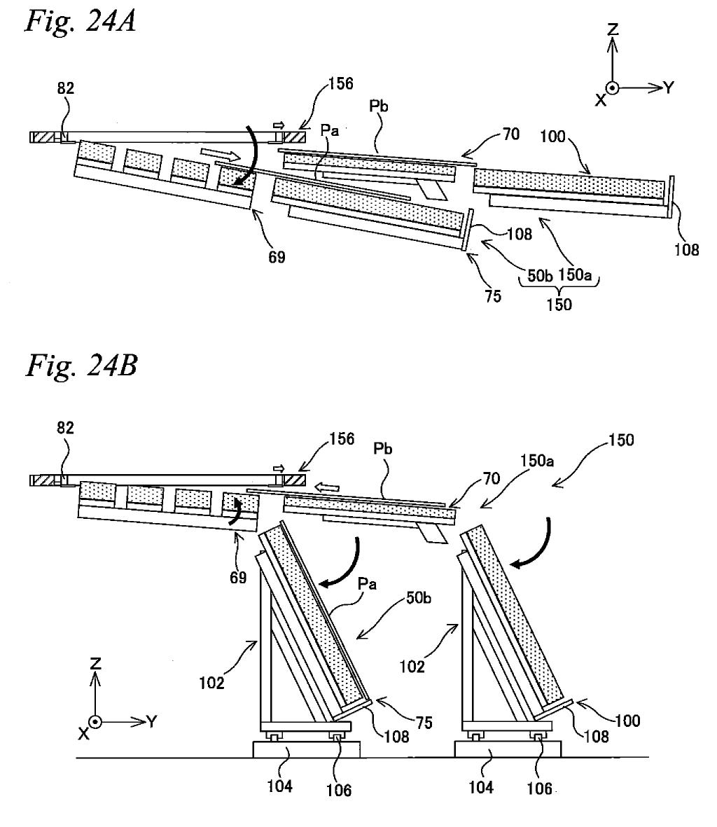

Next, a seventh embodiment will be described, with reference to FIGS. 24A and 24B. Here, points that are different from the fifth embodiment previously described will be explained. Further, the same or similar reference numerals will be used for the same or similar members as in the fifth embodiment and the fourth embodiment described above, and a description thereabout will be simplified or omitted.

In the seventh embodiment, when compared to the fifth embodiment described above, the point where substrate Pa is carried out from within substrate holding frame 156 obliquely downward on the +Y side, and the point where substrate Pb is carried in to substrate holding frame 156 obliquely from below on the +Y side differ.

In the seventh embodiment, as shown in FIG. 24A, the first air floating unit 69 is vertically movable by a plurality of Z linear actuators 74 (refer to FIG. 16), and its attitude is shifted between the horizontal state (refer to the fifth embodiment described above), the third state (refer to the sixth embodiment described above), and a state tilted at a predetermined angle (e.g., 15 degrees) to the θx direction with respect to a horizontal plane so that the +Y side becomes lower than the −Y side.

Further, in the seventh embodiment, the second air floating unit 70 is placed obliquely below on the +Y side of substrate holding frame 156 which is on the first air floating unit 69, in a state tilted at a predetermined angle (e.g., five degrees) to the θx direction with respect to the horizontal plane, so that the +Y side is lower than the −Y side. The third air floating unit 75 is placed below the second air floating unit 69, in a state tilted at a predetermined angle (e.g., fifteen degrees) to the θx direction with respect to the horizontal plane, so that the +Y side becomes lower than the −Y side.

Further, because substrate exchanging device 150 related to the seventh embodiment is configured similar to the substrate exchanging device related to the fourth embodiment previously described, a detailed description thereabout will be omitted.

The operation at the time of substrate exchange of the liquid crystal exposure apparatus related to the seventh embodiment is substantially similar to the fifth embodiment described above, except for the carriage direction of the substrate. However, in the seventh embodiment, the first air floating unit 69 is tilted in the θx direction so that the edge on the +Y side of the first air floating unit 69 becomes lower than the edge on the −Y side. Therefore, when substrate Pa. is carried out from substrate holding frame 156, all four support sections 82 do not have to be withdrawn, and only support sections 82 on the +Y side have to be withdrawn in the +Y direction. Then, when substrate Pa is carried out, the first air floating unit 69 is tilted in the θx direction so that substrate Pa separates from support sections 82 on the −Y side.

In the seventh embodiment, in the case of substrate exchange, similar to the fifth embodiment described above, after substrate Pa subject to carry-out is carried onto the third air floating unit 75 from the first air floating unit 69 as shown in FIG. 24A, the third air floating unit 75 supporting substrate Pa is mounted on truck 102 waiting below, as shown in FIG. 24B. Then, after truck 102 has been moved to a predetermined X position (an X position different from the first air floating unit 69), substrate Pa is carried out from above the third air floating unit 75. Subsequently, truck 102 on which the third air floating unit 75 was mounted, is moved to a position below (the same X position as the first air floating unit 69) the second air floating unit 70, and is prepared for the next carry-out of substrate Pa.

Meanwhile, substrate Pb subject to carry-in is loaded onto the fourth air floating unit 100 mounted on truck 102 at a predetermined X position (an X position different from the first air floating unit 69). Then, this truck 102 is moved to a position obliquely downward (the same X position as the first air floating unit 69) of the second air floating unit 70. Subsequently, after the fourth air floating unit 100 has been removed from truck 102 as shown in FIG. 24A, for example, by a crane device and the like which is not illustrated, and the position of the fourth air floating unit 100 has been adjusted so that its upper surface is flush with the upper surface of the second air floating unit 70, substrate Pb is carried onto the second air floating unit 70 from above the fourth air floating unit 100, along a along a tilted surface formed by the upper surface of the second and fourth air floating units 70 and 100. Then, as in the fifth embodiment described above, substrate Pb is carried onto the first air floating unit 69 from above the second air floating unit 70. The fourth air floating unit 100 is moved to the predetermined x position after being loaded on truck 102 waiting below, and then is prepared for the carry-in of the next substrate Pb.

As described so far, according to the seventh embodiment, because substrate Pa subject to carry-out is loaded on truck 102 together with the third air floating unit 75 in a state of being supported by the third air floating unit 75, substrate Pa which is supported by the third air floating unit 75 can be carried out quickly and easily to a predetermined position. Further, because substrate Pb subject to carry-in is supported by the fourth air floating unit 100 mounted on truck 102 at a predetermined position, carriage preparation of substrate Pb onto the second air floating unit 70 from the fourth air floating unit 100 can be performed quickly.

Incidentally, in the seventh embodiment, while the third and the fourth air floating units 75 and 100 are each configured separately from trucks 102, for example, at least one of the third and the fourth air floating units 75 and 100 can be supported rotatable in the θx direction by truck 102.

Incidentally, the configuration of each of the fifth to seventh embodiments can be appropriately changed. For example, in each of the fifth and seventh embodiments described above, while substrate exchanging devices 50′ or 150 carries the substrate at a different angle at the time of carry-in of the substrate and at the time of carry-out of the substrate, the substrate can be carried at the same angle. Specifically, the second air floating unit 70 and the third air floating unit 75 are placed tilted to the θy direction (or θx direction), so that the upper surfaces each become lower on the +X side than the −X side (or lower on the +Y side than the −Y side) and also become parallel to each other. Then, the attitude and position of the first air floating unit 69 is controlled so that the upper surface is located flush with the upper surface of the third air floating unit 75 at the time of carry-out of the substrate, and the attitude and position of the first air floating unit 69 is controlled so that the upper surface is located flush with the upper surface of the second air floating unit 70 at the time of carry-in of the substrate.

In each of the fifth and seventh embodiments described above, while substrate exchanging device 50′ or 150 carries out the substrate obliquely downward from on the first air floating unit 69, and the substrate is carried in obliquely from below onto the first air floating unit 69, instead of this, for example, the substrate can be carried out obliquely above from the first air floating unit 69, and the substrate can be carried in from obliquely above the first air floating unit 69. Specifically, the second and the third air floating units 70 and 75 are placed obliquely upward on the +X side (or the +Y side) of the first air floating unit 69, tilted to the θy direction (or θx direction) with respect to a horizontal plane so that the +X side becomes higher than the -X side (or the +Y side becomes higher than the −Y side). The tilt angle of the second and the third air floating units 70 and 75 with respect to the horizontal plane at this point can be different or the same. Further, because carriage of the substrate from on the first air floating unit 69 onto the third air floating unit 75 works against gravitational force, for example, a substrate feeding device (not illustrated) similar to substrate feeding device 73 is provided in the first air floating device 69, instead of the third air floating unit 75. Then, at the time of carry-out of the substrate, after the upper surface of the first air floating unit 69 has been made to be located flush with the third air floating unit 75, the substrate is carried out from on the first air floating unit 69 onto the third air floating unit 75, using the substrate feeding device. At the time of carry-in of the substrate, substrate Pb is carried from the second air floating unit 70 onto the first air floating unit 69 as in the sixth embodiment described above.

In each of the fifth and seventh embodiments described above, while substrate exchanging device 50′ or 150 carries out the substrate from the first air floating unit 69 at a large tilt angle (e.g., 15 degrees) with respect to a horizontal plane, and carries in the substrate onto the first air floating unit 69 at a small tilt angle (e.g., 5 degrees) with respect to a horizontal plane, this can be reversed.

In the sixth embodiment, while substrate exchanging device 50′ carries the substrate at the same angle (e.g., 5 degrees) with respect to the horizontal plane between the first air floating unit 69 and the second and the third air floating units 70 and 75, the substrates can be carried at a different angle.

In the sixth embodiment, while substrate exchanging device 50′ carries out the substrate from the first air floating unit 69 obliquely downward, and carries in the substrate onto the first air floating unit 69 from obliquely above, this can be reversed. Specifically, the substrate is carried out onto the second air floating unit 70 from the first air floating unit 69, and the substrate is carried in from the third air floating unit 75 onto the first air floating unit 69. In doing so, because the substrate is carried against gravitational force, a substrate feeding device similar to substrate feeding device 73 has to be provided in the first air floating device 69 so as to push the substrate toward the second air floating unit 70 side from the first air floating unit 69 side.

In each of the fifth to seventh embodiments described above, while the first air floating unit 69 was driven upward when the hold of the substrate by adsorption was released in FIGS. 19A to 19C, in substrate holding frame 156, the substrate can be delivered from support section 82 to the first air floating unit 69 by configuring support section 82 vertically movable, and vertically driving support section 82.

In each of the fifth to seventh embodiments described above, while support section 82 is withdrawn in a state where the first air floating unit 69 driven upward and substrate Pa is separated from support section 82, if frictional resistance between substrate Pa and support section 82 is low (in other words, if the frictional resistance does not cause any damage to the substrate), support section 82 can be withdrawn in a state where substrate Pa is in contact with support section 82, without driving the first air floating unit 69 upward.

In each of the fifth to seventh embodiments described above, the upper surface of the third air floating unit 75 which is located below the second air floating unit 70 whose upper surface is placed at a position slightly lower than the first air floating unit 69 is be tilted with respect to the horizontal plane larger than the upper surface of the second air floating unit 70. Accordingly, by simply making the first air floating unit 69 rotate around a predetermined axis extending in the Y-axis direction (or the X-axis direction), the upper surface of the first air floating unit 69 can be made flush with the upper surface of each of the second and third air floating units 70 and 75. Therefore, in the case the first air floating unit 69 does not have to move vertically (e.g., in the case frictional resistance between the substrate and the supporting section is low, or when employing a configuration where support section 82 is made to move vertically with respect to main section 180), a configuration can be employed where the first air floating unit 69 is made simply to rotate with a predetermined shaft member extending in the Y-axis direction (or the X-axis direction) serving as a supporting point. In this case, first air floating unit 69 can be controlled easily.

In the sixth embodiment, the second air floating unit 70 is placed on the +X side of the first air floating unit 69, above a horizontal plane including the upper surface of the first air floating unit 69 which is in the horizontal state, tilted to the θx direction so that the upper surface of the second air floating unit 70 becomes higher on the +Y side than on the −Y side. Further, the third air floating unit 75 is placed on the +X side of the first air floating unit 69, below a horizontal plane including the upper surface of the first air floating unit 69 which is in the horizontal state, tilted to the θx direction so that the upper surface of the third air floating unit 75 becomes lower on the +Y side than on the -Y side. Accordingly, when the upper surface of each of the second and third air floating units 70 and 75 are made symmetrical with respect to a horizontal plane including the upper surface of the first air floating unit 69 which is in the horizontal state described above, by simply making the first air floating unit 69 rotate around a predetermined axis extending in the Y-axis direction (or the X-axis direction), the upper surface of the first air floating unit 69 can be positioned flush with the upper surface of each of the second and third air floating units 70 and 75. Accordingly, in the case the first air floating unit 69 does not have to move vertically (e.g., in the case frictional resistance between the substrate and the supporting section is low, or when employing a configuration where support section 82 is made to move vertically with respect to main section 180), configuration can be employed where the first air floating unit 69 is made simply to rotate, with a predetermined shaft member extending in the Y-axis direction (or the X-axis direction) serving as a supporting point. In this case, the carriage angle of the substrate with respect to the horizontal plane between the first air floating unit 69 and the second air floating unit 70, and the first air floating unit 69 and the third air floating unit 75, can both be small, and on both the carry-in and the carry-out of the substrate, acceleration when the substrate moves by its self-weight can be reduced, and the speed can be controlled easily.

In each of the fifth to seventh embodiments described above, while the second air floating unit 70 and the third air floating unit 75 are placed overlapping each other in the vertical direction, for example, the second air floating unit 70 can be placed on the +X side of the first air floating unit 69, and the third air floating unit 75 can be placed on the +Y side (or the −Y side) of the first air floating unit 69. In this case, the first air floating unit 69 tilts to the ex direction and the substrate which has been exposed is carried out to the third air floating unit 75 from the substrate holding frame 156, and the first air floating unit 69 tilts to the θy direction and an unexposed substrate is carried in from the second air floating unit 70 into substrate holding frame 156. Further, the third air floating unit 75 can be placed on the +X side of the first air floating unit 69, and the second air floating unit 70 can be placed on the +Y side (or the −Y side) of the first air floating unit 69. In this case, the first air floating unit 69 is tilted to the θy direction and the substrate which has been exposed is carried out to the third air floating unit 75 from the substrate holding frame 156, and the first air floating unit 69 is tilted to the θx direction and an unexposed substrate is carried in from the second air floating unit 70 into substrate holding frame 156 .

In each of the fifth to seventh embodiments, while the shape of substrate holding frame 156 is a rectangular frame shaped member in a planar view placed surrounding the outer periphery of the substrate, as well as this, for example, the shape can be a rhomboidal frame shape in a planar view, an elliptical frame shape in a planar view placed along the periphery of the substrate and the like. Further, the shape of substrate holding frame 156, for example, can have a U-shape and the like which is placed along a part of the outer periphery of the substrate.

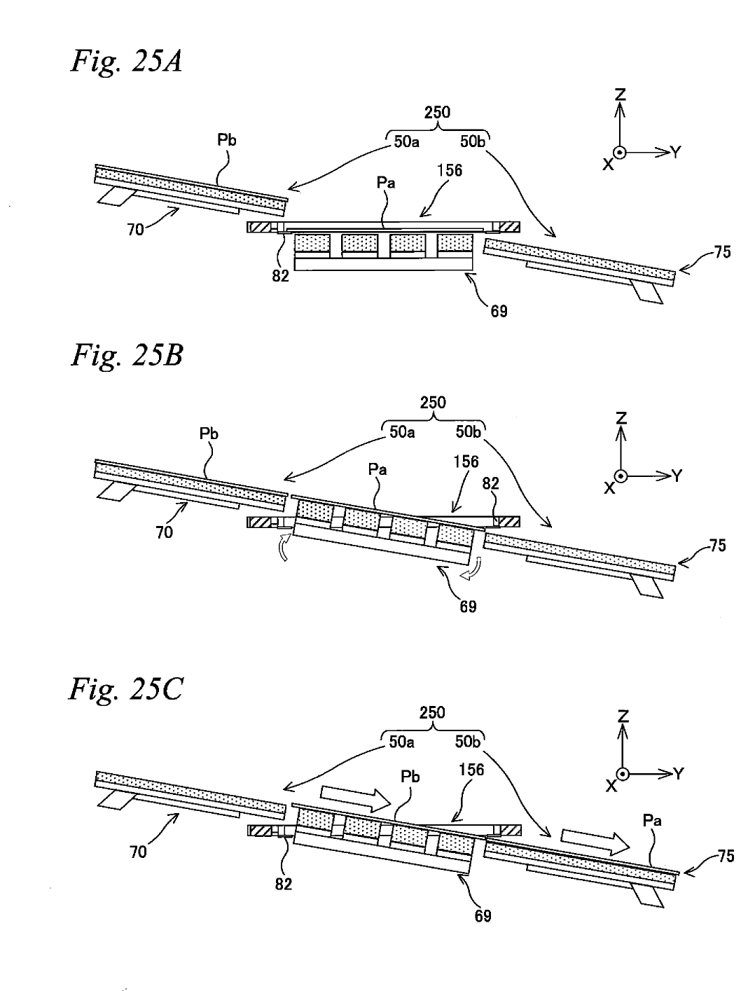

In the substrate exchanging device related to each of the fifth to seventh embodiments, while the carry-out path and the carry-in path of the substrate are along different planes, the paths can be along the same plane. A specific example will be described below. As shown in FIG. 25A, substrate exchanging device 250 is placed tilted to the θx direction with respect to the horizontal plane so that the third air floating unit 75 of substrate carry-out device 50b is placed obliquely downward on the -FY side of substrate holding frame 156, and the second air unit 70 is placed obliquely upward on the −Y side of substrate holding frame 156, so that the +Y side of each of the upper surfaces becomes lower than the −Y side, and are positioned flush with each other. Then, as shown in FIG. 25B, after the upper surface of the first air floating unit 69 is positioned to be flush with the upper surface of each of the second and third floating units 70 and 75, substrate Pa is carried out from above the first air floating unit 69 along this plane to above the third air floating unit 75, and substrate Pb is carried in along this plane from above the second air floating unit 70 to above the first air floating unit 69 as shown in FIG. 13C. Accordingly, the carry-out and the carry-in of the substrate can be performed concurrently (synchronously), and substrate exchange on the first air floating unit 69 can be performed extremely quickly.

Incidentally, in each of the first to seventh embodiments described above, while stopper 76, which prevents the substrate from sliding down when the first air floating unit 69 is tilted, is provided, as well as this, for example, the air floating device of the first air floating unit 69 can be configured so that gas suction can be performed together with gas ejection, and the air floating device holds the substrate by vacuum suction and the like.

In each of the first to seventh embodiments described above, while substrate feeding device 73 is provided to carry substrate Pa from above the first air floating unit 69 to above the third air floating unit 75, instead of this, for example, substrate Pa can be made to slide from above the first air floating unit 69 to above the third air floating unit 75 by its self-weight. In this case, it is desirable to have a stopper on the edge in the downstream side of the substrate carry-out direction of the third air floating unit 75 to prevent the substrate from sliding off from above the third air floating unit 75, as well as to keep the tilt angle of the third air floating unit 75 with respect to the XY plane as small as possible in order to suppress the impact from growing at the time of collision between the substrate and the stopper.

### Eighth Embodiment

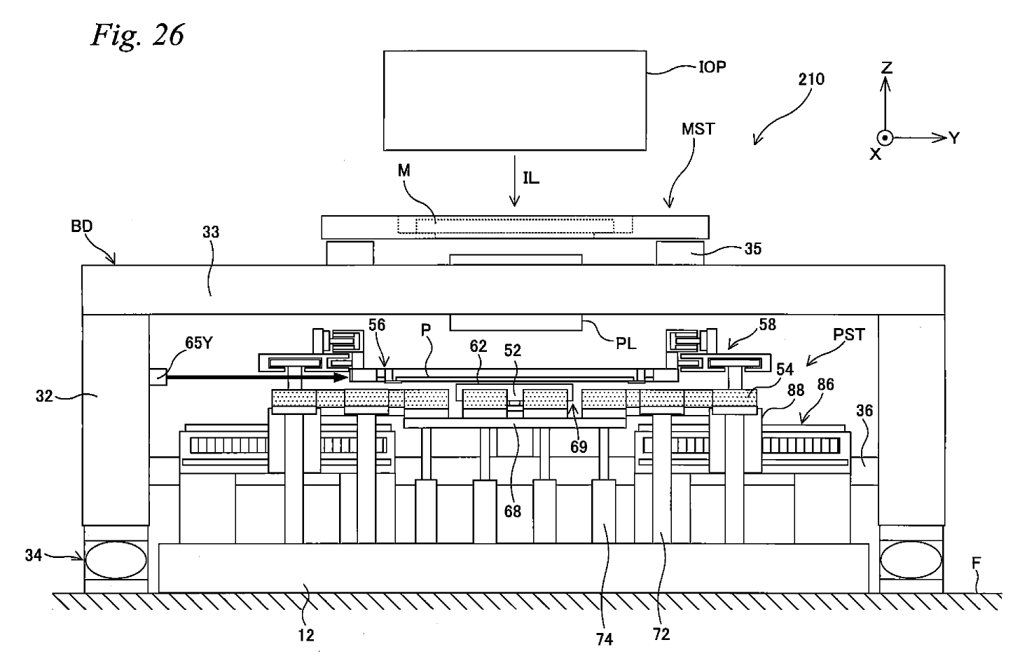

Next, an eighth embodiment will be described, with reference to FIGS. 26 to 30. Herein, the same or similar reference numerals will be used for the same or similar members as in the first embodiment described above, and a description thereabout will be simplified or omitted.

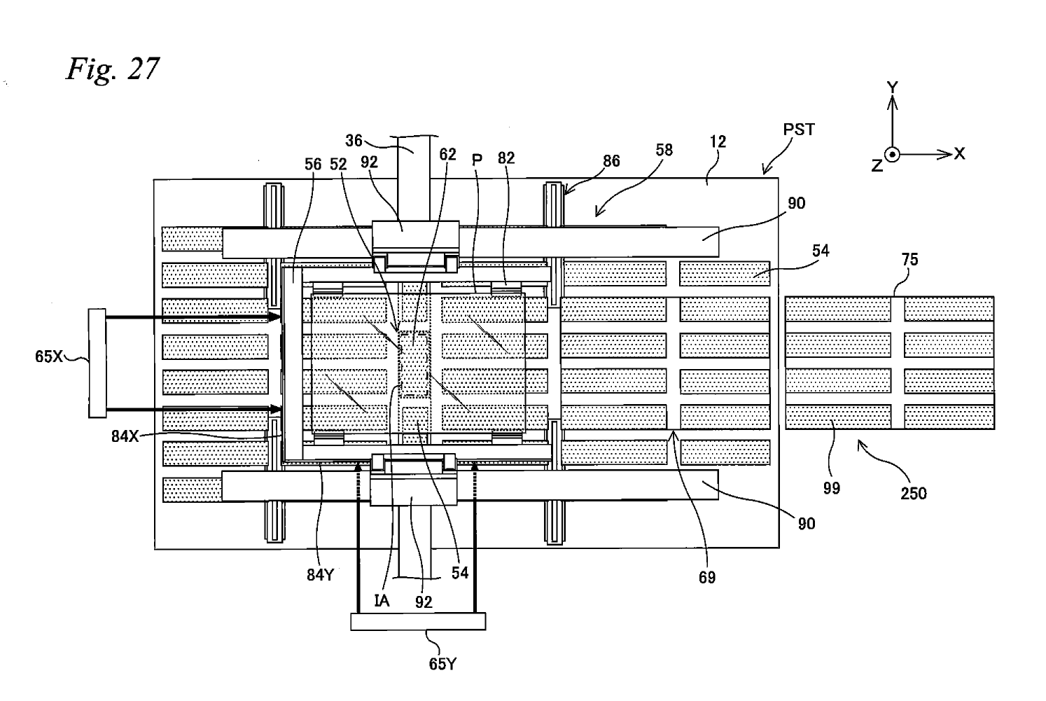

FIG. 26 schematically shows a configuration of a liquid crystal exposure apparatus 210 related to the eighth embodiment, and FIG. 27 shows a planar view of a substrate stage device which the liquid crystal exposure apparatus 210 has.

As it can be seen when comparing FIGS. 26 and 27 to FIGS. 1 and 2, liquid crystal exposure apparatus 210 related to the eighth embodiment is configured similar to liquid crystal exposure apparatus 10 related to the first embodiment previously described, except for substrate exchanging device 250.

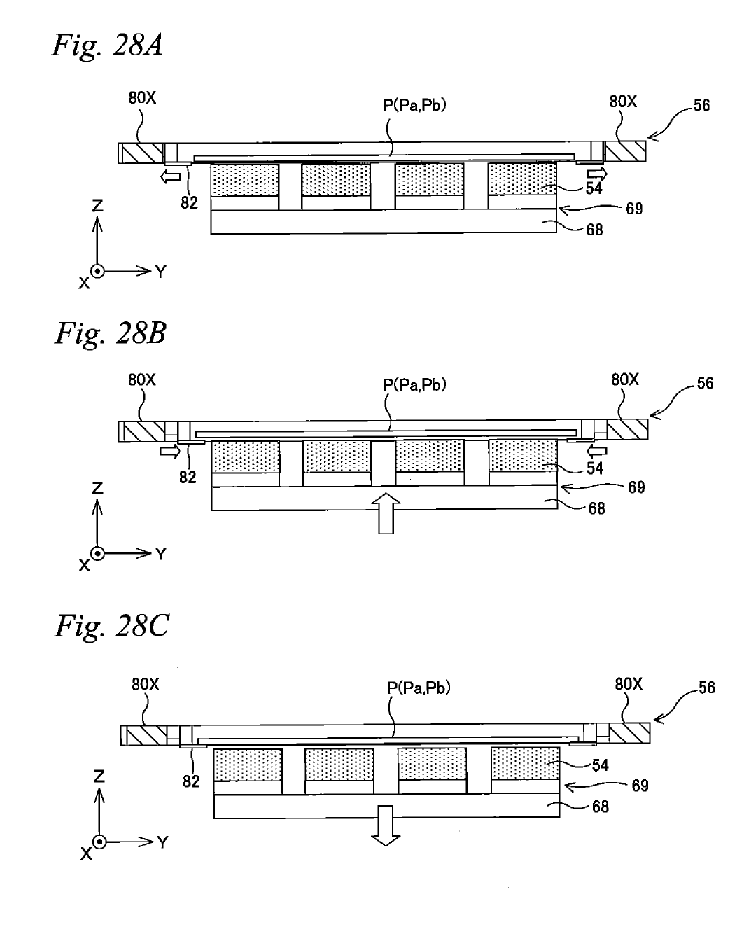

In liquid crystal exposure apparatus 210 related to the eighth embodiment, the first air floating unit 69 is configured similar to the first embodiment previously described, and is similarly movable in a vertical direction (refer to FIGS. 28A to 28C) by the plurality of Z linear actuators 74 being driven (controlled) synchronously, for example, in a state where the upper surface of the eight air floating devices 54 are positioned on the same horizontal plane. Hereinafter, a Z position of the first air floating unit 69 when the upper surface (the upper surface of the first air floating unit 69) of, for example, the eight air floating devices 54 of the first air floating unit 69 become positioned on the same horizontal plane as the upper surface of other air floating devices 54 on surface plate 12 will be referred to as a first position.

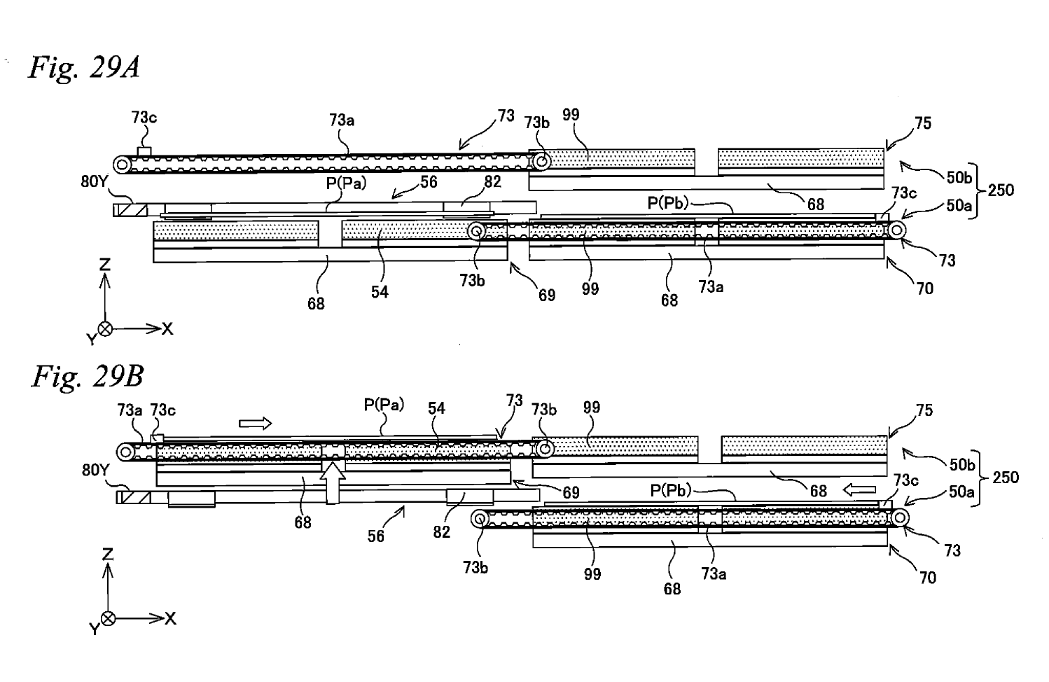

Substrate exchanging device 250 related to the eighth embodiment is a device which performs substrate exchange with the first air floating unit 69, and is equipped with a substrate carry-in device 50a and a substrate carry-out device 50b placed above substrate carry-in device 50a, as shown in FIG. 29A.

Substrate carry-in device 50a has a second air floating unit 70 having a similar configuration and function as the first air floating unit 69, on the +X side of the first air floating unit 69. In other words, the second air floating unit 70 has a plurality of (e.g., eight), air floating devices 99 mounted on base member 68. The upper surface, for example, of the eight air floating devices 99 that the second air floating unit 70 has, is positioned on the same horizontal plane as the upper surface (the upper surface of the first air floating unit 69) of the eight air floating devices 54 that the first air floating unit 69 has in a state shown in FIG. 29A, namely in a state where the first air floating unit 69 is located at the first position described above.

Further, as shown in FIGS. 29A and 29B, substrate carry-in device 50a has a substrate feeding device 73 (not illustrated in figures other than FIGS. 29A and 29B) which is configured similar to substrate carry-in device 50a related to the first embodiment previously described including belt 73a. When belt 73a is driven in a state where substrate P is mounted on the second air floating unit 70, substrate carry-in device 50a pushes substrate P by pad 73c and moves substrate P, for example, along the upper surface of the eight air floating devices 99 (pushes out substrate P which is on the second air floating unit 70 on to the first air floating unit 69).

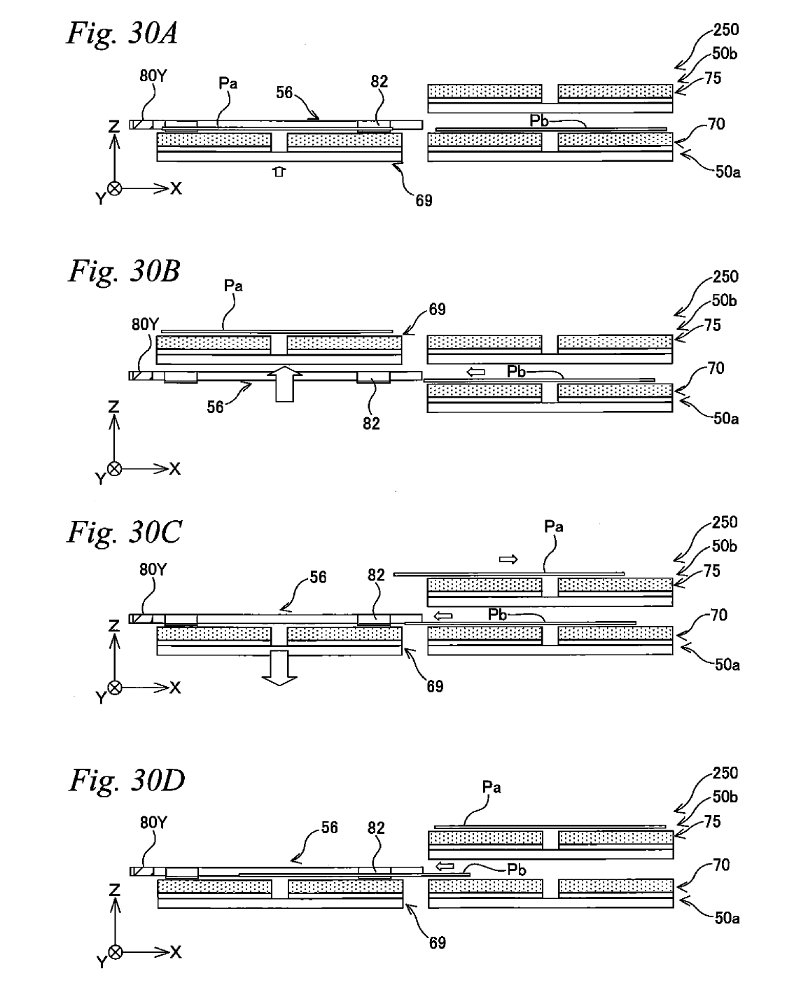

Substrate carry-out device 50b has a third air floating unit 75 that has a similar configuration and function as the first air floating unit 69, above (obliquely upward on the +X side of the first air floating unit 69) the second air floating unit 70. In other words, the third air floating unit 75 has a plurality of, e.g., eight, air floating devices 99 (refer to FIG. 27) mounted on a base member 68. The upper surface of, for example, the eight air floating devices 99 that the third air floating unit 75 has, is positioned on the same horizontal plane. The third air floating unit 75 is set so that the height of its upper surface is at the same height (refer to FIG. 30B) as the upper surface of the first air floating unit 69 positioned at a predetermined position (the second position described below) which is higher than substrate holding frame 56 as it will be described later on. Further, substrate carry-out device 50b has (refer to FIG. 293) a substrate feeding device 73 which is on the +Y side, and −Y side (or between the plurality of air floating devices 54) of the first air floating unit 69 (refer to FIG. 303) positioned at the second position to be described later on, having a configuration similar to substrate feeding device 73 of substrate carry-in device 50a.

In liquid crystal exposure apparatus 210 related to the eighth embodiment having the configuration described above, similar to the liquid crystal exposure apparatus 10 related to the first embodiment previously described, after preparatory operations such as loading of a mask on mask stage MST, loading of substrate P onto substrate stage device PST by substrate carry-in device 50a, and alignment measurement have been performed under the control of main controller 20 (refer to FIG. 7), exposure operation by the step-and-scan method is performed.

In liquid crystal exposure apparatus 210 related to the present embodiment, after the exposure operation by the step-and-scan method described above has been completed, exchange of substrate P held by substrate holding frame 56 is performed, by substrate P that has been exposed being carried out from substrate holding frame 56 and another substrate P being carried in to substrate holding frame 56. This exchange of substrate P is performed under the control of main controller 20. An example of an exchange operation of substrate P is described below, based on FIGS. 30A to 30D. Incidentally, to simplify the drawings, illustration of substrate feeding device 73 (refer to FIGS. 29A and 29B) and the like is omitted in FIGS. 30A to 30D. Further, the substrate subject to carry-out from substrate holding frame 56 will be described as Pa, and the substrate subject to carry-in to substrate holding frame 56 will be described as Pb. As shown in FIG. 29A, substrate Pb is mounted on the second air floating unit 70 of substrate carry-in device 50a in a state where the edge (the edge in the upstream side of the substrate carry-in direction) on the +X side is in contact with pad 73c of substrate feeding device 73 of substrate carry-in device 50a. Further, in this state, position adjustment on the second air floating unit 70 of substrate Pb is performed so that substrate Pb is positioned in between each of the pair of X frame members 80X of substrate holding frame 56 in the Y-axis direction.

After the exposure processing has been completed, by substrate holding frame 56 being driven in a direction parallel to the XY plane, substrate Pa is moved onto the first air floating unit 69 as shown in FIG. 30A. At this point, the position of substrate holding frame 56 in the Y axis direction is decided so that support section 82 of substrate holding frame 56 is not located above (not overlapping in the vertical direction) the first air floating unit 69 as shown in FIG. 28C, and then as shown in FIG. 30A, the position of substrate holding frame 56 in the X axis direction is decided so that Y frame member 80Y of substrate holding frame 56 is not located above (not overlapping in the vertical direction) the first air floating unit 69. Then, suction of substrate Pa by substrate holding frame 56 is canceled, and the first air floating unit 69 is driven in the +Z direction. At this point, the first air floating unit 69 supporting substrate Pa passes through within substrate holding frame 56 (between the pair of X frame members 80X) without coming in contact with substrate holding frame 56 (refer to FIG. 28B). Then, as shown in FIG. 30B, when the upper surface of the first air floating unit 69 becomes the same height as the upper surface of the third air floating unit 75, the first air floating unit 69 is stopped. Hereinafter, a Z position of the first air floating unit 69 when the upper surface of the first air floating unit 69 becomes the same height as the upper surface of the third air floating unit 75 will be referred to as a second position.

As shown in FIG. 29A, here, in substrate feeding device 73 of substrate carry-out device 50b, the X position of pad 73c is adjusted to be slightly on the −X side than the edge of substrate Pa on the −X side before the first air floating unit 69 is driven upward. Main controller 20 carries substrate Pa along a horizontal plane (movement plane) formed with the upper surface of the first air floating unit 69 and the upper surface of the third air floating unit 75, from above the first air floating unit 69 onto the third air floating unit 75 by substrate feeding device 73 of substrate carry-out device 50b. Main controller 20 drives the first air floating unit 69 in the -Z direction and positions the first air floating unit 69 at the first position describe above, and sends out substrate Pb by substrate feeding device 73 of substrate carry-in device 50a in the −X direction, before the entire substrate Pa is positioned onto the third air floating unit 75, as shown in FIG. 30C. This allows substrate Pb to be carried from above the second air floating unit 70 onto the first air floating unit 69, along a horizontal plane (movement plane) formed by the upper surface of the first air floating unit 69 and the upper surface of the second air floating unit 70, as shown in FIG. 30D. Prior to this carriage, here, as shown in FIG. 28A, two support sections 82 on the +Y side and the two support sections 82 on the −Y side are withdrawn (located at the withdrawal position described above) in the +Y direction and the −Y direction, respectively, and substrate Pb is carried in to substrate holding frame 56 on the first air floating unit 69 without coming into contact with support section 82. Incidentally, substrate Pa carried onto the third air floating unit 75 is carried to an external device such as, for example, a coater developer device by a substrate carrier device which is not illustrated.

Next, after finely driving the first air floating unit 69 supporting substrate Pb, main controller 20 drives the two support sections 82 on the +Y side and the two support sections 82 on the −Y side to the −Y direction and the +Y direction, respectively, and positions them at the support position described above, as shown in FIG. 28B. Then, after driving the first air floating unit 69 supporting substrate Pb downward, and making the four support sections 82 support substrate Pb while making the first air floating unit 69 support substrate Pb, main controller 20 makes substrate holding frame 56 hold substrate Pb by making the four support sections 82 vacuum chuck substrate Pb. Hereinafter, alignment measurement and exposure operation by the step-and-scan method are performed.

As described above, in liquid crystal exposure apparatus 210 related to the eighth embodiment, exposure operation and the like is performed consecutively to a plurality of substrates by repeatedly performing the substrate exchange operation shown in FIGS. 30A to 30D described above.

As is described so far, according to liquid crystal exposure apparatus 210 of the eighth embodiment, an equivalent effect can be obtained as in the first embodiment previously described. Further, according to the embodiment, by a simple configuration of placing the second and third air floating units 70 and 75 vertically overlapping each other and vertically moving the first air floating unit 69 with respect to the second and the third air floating units 70 and 75, substrate carriage between the first and second air floating units 69 and 70, and the first and third air floating units 69 and 75 can be performed. Furthermore, because the first air floating unit 69 simply has to be vertically moved between the first and second positions described above, the control is easy.

Further, because the upper surface of the second air floating unit 70 is positioned at the same height as the upper surface of the first air floating unit 69 at the first position, exposure processing can be started without vertically moving the first air floating unit 69, after the substrate is carried (carried in) from above the second air floating unit 70 onto the first air floating unit 69. In other words, the operation can shift from the substrate carry-in operation to the exposure operation quickly.

Further, because substrate holding frame 56 is positioned so that substrate holding frame 56 does not vertically overlap the first air floating unit 69 in the case of substrate exchange, substrate holding frame 56 does not have to be withdrawn when the first air floating unit 69 is moved vertically.

### Ninth Embodiment

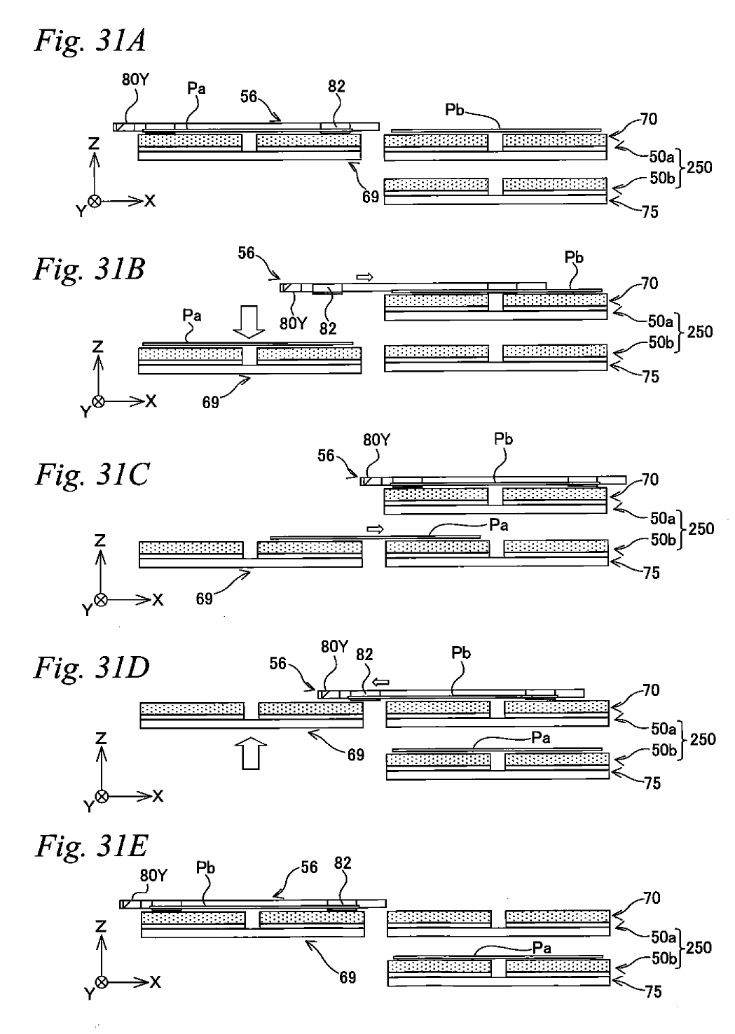

Next, a ninth embodiment will be described, with reference to FIGS. 31A to 31E. Here, points that are different from the eighth embodiment previously described will be explained, and the same or similar reference numerals will be used for the same or similar members as in the eighth embodiment previously described, and a description thereabout will be simplified or omitted.

In the eighth embodiment described above, while substrate carry-in device 50a carried substrate Pb to substrate holding frame 56 using substrate feeding device 73, in the liquid crystal exposure apparatus related to the ninth embodiment, as shown in FIGS. 31A to 31C, substrate holding frame 56 is driven onto the second air floating unit 70 of substrate carry-in device 50a, and substrate Pb is delivered to substrate holding frame 56 on the second air floating unit 70. Therefore, although it is not illustrated, a stator of the X linear motor used to drive substrate holding frame 56 in the X-axis direction is set longer only by a predetermined length to the +X side than in the first embodiment. Further, substrate carry-in device 50a does not have a substrate feeding device 73.

In substrate exchanging device 250 related to the ninth embodiment, the second air floating unit 70 of substrate carry-in device 50a is placed on the +X side of the first air floating unit 69, and the third air floating unit 75 of substrate carry-out device 50b is placed below (obliquely downward to the +X side of the first air floating unit 69) of the second air floating unit 70. The upper surface of the second air floating unit 70 is located at the same height as the upper surface of the first air floating unit 69 at the first position described above.

In the liquid crystal exposure apparatus related to the ninth embodiment, in the case of substrate exchange, first of all, holding of substrate Pa by substrate holding frame 56 is canceled (refer to FIG. 31A) on the first air floating unit 69 at the first position, as in the eighth embodiment described above. Subsequently, the first air floating unit 69 is driven downward, and substrate holding frame 56 is also driven in the +X direction (refer to FIG. 31B) by X linear motor 93 (refer to FIG. 7). Prior to substrate holding frame 56 being driven in the +X direction, here, as shown in FIG. 28A, four support sections 82 are located at the withdrawal position described above, and substrate holding frame 56 moves from above the first air floating unit 69 onto the second air floating unit 70 without coming into contact with substrate Pb, while inserting substrate Pb in between the pair of X frame members 80. Meanwhile, after the upper surface of the first air floating unit 69 is located at the same height as the upper surface of the third air floating unit 75, substrate Pa is carried (refer to FIG. 31C) from above the first air floating unit 69 onto the third air floating unit 75, as in the eighth embodiment described above.

In this case, although it is not illustrated, the second air floating unit 70 is configured finely drivable in the vertical direction, and substrate Pb is held by substrate holding frame 56 moved to (located) above the second air floating unit 70 as in the eighth embodiment. Then, after substrate Pa has been moved onto the third air floating unit 75 (to be more precise, after substrate Pa has been moved off from above the first air floating unit 69), the first air floating unit 69 is driven upward and is positioned to the first position, and substrate holding frame 56 holding substrate Pb is also driven to the −X side and is carried (refer to FIG. 31D) from above the second air floating unit 70 onto the first air floating unit 69 along a horizontal plane (movement plane) formed by the upper surface of the second air floating unit 70 and the upper surface of the first air floating unit 69. Substrate Pb carried onto the first air floating unit 69 is held (refer to FIG. 31E) by substrate holding frame 56 as in the first embodiment described above. Hereinafter, alignment measurement and exposure operation by the step-and-scan method are performed. Incidentally, substrate Pa carried onto the third air floating unit 75 is carried to an external device such as, for example, a coater developer device by a substrate carrier device which is not illustrated.

According to the liquid crystal exposure apparatus related to the ninth embodiment, because substrate Pb is carried to above the first air floating unit 69 in a state where substrate Pb is held by substrate holding frame 56 on the second air floating unit 70, substrate Pb can be moved quickly (in the eighth embodiment described above, carriage at a high speed is difficult because carriage is performed in a state where there is no restriction in the XY direction) compared with the case where a belt drive method is used as in the eighth embodiment described above. Accordingly, the cycle time of substrate exchange can be reduced when compared with the eighth embodiment described above.

Further, by simply extending stator 90 of the X linear motor in the X direction without changing the control system of substrate holding frame 56 and the measurement system with respect to the eighth embodiment described above (in other words, while suppressing cost increase), substrate holding frame 56 can be moved onto the second air floating unit 70. Further, substrate feeding device 73 does not have to be provided in substrate carry-in device 50a.

### Tenth Embodiment

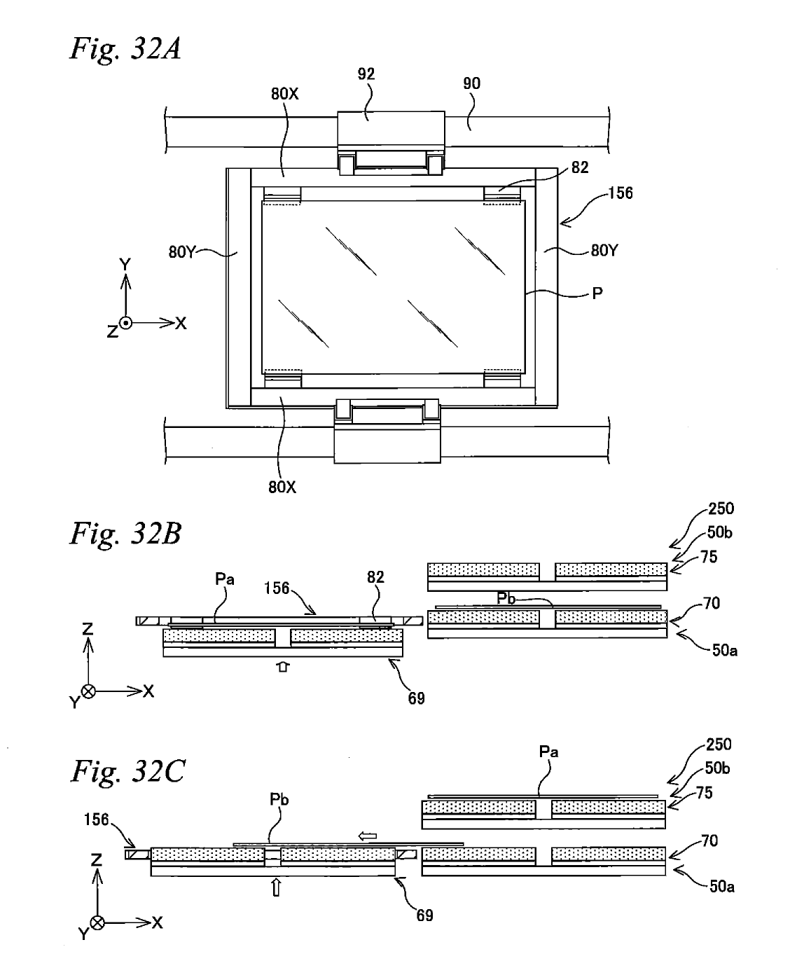

Next, a tenth embodiment will be described, with reference to FIGS. 32A to 32C. Here, points that are different from the eighth embodiment previously described will be explained, and the same or similar reference numerals will be used for the same or similar members as in the eighth embodiment previously described, and a description thereabout will be simplified or omitted.

The liquid crystal exposure apparatus related to the tenth embodiment has substrate holding frame 156 previously described as the substrate holding frame, as shown in FIG. 32A. Rigidity of substrate holding frame 156 is higher than that of substrate holding frame 56. Substrate holding frame 156 supports substrate P by four support sections 82, in a state where the pair of X frame members 80X and a pair of Y frame members 80Y surround substrate P on all four sides (periphery).

Further, in the tenth embodiment, as shown in FIG. 32B, the second air floating unit 70 is placed at the position where the upper surface is at a position higher than substrate holding frame 156.

In the liquid crystal exposure apparatus related to the tenth embodiment, in the case of substrate exchange, as shown in FIG. 32B, the first air floating unit 69 supporting substrate Pa is driven upward and is positioned at the second position described above, after the holding of substrate Pa by substrate holding frame 156 is released on the first air floating unit 69 as in the eighth embodiment described above. Then, after substrate Pa has been carried from above the first air floating unit 69 onto the third air floating unit 75, the first air floating unit 69 is driven downward. Then, as shown in FIG. 32C, when the upper surface of the first air floating unit 69 comes to the same height as the upper surface of the second air floating unit 70 (the Z position of the first air floating unit 69 at this point will be referred to as a third position), the first air floating unit 69 is stopped, substrate Pb is carried from above the second air floating unit 70 to the first air floating unit 69 as in the eighth embodiment described above. Subsequently, the first air floating unit 69 supporting substrate Pb is driven downward to be positioned at the first position, and substrate Pb is held by substrate holding frame 156 as in the eighth embodiment described above. Hereinafter, alignment measurement and exposure operation by the step-and-scan method are performed. Incidentally, substrate Pa carried onto the third air floating unit 75 is carried to an external device such as, for example, a coater developer device by a substrate carrier device which is not illustrated.

As described above, in the tenth embodiment, the substrate cannot be carried in directly into substrate holding frame 156 by relatively moving substrate holding frame 156 and substrate a horizontal direction because substrate holding frame 156 holds the substrate in a state where all four sides (periphery) of the substrate is surrounded, which is different from each of the eighth and ninth embodiments described above. Therefore, in the tenth embodiment, the carriage path of the substrate between the first and second air floating units 69 and 70 is set at a position away from the Z position of substrate holding frame 156 as is described above, and by vertically moving the first air floating unit with respect to substrate holding frame 156, the substrate can be carried in into substrate holding frame 156.

### Eleventh Embodiment

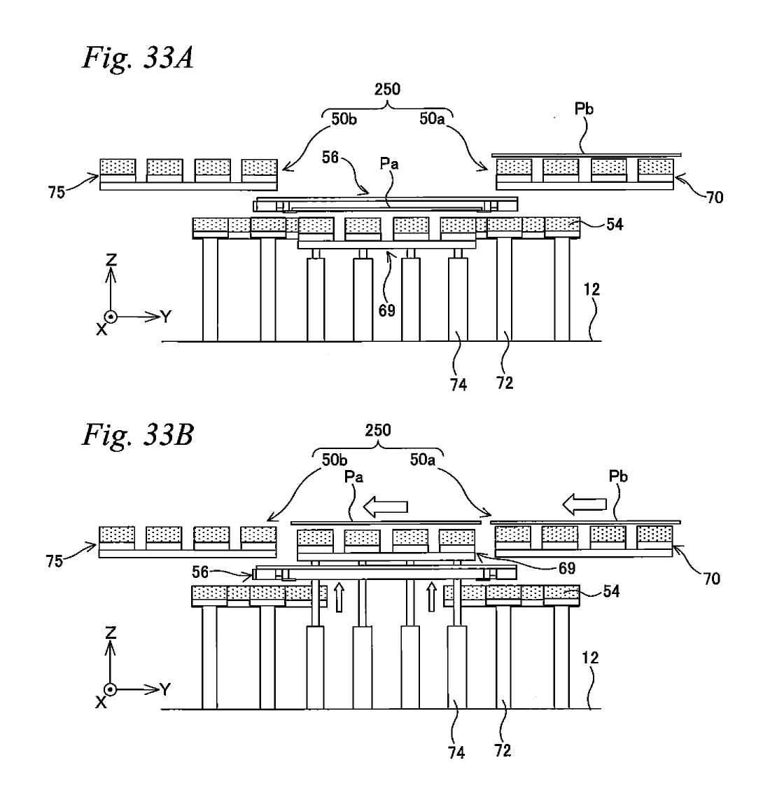

Next, an eleventh embodiment will be described, with reference to FIGS. 33A and 33B. In each of the eighth to tenth embodiments described above, while the height of the carry-in path and the carry-out path of the substrate is different, in the eleventh embodiment, the height of the carry-in path and the carry-out path of the substrate is set to the same height as shown in FIG. 33A.

In substrate exchanging device 250 related to the eleventh embodiment, as shown in FIG. 33A, the second air floating unit 70 of substrate carry-in device 50a and the third air floating unit 75 of substrate carry-out device 50b are placed obliquely upward to the +Y side and the −Y side of substrate holding frame 56, respectively, and are also placed so that each of the upper surfaces are located on the same horizontal plane.

In the liquid crystal exposure apparatus related to the eleventh embodiment, in the case of substrate exchange, the first air floating unit 69 (refer to FIG. 33A) supporting substrate Pa is driven upward after the holding of substrate Pa by substrate holding frame 56 has been released, and the first air floating unit 69 is positioned (refer to FIG. 33B) in between the second and third air floating units 70 and 75 so that its upper surface becomes the same height (located on the same horizontal plane) as the upper surface of the second and third air floating units 70 and 75. Then, carriage of substrate Pa from above the first air floating unit 69 onto the third air floating unit 75 begins as in the eighth embodiment described above, and at the same time, carriage substrate Pb from above the second air floating unit 70 onto the first air floating unit 69 begins as in the eighth embodiment described above. The carriage speed of substrate Pa and the substrate Pb is set the same, and substrate Pa and substrate Pb are carried in the same direction (the −Y direction in FIG. 33A) while keeping a constant distance (with substrate Pb following substrate Pa). Subsequently, the first air floating unit 69 supporting substrate Pb is driven downward and is positioned at the first position described above, and substrate Pb is held by substrate holding frame 56 as in the eighth embodiment described above. Hereinafter, alignment measurement and exposure operation by the step-and-scan method are performed. Incidentally, substrate Pa carried onto the third air floating unit 75 is carried to an external device such as, for example, a coater developer device by a substrate carrier device which is not illustrated.

According to the liquid crystal exposure apparatus related to the eleventh embodiment, in the case of substrate exchange, because the first air floating unit 69 is positioned at a position adjacent to both the second and the third air floating units 70 and 75, carry-out of the substrate from above the first air floating unit 69 onto the third air floating unit 75 and carry-in of the substrate from the second air floating unit 70 onto the first air floating unit 69 can be performed concurrently (synchronously). Accordingly, substrate exchange between the first air floating unit 69 and substrate exchanging device 50 can be performed extremely quickly.

Incidentally, the configuration of each of the eighth to eleventh embodiments can be appropriately changed. For example, in each of the eighth to tenth embodiments described above, while substrate exchanging device 50 carries in the substrate when the first air floating unit 69 is located at the first position (or the third position) described above and carries out the substrate when the first air floating unit 69 is located at the second position described above, this can be reversed. In this case, the next substrate Pb is prepared on the third air floating unit 75. Then, substrate Pa is carried out (a feeding device 73 as in the eighth and tenth embodiment described above can be used, or a substrate holding frame 56 as in the ninth embodiment can be used) horizontally onto the second air floating unit 70 from above the first air floating unit 69, and subsequently, substrate Pb is carried (carried in) along a horizontal plane (movement plane) formed by the upper surface of the first and third air floating units 69 and 75. Incidentally, in each of the eighth and ninth embodiments described above, in the case the frictional resistance between substrate Pa and support section 82 is high, substrate Pa can be carried from above the first air floating unit 69 onto the second air floating unit 70 after having support section 82 withdrawn in the order of, for example, FIGS. 28C to 28A. This prevents substrate Pa from being damaged.

In each of the eighth and tenth embodiments described above, while the third air floating unit 75 is placed above the second air floating unit 70, the third air floating unit 75 can also be placed below. In this case, in the eighth embodiment described above, because the upper surface of the first air floating unit 69 does not have to be located at a higher position than the substrate holding frame, substrate holding frame and the first air floating unit 69 can vertically overlap each other. Accordingly, the degree of freedom increases of the design of the substrate holding frame and the placement of the substrate holding frame with respect to the first air floating unit 69. However, in this case, when the first air floating unit 69 supporting the substrate is made to move vertically with respect to substrate holding frame 56, support section 82 has to be withdrawn.

In the ninth embodiment described above, while the third air floating unit 75 is placed below the second air floating unit 70, the third air floating unit 75 can also be placed above. In this case, for example, first of all, the first air floating unit 69 supporting substrate Pa at the first position is driven upward and is positioned at the second position, and substrate holding frame 56 is driven in the +X direction and is positioned on the second air floating unit 70. In this case, a vertical movement mechanism section of the first air floating unit 69 can be configured suspending from above so that the vertical movement mechanism section does not to interfere with substrate holding frame 56. Subsequently, substrate Pa is carried out from above the first air floating unit 69 onto the third air floating unit 75, and substrate Pb is also held by substrate holding frame 56 on the second air floating unit 70. Then, the first air floating unit 69 is driven downward and is positioned at the first position, and substrate holding frame 56 holding substrate Pb is driven in the −X direction and substrate Pb is carried in from above the second air floating unit 70 onto the first air floating unit 69.

In the tenth embodiment described above, while the upper surface of each of the second and the third air floating units 70 and 75 are located at a position higher than substrate holding frame 156, the upper surfaces can be located at a position lower than the upper surface of the first air floating unit 69 (to be more specific, a position where the Z position of the substrate becomes lower than substrate holding frame 156 when the substrate is mounted on the upper surface of the second and third air floating units 70 and 75). In this case, because the upper surface of the first air floating unit 69 does not have to be located at a higher position than the substrate holding frame, substrate holding frame and the first air floating unit 69 can vertically overlap each other. Accordingly, the degree of freedom increases of the design of the substrate holding frame and the placement of the substrate holding frame with respect to the first air floating unit 69. However, when the first air floating unit 69 supporting the substrate is made to move vertically with respect to substrate holding frame 56, support section 82 has to be withdrawn.

In each of the eighth to tenth embodiments described above, while the second air floating unit 70 and the third air floating unit 75 are placed overlapping each other in the vertical direction (substrate Pa and substrate Pb are carried to one side and the other side in a pair of horizontal axis directions parallel to each other and distanced apart in the Z axis direction), for example, the second air floating unit 70 can be placed on the +X side of the first air floating unit 69 and the third air floating unit 75 can be placed on the +Y side (or the −Y side) of the first air floating unit 69 so that the height of the upper surfaces of each of the second and the third air floating units 70 and 75 are different. In this case, substrate Pb subject to carry-in is carried in the −X direction, and substrate Pa subject to carry-out is carried in the +Y direction (or the −Y direction) at a Z position different from substrate Pa. In other words, substrate Pa and substrate Pb are carried in directions orthogonal to each other in a planar view. Further, the third air floating unit 75 can be placed on the +X side of the first air floating unit 69 and the second air floating unit 70 can be placed on the +Y side (or the −Y side) of the first air floating unit 69 so that the height of the upper surfaces of each of the second and the third air floating units 70 and 75 are different. In this case, substrate Pb is carried in the −Y direction (or the +Y direction), and the substrate Pa is carried in the +X direction. In other words substrate Pa and substrate Pb are carried in directions orthogonal to each other in a planar view. Incidentally, in the case described above, when the substrate is carried in the Y-axis direction, the Z position of the second or the third air floating unit 70 or 75 has to be set at a height diverging from the Z position of the substrate holding frame (X frame member 80X).

In the eleventh embodiment, while the carry-in and carry-out direction is in the −Y direction, for example, the direction can be the +X direction or the −X direction. In the case the carry-in direction and the carry-out direction is in the +X direction or the −X direction, for example, one of the second and the third air floating units 70 and 75 is to be located obliquely above one the first air floating unit 69 to the +X side, and the other of the second and the third air floating units 70 and 75 is to be located obliquely above the first air floating unit 69 to the −X side, and Y frame member 80Y of substrate holding frame 56 is to be fixed to each of the upper surface of, for example, the pair of X frame members 80X, so that the substrate can be carried in and carried out to/from the substrate holding frame 56 from both sides in the X-axis direction.

In the eleventh embodiment described above, while each of the second and third air floating units 70 and 75 are placed obliquely above the first air floating unit 69 in the first position, the second and third air floating units 70 and 75 can be placed obliquely below the first air floating unit 69 which is located at the first position. In this case, because the upper surface of the first air floating unit 69 does not have to be positioned above the substrate holding frame 56, the degree of freedom increases of the design of the substrate holding frame and the placement of the substrate holding frame with respect to the first air floating unit 69.

In the eleventh embodiment described above, while the second and third air floating units 70 and 75 are placed on the +Y side and the −Y side of the first air floating unit 69, or in other words, placed (substrate Pa and substrate Pb move in the same direction (e.g., the −Y direction)) spaced apart in the Y-axis direction, for example, the second air floating unit 70 can be placed on the +X side of the first air floating unit 69 and the third air floating unit 75 can be placed on the +Y side (or the −Y side) of the first air floating unit 69, with each of the upper surfaces of the second and third air floating units 70 and 75 placed at the same height. In this case, substrate Pa is carried in the +Y direction (or the −Y direction), and substrate Pb is carried in the -Z direction at a Z position which is the same as substrate Pa. In other words substrate Pa and substrate Pb are carried in directions orthogonal to each other. Further, the third air floating unit 75 can be placed on the +X side of the first air floating unit 69 and the second air floating unit 70 can be placed on the +Y side (or the −Y side) of the first air floating unit 69 so that each of the upper surfaces of the second and the third air floating units 70 and 75 are at the same height. In this case, substrate Pa is carried in the +X direction, and substrate Pb is carried in the −Y direction or the +Y direction at a Z position which is the same as substrate Pa. In other words substrate Pa and substrate Pb are carried in directions orthogonal to each other.

In each of the eighth to eleventh embodiments described above, while the first air floating unit 69 was vertically moved (refer to FIGS. 28A to 28C) or the second air floating unit 70 was vertically moved when the substrate was held by the substrate holding frame, in the substrate holding frame, the substrate can be held by the substrate holding frame by configuring support section 82 vertically movable and vertically moving support section 82.

In each of the eighth to eleventh embodiments described above, while the first air floating unit 69 or the second air floating unit 70 was vertically moved when the substrate was held by the substrate holding frame, instead of this, for example, the amount of floating of the substrate by the first air floating unit 69 or the second air floating unit 70 can be varied.

In the tenth embodiment described above, while the second air floating unit 70 is placed at a height where the Z position of substrate Pb supported on upper surface of the second air floating unit 70 diverges from the Z position of substrate holding frame 156, instead of this, for example, substrate holding frame 156 can be made vertically movable, and the upper surface of the second air floating unit 70 can be positioned to the same height as the upper surface of the first air floating unit 69 at the first position as in each of the eighth and ninth embodiments described above. This allows substrate holding frame 156 to be positioned at a height diverging from the Z position of substrate Pb on the second air floating unit 70, and to move substrate Pb from above the second air floating unit 70 onto the first air floating unit 69 located at the first position.

In the eighth embodiment described above, while the upper surface of the third air floating unit 75 is positioned at the same height as the upper surface of the first air floating unit 69 at a position that is higher than substrate holding frame 56, instead of this, the upper surface of the third air floating unit 75 can be positioned at the same height as the upper surface of the first air floating unit 69 which is in an inserted state (in between the pair of X frame members 80X) into substrate holding frame 56. In this case, after the upper surface of the first air floating unit 69 is positioned at the same height as the upper surface of the third air floating unit 75 in a state where the first air floating unit 69 is inserted into substrate holding frame 56, the substrate is carried from above the first air floating unit 69 onto the third air floating unit 75. Accordingly, because the movement strokes in the Z-axis direction of the first air floating unit 69 can be shortened, substrate exchange between the first air floating unit 69 and substrate exchanging device 250 can be performed quickly.

In the eleventh embodiment described above, while each of the upper surfaces of the second and third air floating units 70 and 75 are positioned at the same height as the upper surface of the first air floating unit 69 at a position that is higher than substrate holding frame 56, instead of this, each of the upper surfaces of the second and third air floating units 70 and 75 can be positioned at the same height as the upper surface of the first air floating unit 69 which is in an inserted state into substrate holding frame 56. This allows the movement strokes in the Z-axis direction of the first air floating unit 69 to be shortened, therefore substrate exchange between the first air floating unit 69 and substrate exchanging device 250 can be performed quickly.

In the ninth embodiment described above, while substrate Pb is carried onto the first air floating unit 69 in a state where substrate Pb is held by substrate holding frame 56, substrate Pa can be carried out from above the first air floating unit 69 in a state where substrate Pa is held by substrate holding frame 56. In this case, for example, substrate Pb is prepared on the third air floating unit 75, and after substrate holding frame 56 which holds substrate Pa on the first air floating unit 69 at the first position has been carried onto the second air floating unit 70, the first air floating unit 69 is driven downward and is positioned at the second position. Subsequently, the holding of substrate Pa is released from above the second air floating unit 70, and substrate Pb is carried onto the first air floating unit 69 from above the third air floating unit 75. Then, after substrate holding frame 56 has been carried onto the first air floating unit 69, the first air floating unit 69 supporting substrate Pb is driven upward to the first position and substrate Pb is positioned within substrate holding frame 56.

In each of the eighth and ninth embodiments described above, while substrate Pb is positioned within the substrate holding frame by horizontally moving only substrate Pb toward the substrate holding frame, or by horizontally moving the substrate holding frame toward substrate Pb, instead of this, for example, after having made the first air floating unit 69 move upward or downward so that the first air floating unit 69 is positioned diverging from the Z position of substrate Pb and the Z position of second air floating unit 70, the second air floating unit 70 supporting substrate Pb can be moved horizontally toward the substrate holding frame, and substrate Pb can be positioned within the substrate holding frame.

In each of the eighth to eleventh embodiments described above, while the first air floating unit 69 is driven vertically (in the vertical direction) while its upper surface is maintained horizontally, as well as this, for example, the first air floating unit 69 can be driven in a tilt direction (a direction intersecting the horizontal plane) with respect to the horizontal plane while its upper surface is maintained horizontally.

In the eleventh embodiment described above, while carriage starting point is the same for substrate Pa subject to carry-out and substrate Pb subject to carry-in, the carriage starting point can be changed. For example, in the case the carriage starting point of substrate Pa is earlier than substrate Pb, it is desirable to set the carriage speed of substrate Pb faster than substrate Pa (to a degree where substrate Pb does not catch up with substrate Pa). Meanwhile, for example, in the case the carriage starting point of substrate Pa is later than substrate Pb, it is necessary to set the carriage speed of substrate Pa equal to or faster than substrate Pb (to a degree where substrate Pa is not caught up with substrate Pb).

In the eleventh embodiment described above, while the carriage speed of substrate Pa and substrate Pb are the same, it may be varied. However, the carriage speed of substrate Pa and substrate Pb is set so that substrate Pb does not catch up with substrate Pa, based on carriage starting point of substrate Pa and substrate Pb, and the initial distance between substrate Pa and substrate Pb.

### Twelfth Embodiment

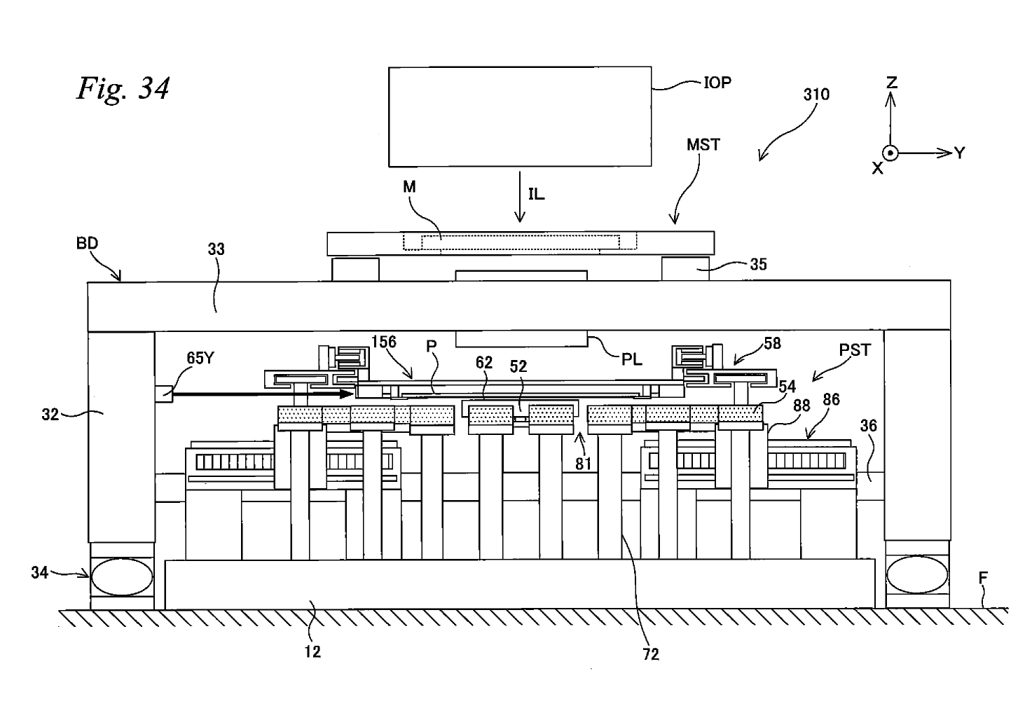

Next, a twelfth embodiment will be described, with reference to FIGS. 34 to 40C. Herein, the same or similar reference signs are used for the components that are the same as or similar to those in the first embodiment described previously, and the description thereabout is simplified or omitted.

FIG. 34 schematically shows a configuration of a liquid crystal exposure apparatus 310 related to the twelfth embodiment.

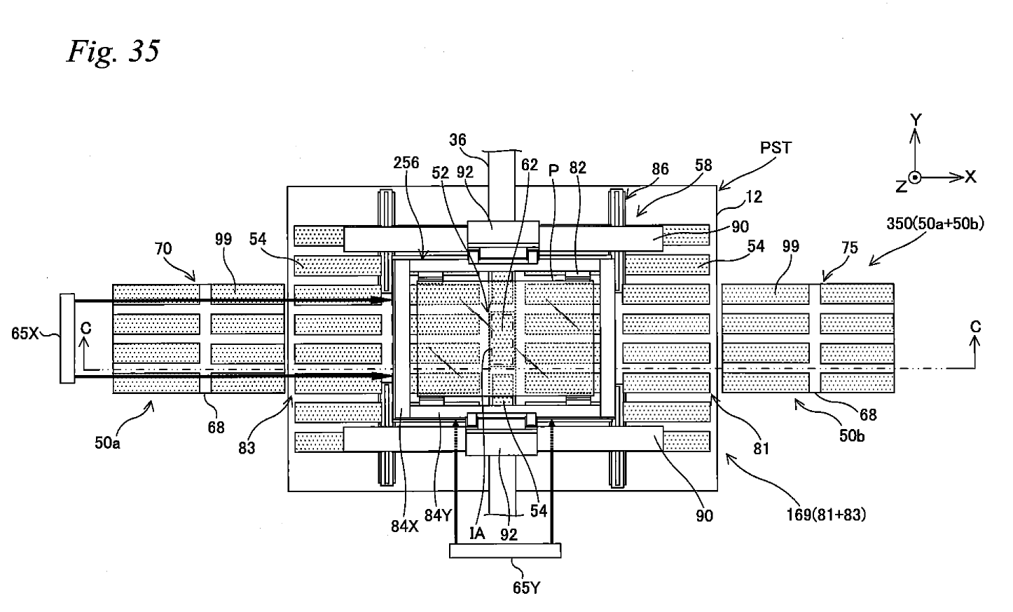

In liquid crystal exposure apparatus 310, while the point where a substrate exchanging device 350 (refer to FIG. 35) is provided instead of the substrate exchanging device 50, the point where a first air floating unit 169 to be described later on is provided correspondingly, instead of the first air floating unit 69 vertically driven by the plurality of Z linear actuators previously described, the point where a substrate holding frame 256 is provided instead of substrate holding frame 56, and the placement, number of air floating devices 54 and the like differ from liquid crystal exposure apparatus 10 related to the first embodiment previously described, the configuration for other sections is the same as liquid crystal exposure apparatus 10. The description below will focus mainly on the difference.

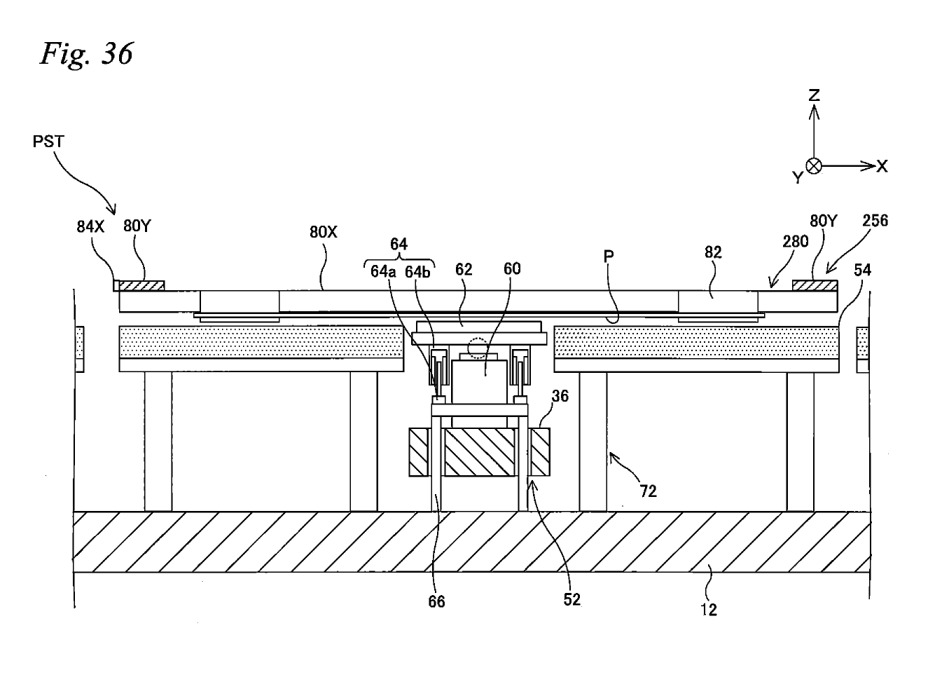

As shown in FIG. 35, a plurality of (e.g., 34, in the embodiment) air floating devices 54 support substrate P (however, the area excluding the part to be exposed of substrate P held by fixed point stage 52 (refer to FIG. 36)) from below in a non-contact manner so that substrate P is roughly parallel to the horizontal plane.

In the twelfth embodiment, an air floating device group consisting of eight air floating devices 54 arranged at a predetermined distance in the Y-axis direction is placed, in four rows at a predetermined distance in the X-axis direction. In the description below, the eight air floating devices 54 configuring the air floating device group will be referred to as one to eight starting from the −Y side, for the sake of convenience. Further, the four rows of air floating device group will be referred to sequentially as one to four rows starting from the −X side, for the sake of convenience. Further, Y beam 36 passes between the second row of the air floating device group and the third row of the air floating device group, and one each of air floating devices 54 is placed on the +Y side and −Y side of fixed point stage 52 mounted on Y beam 36.

Each of the plurality of air floating devices 54 prevents the lower surface of substrate P from being damaged when substrate P moves along the XY plane, by blowing pressurized gas (e.g., air) from the upper surface and supporting substrate P in a non-contact manner. Incidentally, the distance between the upper surface of each of the plurality of air floating devices 54 and lower surface of substrate P is set so that it is longer than the distance between the upper surface of air chuck device 62 of fixed point stage 52 and the lower surface of substrate P (refer to FIG. 34). Of the plurality of air floating device groups, the third to sixth air floating devices 54 (a total of eight air floating devices 54) in the air floating device group of the third row and the fourth row are referred to together as a first air floating device group 81, and the third to sixth air floating devices 54 (a total of eight air floating devices 54) in the air floating device group of the first row and the second row are referred to together as a second air floating device group 83. Further, the first and the second air floating device groups 81 and 83 are referred to together as a first air floating unit 169. Each of the plurality of (e.g., 34, in the embodiment) air floating devices 54 are fixed on surface plate 12 via two each of columnar support members 72 as shown in FIGS. 34 and 36, so that their upper surfaces are positioned on the same horizontal plane as one another. In other words, the first air floating unit 169 does not move vertically.

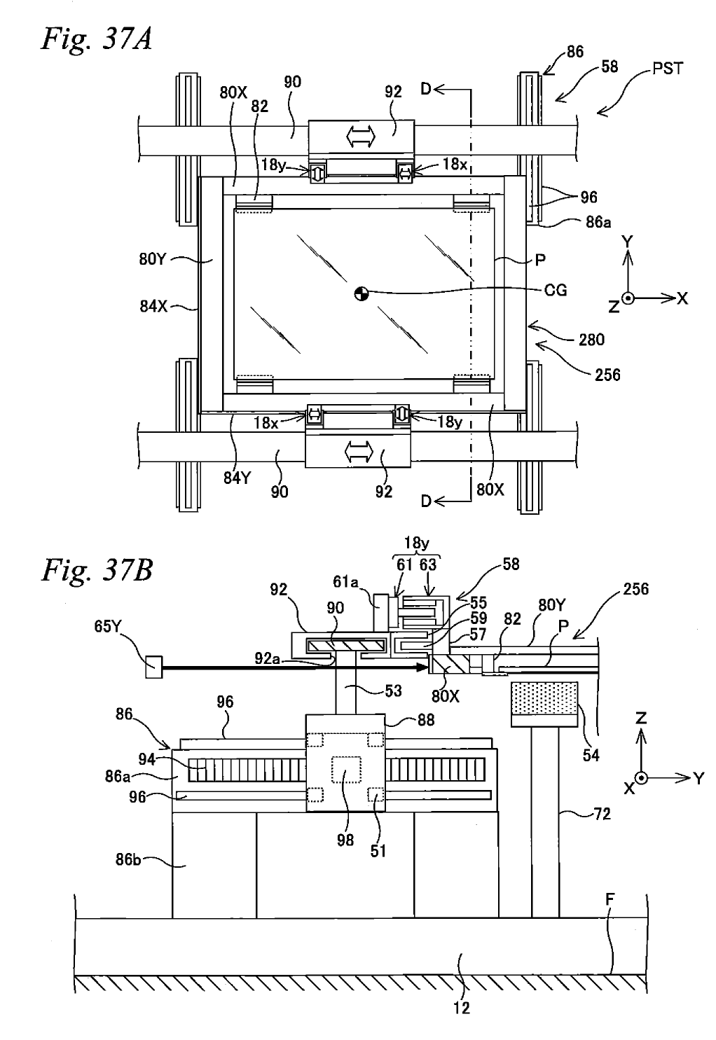

Substrate holding frame 256, as shown in FIG. 37A, includes a main section 280 consisting of a frame shaped member having a rectangular shape in a planar view, and a plurality of, as an example, four support sections 82 which support substrate P from below. Main section 280 has a pair of X frame members 80X and a pair of Y frame members 80Y. Each of the pair of X frame members 80X consists of a plate shaped member parallel to the XY plane and whose longitudinal direction is in the X-axis direction, and is placed parallel at a predetermined distance (a distance larger than the dimension in the y-axis direction of substrate P) in the Y-axis direction. Each of the pair of Y frame members 80Y consists of a plate shaped member parallel to the XY plane and whose longitudinal direction is in the Y-axis direction, and is placed parallel at a predetermined distance (a distance larger than the dimension in the X-axis direction of substrate P) in the X-axis direction. As shown in FIGS. 36 and 37A, Y frame member 80Y on the +X side is fixed to the upper surface of an edge on the +X side of each of the pair of X frame members 80X, and Y frame member 80Y on the −X side is fixed to the upper surface of an edge on the −X side of each of the pair of X frame members 80X. As described, in substrate holding frame 256, the pair of X frame members 80X are connected by the pair of Y frame members 80Y. As shown in FIG. 37A, to the side surface on the side of X frame member 80X on the −Y side, a Y movable mirror 84Y having a reflection surface which is orthogonal to the Y-axis is attached, and to the side surface on the −X side of Y frame member 80 on the −X side, an X movable mirror 84 having a reflection surface orthogonal to the X-axis is attached.

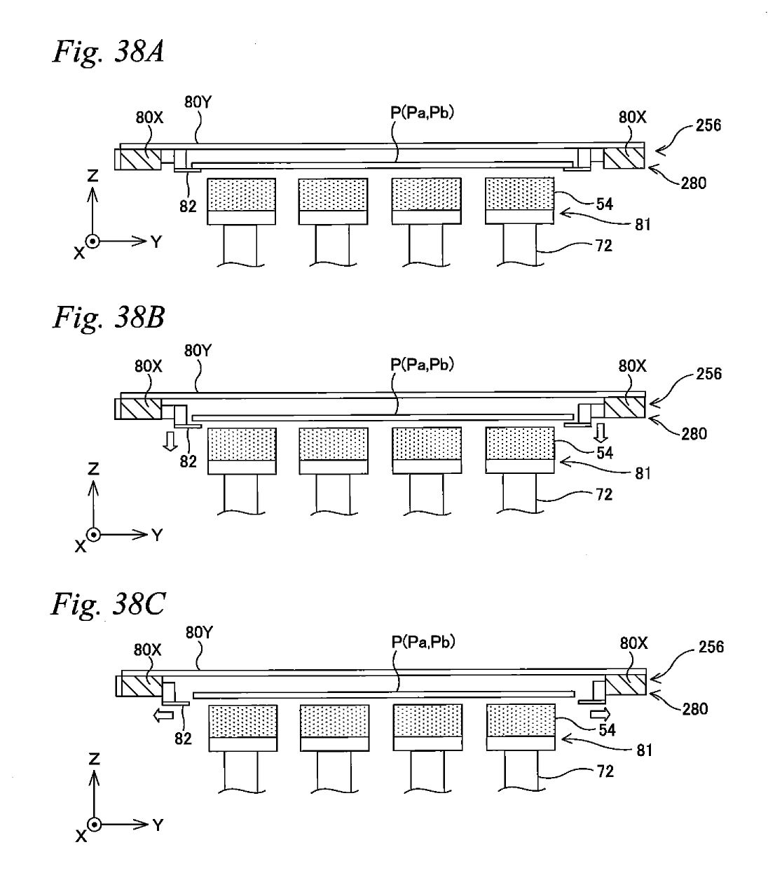

Two of the four support sections 82 are attached to X frame member 80X on the −Y side, and the other two are attached to X frame member BOX on the +Y side, each spaced apart in the X-axis direction at a predetermined distance (a distance smaller than the dimension in the X-axis direction of the substrate). Support section 82 consists of a member having an L-like shape in the YZ section (refer to FIG. 38A), and supports the substrate by a portion parallel to the XY plane from below. Support section 82 has an adsorption pad which is not illustrated on a surface which faces substrate P, and holds substrate P, for example, by vacuum suction. The four support sections 82 are each attached to X frame member 80X on the +y side or the −Y side, via Z actuators (actuators whose drive direction is in the Z-axis direction) which are not illustrated, respectively. This allows the four support sections 82 to be movable in a vertical direction with respect to X frame members 80X to which each support section is attached, as shown in FIGS. 38A and 38B. The Z actuator, for example, includes a linear motor, an air cylinder and the like.

Substrate holding frame 256 configured in the manner described so far supports substrate P by four support sections 82 as shown in FIG. 37A, in a state where the pair of X frame members 80X and a pair of Y frame members 80Y surround the periphery of substrate P in a planar view, for example, equally in the four corners of substrate P. Therefore, substrate holding frame 256 can hold substrate P with good balance.

Positional information of substrate holding frame 256, or in other words, substrate P within the XY plane (including the θz direction) is obtained by a substrate interferometer system including an X interferometer 65x which irradiates a measurement beam on X movable mirror 84 and a Y interferometer 65Y which irradiates a measurement beam on a Y movable mirror 84Y, as shown in FIG. 35.

As can be seen when comparing FIGS. 37A and 37B and FIGS. 4A and 4B, the configuration of drive unit 58 which drives (and finely drives in the θz direction) substrate holding frame 256 in the X-axis direction and the Y-axis direction with predetermined strokes (along the XY plane) is similar to the one described in the first embodiment previously described. Accordingly, a detailed description of drive unit 58 related to the twelfth embodiment will be omitted.

Substrate exchanging device 350, as shown in FIG. 35, is a device which exchanges the substrate with the first air floating unit 169, and includes substrate carry-in device 50a and substrate carry-out device 50b.

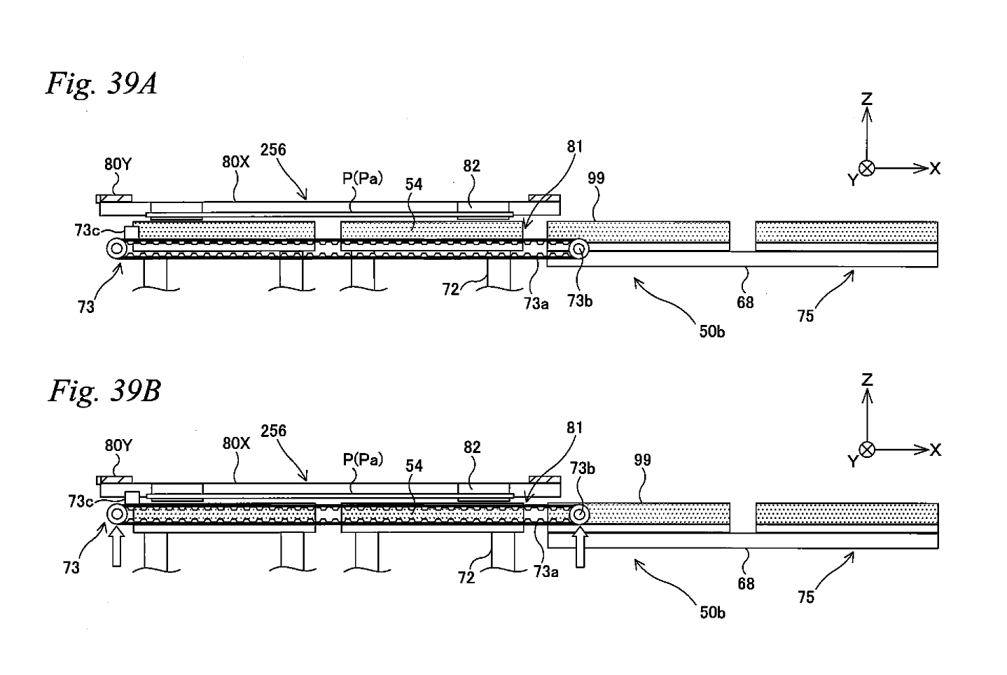

Substrate carry-in device 50a has a second air floating unit 70 which includes an air floating device group having a configuration similar to each of the first and second air floating device groups 81 and 83, on the −X side of the second air floating device group 83. Substrate carry-out device 50b has a third air floating unit 75 which includes an air floating device group having a configuration similar to each of the first and second air floating device groups 81 and 83, on the +X side of the first air floating device group 81. In other words, each of the second and third air floating units 70 and 75, have a plurality of, e.g., eight, air floating devices 99 (refer to FIG. 35) mounted on a base member 68 consisting of a tabular member parallel to the XY plane. Incidentally, air floating device 99 is substantially the same as air floating device 54. The upper surface of, for example, the eight air floating devices 99 that the third air floating unit 75 has are positioned on a horizontal plane the same as, for example, the upper surface (the upper surface of the first air floating device group 81) of the eight air floating devices 54 that configure the first air floating device group 81, as shown in FIGS. 39A and 39B. Similarly, the upper surface of, for example, the eight air floating devices 99 that the second air floating unit 70 has are positioned on a horizontal plane the same as, for example, the upper surface (the upper surface of the second air floating device group 83) of the eight air floating devices 54 that configure the second air floating device group 83.

Further, as shown in FIGS. 39A and 39B, substrate carry-out device 50b has a substrate feeding device 73 (not illustrated in drawings other than. FIGS. 39A and 39B) including belt 73a. Belt 73a is wound to a pair of pulleys 73b, and is driven by rotationally driving the pair of pulleys 73b. To the upper surface of belt 73a, a pad 73c is fixed.

Substrate feeding device 73 is provided vertically movable with respect to the first air floating device group 81 by an elevating device which is not illustrated. More specifically, substrate feeding device 73 is vertically movable between an upward movement limit position (refer to FIG. 39B) where pad 73c fixed to the upper surface of belt 73a protrudes above the upper surface of the first air floating device group 81, and a downward movement limit position (refer to FIG. 39A) where pad 73c is positioned lower than the upper surface of the first air floating device group 81. Incidentally, belt 73a and pulleys 73b are placed, for example, on the +Y side and the −Y side (or in between the plurality of air floating devices 54) of the first air floating device group 81 and the like, and substrate feeding device 73 moves vertically without being in contact with the first air floating device group 81.

When belt 73a of substrate feeder 73 (refer to FIG. 39B), which is positioned at the upward movement limit position in a state where substrate P is mounted on first air floating device group 81, is driven, substrate export device 50b pushes substrate P by pad 73c and makes substrate P move along the upper surface of the first air floating device group 81 (pushes out substrate P from above the first air floating device group 81 onto the third air floating unit 75). Incidentally, although the illustration is omitted, substrate carry-in device 50a also has a substrate feeding device (not illustrated) whose configuration is similar to substrate feeding device 73 of substrate carry-out device 50b described above.

In liquid crystal exposure apparatus 310 (refer to FIG. 34) which is configured as described above, loading of a mask on mask stage MST by a mask loader which is not illustrated, and loading of substrate P onto substrate stage device PST by substrate carry-in device 50a (not illustrated in FIG. 34, refer to FIG. 35) are performed under the control of main controller 20 (refer to FIG. 7). After that, main controller 20 executes alignment measurement using an alignment detection system that is not illustrated, and after the alignment measurement has been completed, an exposure operation by the step-and-scan method is performed.

Because the operation of substrate stage device PST at the time of the exposure operation described above is similar to liquid crystal exposure apparatus 10 related to the first embodiment previously described, the description thereabout is omitted.

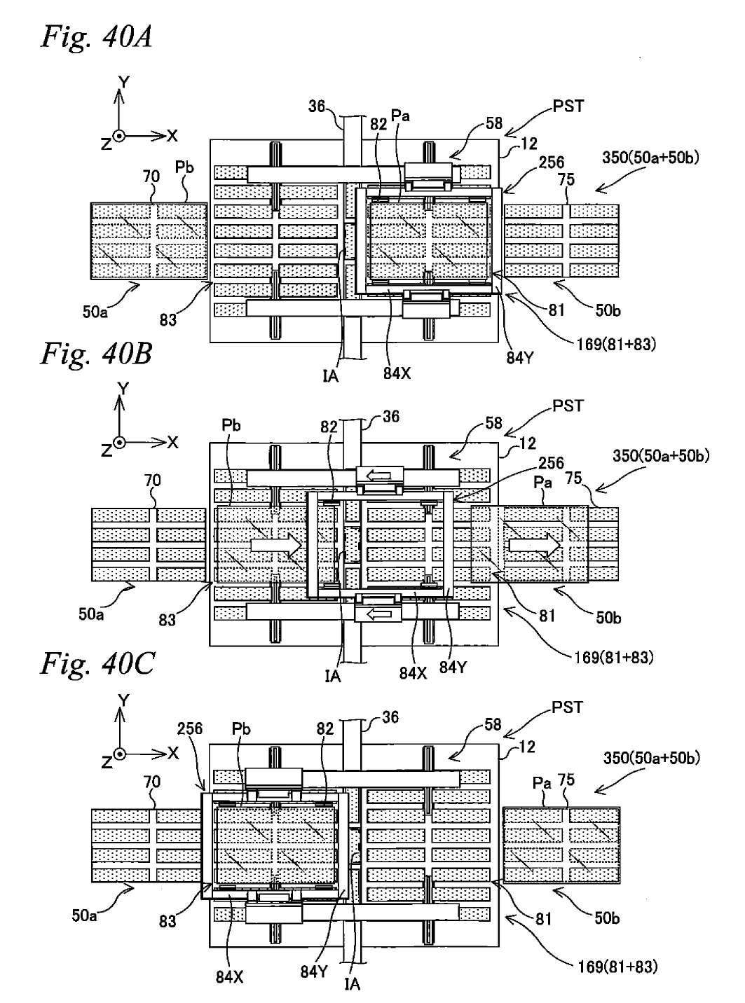

In liquid crystal exposure apparatus 310 related to the present embodiment, after the exposure operation by the step-and-scan method described above has been completed, exchange of substrate P held by substrate holding frame 256 is performed, by substrate P that has been exposed being carried out from substrate holding frame 256 and another substrate P being carried in to substrate holding frame 256. This exchange of substrate P is performed under the control of main controller 20. An example of an exchange operation of substrate P is described below, based on FIGS. 40A to 400. Incidentally, to simplify the drawings, illustration of substrate feeding device 73 (refer to FIGS. 39A and 39B) and the like is omitted in FIGS. 40A to 40C. Further, the substrate subject to carry-out from substrate holding frame 256 will be described as Pa, and the substrate subject to carry-in to substrate holding frame 256 will be described as Pb. Substrate Pb is mounted on the second air floating unit 70 in a state where the edge (the edge in the upstream side of the substrate carry-in direction) on the −X side is in contact with a pad (not illustrated) of the substrate feeding device of substrate carry-in device 50a. Further, in this state, the position of substrate Pb on the second air floating unit 70 in the Y-axis direction is adjusted so that substrate Pb is located in between a section which is orthogonal to the XY plane of each of the support section 82 on the +Y side and support section 82 on the −Y side of substrate holding frame 256. Further, the substrate feeding devices of each of the substrate carry-in device 50a and substrate carry-out device 50b are both positioned at the downward movement limit position (refer to FIG. 39A). In this state, in substrate carry-out device 50b, the X position of pad 73c is adjusted to be slightly on the −X side than the edge of substrate Pa on the −X side, as shown in FIG. 39A.

After the exposure processing has been completed, by substrate holding frame 256 being driven in a direction parallel to the XY plane, substrate Pa is moved onto the first air floating device group 81 as shown in FIG. 40A. At this point, as shown in FIGS. 40A and 38A, the position in the Y-axis direction of substrate holding frame 256 is set so that the four support sections 82 are not positioned above the first air floating device group 81 (not to overlap one another in the vertical direction). Subsequently, suction of substrate Pa by the four support sections 82 of substrate holding frame 256 is released, and the substrate feeding devices of each of the substrate carry-in device 50a and substrate carry-out device 50b are driven upward from the downward movement limit position to the upward movement limit position. Then, as shown in FIG. 38B, in substrate holding frame 256, the four support sections 82 is driven downward with respect to main section 280, and is separated from substrate Pa. Then, as shown in FIG. 40B, substrate Pa is driven by substrate feeding device 73 (refer to FIG. 39B) of substrate carry-out device 50b in the +X direction and is carried from above the first air floating device group 81 onto the third air floating unit 75, along a horizontal plane (movement plane) formed by the upper surface of the first air floating device group 81 and the upper surface of the third air floating unit 75, and substrate holding frame 256 is driven in the −X direction by drive unit 58. Further, at the same time, substrate Pb is driven by the substrate feeding device of substrate carry-in device 50 in the +X direction and is carried from above the second air floating unit 70 onto the second air floating device group 83, along a horizontal plane (movement plane) formed by the upper surface of the second air floating unit 70 and the upper surface of the second air floating device group 83. Substrate holding frame 256 is stopped when it is located on the second air floating device group 83.

Incidentally, in substrate holding frame 256, because the pair of Y frame members 80Y is placed (refer to FIG. 38A) on the pair of X frame members 80X as is described above, the substrate is allowed to pass in the X-axis direction with respect to substrate holding frame 256. Accordingly, when substrate Pa and substrate holding frame 256 relatively moves in the X-axis direction (in a direction separating from each other) as is described above, substrate Pa passes under Y frame member 80Y on the +X side of substrate holding frame 256, and moves out from between the pair of X frame members 80X. Further, when substrate Pb and substrate holding frame 256 relatively moves in the X-axis direction (in a direction approaching each other) as is described above, substrate Pb passes under Y frame member 80Y on the −X side of substrate holding frame 256, and is inserted between the pair of X frame members 80X.

In a state (refer to FIG. 40C) where that substrate Pb and substrate holding frame 256 are positioned on the second air floating device group 83, substrate Pb is located between the section which is orthogonal to the XY plane of each of the support section 82 on the +Y side and the −Y side of substrate holding frame 256, as shown in FIG. 38B. In this case, the four support sections 82 are driven upward with respect to main section 280, and by substrate Pb being supported and vacuum suctioned by the four support sections 82, substrate Pb is held by substrate holding frame 256 (refer to FIG. 38A). Hereinafter, alignment measurement and exposure operation by the step-and-scan method are performed. Further, on the second air floating unit 70 which has delivered substrate Pb to the first air floating device group 81, the next substrate Pb is mounted. Incidentally, because substrate feeding device of substrate carry-in device 50a and substrate carry-out device 50b is driven downward from the upward movement limit position to the downward movement limit position prior to the exposure processing, the substrate feeding device does not interfere with the movement of substrate stage device PST at the time of exposure processing. Further, substrate Pa carried onto the third air floating unit 75 is carried to an external device such as, for example, a coater developer device by a substrate carrier device which is not illustrated.

As described above, in liquid crystal exposure apparatus 310 related to the twelfth embodiment, exposure operation and the like is performed consecutively to a plurality of substrates by repeatedly performing the substrate exchange operation shown in FIGS. 40A to 40C described above.

As is described so far, according to liquid crystal exposure apparatus 310 of the twelfth embodiment, an equivalent effect can be obtained as in the first embodiment previously described. Further, according to liquid crystal exposure apparatus 310, because the upper surface of the second and third air floating units 70 and 75 are positioned at the same height as the upper surface of the first air floating unit 169 adjacent to the second and third air floating units 70 and 75, substrate Pa located above the first air floating unit 169 can be carried out from above the first air floating unit 169 by simply moving substrate Pa horizontally onto the third air floating unit 75, and substrate Pb located above the second air floating unit 70 can be carried in onto the first air floating unit 169 by simply moving substrate Pb horizontally onto the first air floating unit 169.

In other words, because substrate Pa moves horizontally from above the first air floating unit 169 which supports the substrate at the time of exposure processing onto the third air floating unit 75 and is carried out directly, and substrate Pb moves horizontally from above the second air floating unit 70 onto the first air floating unit 169 and is carried in directly, transition between the exposure processing operation and the substrate exchange operation can be performed in a short period of time.

In the case of substrate carry-out, because substrate Pa is carried onto the third air floating unit 75 after support sections 82 have been separated from substrate Pa on the first air floating device group 81 which supports substrate Pa, this prevents substrate Pa from being damaged.

### Thirteenth Embodiment

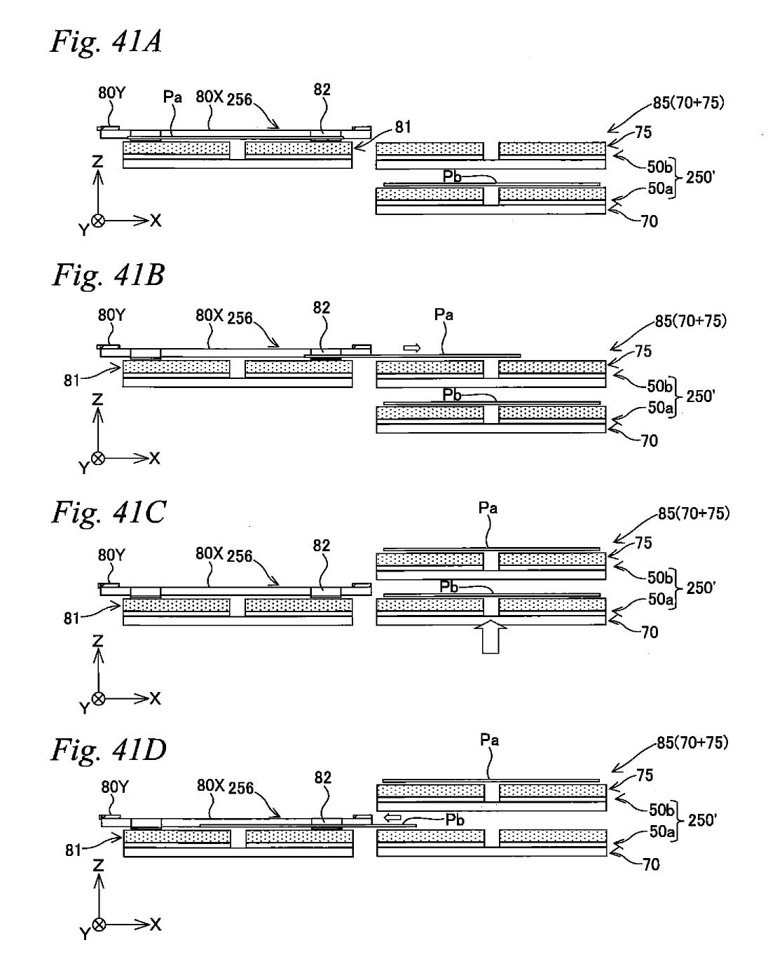

Next, a thirteenth embodiment will be described, with reference to FIGS. 41A to 41D. Here, points that are different from the twelfth embodiment previously described will be explained, and the same or similar reference numerals will be used for the same or similar members as in the twelfth embodiment previously described, and a description thereabout will be simplified or omitted.

While the carry-in path and the carry-out path of the substrate is set to the same height in the twelfth embodiment described above, in the thirteenth embodiment, the carry-in path and the carry-out path of the substrate is set to a different height.

In substrate exchanging device 250′ related to the thirteenth embodiment, as shown in FIGS. 41A to 41D, the second and third air floating units 70 and 75 are placed on the side of the first air floating device group 81 in a state placed a predetermined distance apart vertically and are also integrally movable vertically by an elevating device which is not illustrated. In the description below, the second and the third air floating units 70 and 75 will be referred to together and be described as a paired air floating unit 85. In paired air floating unit 85, the third air floating unit 75 is located above the second air floating unit 70, and the upper surface of the second and third air floating units 70 and 75 are both horizontal.

In the state shown in FIG. 41A, in air floating device group 81, the upper surface of the third air floating unit 75 is located at the same height as the upper surface of the first air floating device group 81 (the Z position of paired air floating unit 85 at this point will be referred to as a first position).

In the liquid crystal exposure apparatus related to the thirteenth embodiment, in the case of substrate exchange, first of all, holding of substrate Pa by substrate holding frame 256 is canceled (refer to FIG. 41A) above the first air floating device group 81, as in the twelfth embodiment described above. Subsequently, substrate Pa is carried (refer to FIG. 41B) from above the first air floating device group 81 onto to the third air floating unit 75 as in the twelfth embodiment. And, after substrate Pa is positioned above the third air floating unit 75 (or more specifically, after when the entire substrate Pa has passed under Y frame member 80Y on the +X side of substrate holding frame 256), paired air floating unit 85 is driven upward and is stopped when the upper surface of the second air floating unit 70 reaches the same height as the upper surface of the first air floating device group 81 (refer to FIG. 41C, the Z position of the paired air floating unit 85 at this point is referred to as a second position). Then, substrate Pb is carried (refer to FIG. 41D) from above the second air floating unit 70 onto the first air floating device group 81, along a horizontal plane (movement plane) formed by the upper surface of the second air floating unit 70 and the upper surface of the first air floating device group 81. At this point, substrate Pb is carried while being inserted in between the section which is orthogonal to the XY plane of support sections 82 on the +Y side and the −Y side of substrate holding frame 256. Substrate Pb which is located on the first air floating device group 81 is held by substrate holding frame 256 as in the twelfth embodiment. Hereinafter, alignment measurement and exposure operation by the step-and-scan method are performed. On the second air floating unit 70 which has delivered substrate Pb to the first air floating device group 81, the next substrate Pb is mounted. Further, substrate Pa located above the third air floating unit 75 is carried to an external device such as, for example, a coater developer device by a substrate carrier device which is not illustrated. Then, the paired air floating unit 85 is driven downward and is positioned at the first position described above, and is prepared) for the carry-out of the next substrate Pa.

According to the liquid crystal exposure apparatus related to the thirteenth embodiment, because the second and the third air floating units 70 and 75 are placed vertically on the +X side of the first air floating device group 81 (surface plate 12), the dimension in the X-axis direction of the entire liquid crystal exposure apparatus can be made shorter than the twelfth embodiment described above where the second and third air floating units 70 and 75 are each placed on the +X side and the −X side of surface plate 12.

Further, by a simple configuration where paired air floating unit 85 consisting of the second and the third air floating units 70, is vertically moved with respect to the first air floating device group 81, substrate carriage can be performed between the first air floating device group 81 and the second air floating unit 70, and between the first air floating device group 81 and the third air floating unit 75. Moreover, because paired air floating unit 85 only has to be simply driven vertically between two positions in the Z-axis direction, the control is easy.

Further, when substrate Pa is located above the first air floating device group 81, because the upper surface of the third air floating unit 75 is located at the same height as the upper surface of the first air floating device group 81, substrate Pa can be carried directly by being horizontally moved from above the first air floating device group 81 onto the third air floating unit 75. In other words, the operation can shift from the exposure operation to the substrate carry-out operation immediately.

Incidentally, in the thirteenth embodiment, because substrate holding frame 256 has Y frame member 80Y on the +X side, paired air floating unit 85 cannot be driven upward until the entire substrate P passes under Y frame member 80Y on the +X side. Therefore, for example, the substrate holding frame can be configured (a configuration in a U-shape in a planar view) so that Y frame member 80Y on the +X side is removed from substrate holding frame 256. In such a case, paired air floating unit 85 can be driven upward during carriage of substrate Pa. And, the carry-in operation of substrate Pb can be started in accordance with driving paired air floating unit 85 upward. This allows a part of the carry-out operation and the carry-in operation of the substrate with respect to substrate holding frame 256 to be performed concurrently, which can reduce the cycle time of substrate exchange.

### Fourteenth Embodiment

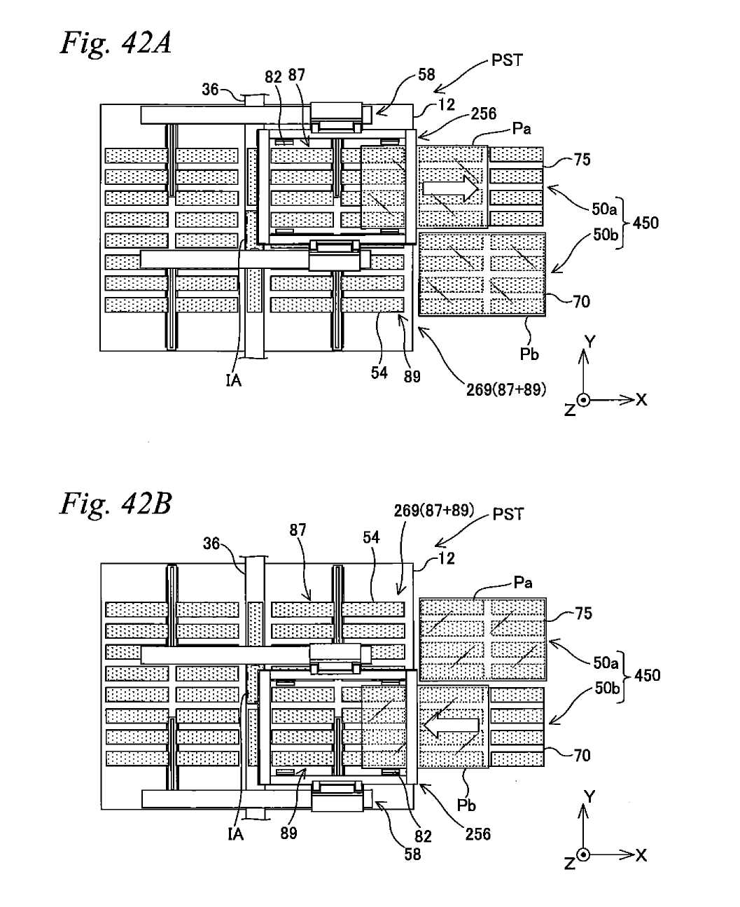

Next, a fourteenth embodiment will be described, with reference to FIGS. 42A and 42B. Here, points that are different from the twelfth embodiment previously described will be explained, and the same or similar reference numerals will be used for the same or similar members as in the twelfth embodiment previously described, and a description thereabout will be simplified or omitted.

While carry-in of the substrate to substrate holding frame 256 is performed by moving substrate holding frame 256 in the X-axis direction (scanning direction) in the twelfth embodiment described above, in the fourteenth embodiment, substrate holding frame 256 is moved in the Y-axis direction (stepping direction) to perform carry-in of the substrate into substrate holding frame 256. Hereinafter, the description will be made describing the fifth to eighth air floating devices 54 (a total of eight air floating devices 54) in the air floating device group of the third row and the fourth row referred to together as a third air floating device group 87, the first to fourth air floating devices 54 (a total of eight air floating devices 54) in the air floating device group of the third row and the fourth row referred to together as a fourth air floating device group 89, and the third and fourth air floating device group are referred together as a first air floating unit 269.

In a substrate exchanging device 450 related to the fourteenth embodiment, the second and the third air floating units 70 and 75 are placed on +X side of surface plate 12 (the first air floating unit 269) lined in the Y-axis direction, as shown in FIG. 42A. More specifically, the second and the third air floating units 70 and 75 are placed adjacent to the fourth and third air floating device groups 89 and 87, respectively. In other words, the Y position of the second and the third air floating units 70 and 75 are each within a movement stroke range of substrate holding frame 256 in the Y-axis direction. Further, the upper surface of each of the second and the third air floating units 70 and 75 are located on the same horizontal plane as the upper surface of the plurality of air floating devices 54 of the first air floating unit 269.

In the liquid crystal exposure apparatus related to the fourteenth embodiment, in the case of substrate exchange, substrate Pa held by substrate holding frame 256 is located above air floating device group 87. Subsequently, after the holding of substrate Pa by substrate holding frame 256 above the third air floating device group 87 is released, substrate Pa is carried from above the third air floating device group 87 onto the third air floating unit 75 (refer to FIG. 42A). After substrate Pa is located above the third air floating unit 75 (more specifically, after the entire substrate Pa is located further to the +X side than support sections 82 on the +X side), substrate holding frame 256 is driven in the −Y direction and is positioned above the fourth air floating device group 89. Then, substrate Pb is carried from above the second air floating unit 70 onto the fourth air floating device group 89 (refer to FIG. 42B), and is held by substrate holding frame 256 above the fourth air floating device group 89. Hereinafter, alignment measurement and exposure operation by the step-and-scan method are performed. Incidentally, substrate Pa carried onto the third air floating unit 75 is carried to an external device such as, for example, a coater developer device by a substrate carrier device which is not illustrated.

According to the liquid crystal exposure apparatus related to the fourteenth embodiment, in the case of substrate exchange, because substrate holding frame 256 is driven in the Y-axis direction, namely in the stepping direction (movement strokes are shorter than the X-axis direction serving as the scanning direction), the movement strokes of substrate holding frame 256 can be made shorter than the twelfth embodiment described above. Accordingly, the time required from completing the carry-out of substrate Pa from substrate holding frame 256 to starting the carry-in of substrate Pb into substrate holding frame 256 can be reduced, which can expedite the substrate exchange with respect to substrate holding frame 256.

Further, according to the fourteenth embodiment, because the second and the third air floating units 70 and 75 are placed on the +X side, the dimension in the X-axis direction of the entire liquid crystal exposure apparatus can be made shorter than the twelfth embodiment described above where the second and third air floating units 70 and 75 are each placed on the +X side and the −X side of surface plate 12.

Incidentally, the configuration of each of the twelfth to fourteenth embodiments can be appropriately changed. For example, in each of the twelfth to fourteenth embodiments described above, while the substrate exchanging device carries out the substrate from above the first air floating unit onto the third air floating unit 75, and carries in the substrate from the second air floating unit 70 onto the first air floating unit, the operation can be reversed. In this case, substrate Pb subject to carry-in is prepared on the third air floating unit 75. Then, substrate Pa is carried out horizontally onto the second air floating unit 70 from above the first air floating unit, and subsequently, substrate Pb is horizontally moved and carried in from above the third air floating unit 75 onto the first air floating unit.

In the thirteenth embodiment described above, while the second air floating unit 70 is placed below the third air floating unit 75, the second air floating unit 70 can also be placed above. In this case, after substrate Pa is carried out horizontally onto the third air floating unit 75 from above the first air floating device group 81, paired air floating unit 85 is driven downward, and substrate Pb is horizontally moved and carried in from above the second air floating unit 70 onto the first air floating device group 81.

In each of the twelfth and the fourteenth embodiment, while the carry-out direction and the carry-in direction of the substrate are both in the X-axis direction, for example, the carry-out direction and the carry-in direction of the substrate can both be in the Y-axis direction. More specifically, for example, the second and the third air floating units 70 and 75 can be placed at a position in the Y-axis direction with the first air floating unit in between, and the carry-out direction and the carry-in direction of the substrate can be in the same direction (both in the +Y direction, or the −Y direction). Further, for example, the second and the third air floating units 70 and 75 can be placed lined in the X-axis direction on the +Y side (or the −Y side) of the first air floating unit, and the carry-out direction and the carry-in direction of the substrate can be in the opposite direction (one in the +Y direction and the other in the −Y direction). However, in order to carry the substrate in the Y-axis direction, for example, substrate holding frame 256 has to be configured rotated by 90 degrees around an axis which passes through the center of the substrate holding frame and is parallel to the Z-axis (however, the dimension of the X frame member 80X has to be replaced with the dimension of the Y frame member 80Y), so that the substrate can be carried in and carried out in the Y-axis direction with respect to the substrate holding frame.

In the thirteenth embodiment described above, while the carry-out direction and the carry-in direction of the substrate are both in the X-axis direction, for example, the carry-out direction and the carry-in direction of the substrate can both be in the Y-axis direction. More specifically, for example, the paired air floating unit 85 can be placed vertically movable on the +Y side (or the −Y side) of the first air floating unit, and the carry-out direction and the carry-in direction of the substrate can be in the opposite direction (one in the direction and the other in the −Y direction). However, in order to carry the substrate in the Y-axis direction, carry-in and carry-out of the substrate in the Y-axis direction has to be allowed with respect to the substrate holding frame.

In each of the twelfth and the fourteenth embodiment, while the carry-out direction and the carry-in direction of the substrate are both in the X-axis direction, for example, one of the carry-out direction and the carry-in direction of the substrate can be in the X-axis direction, and the other can be in the Y-axis direction. More specifically, one of the second and the third air floating units 70 and 75 can be placed on the +X side (or the −X side) of the first air floating unit, and the other can be placed on the +Y side (or the −Y side) of the third air floating unit. However, in order to carry the substrate in the X-axis direction and the Y-axis direction, carry-in and carry-out of the substrate in the X-axis direction and the Y-axis direction has to be allowed with respect to the substrate holding frame.

In each of the twelfth and the fourteenth embodiment, while support sections 82 were vertically moved (refer to FIGS. 38A and 38B) when the substrate was carried out from substrate holding frame and when the substrate was held by the substrate holding frame, the air floating device group of the first air floating unit can be configured vertically movable, and the air floating device group can be moved vertically.

In each of the twelfth and the fourteenth embodiment, while support sections 82 were vertically moved (refer to FIGS. 38A and 38B) when the substrate was carried out from substrate holding frame and when the substrate was held by the substrate holding frame, support sections 82 can be moved in the horizontal direction as shown in FIGS. 38B and 38C.

In each of the twelfth and the fourteenth embodiment, while support sections 82 were vertically moved when the substrate was carried out from substrate holding frame and when the substrate was held by the substrate holding frame, the amount of floating of the substrate by the air floating device group of the first air floating unit can be varied.

In the thirteenth embodiment described above, while paired air floating unit 85 is driven vertically (in the vertical direction), paired air floating unit 85 can be driven in the tilt direction (a direction intersecting the horizontal plane) with respect to the horizontal plane. In this case, to make each of the second and the third air floating units 70 and 75 configuring paired air floating unit 85 movable separately to a position adjacent to the first air floating device group 81, the position of the second and the third air floating units 70 and 75 in a direction parallel to the XY plane (horizontal plane) has to be appropriately shifted.

In the thirteenth embodiment described above, while the second and the third air floating units 70 and 75 are vertically moved integrally, the second and the third air floating units 70 and 75 can be driven individually in the vertical direction or in an intersecting direction with respect to the horizontal plane.

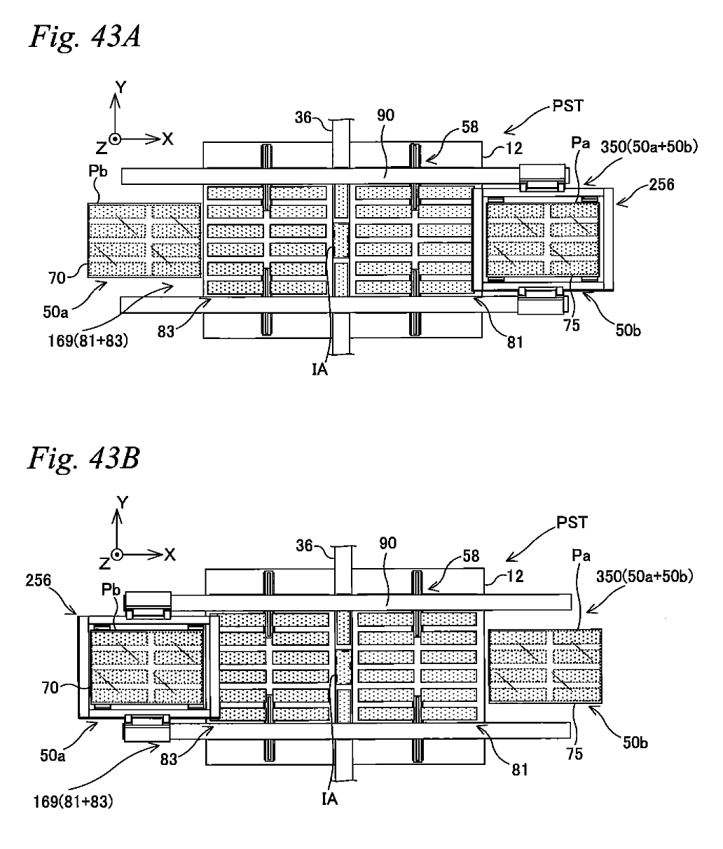

In the twelfth embodiment described above, while the substrate is carried using substrate feeding device 73 in both the first and the second air floating units 169 and 70, and the first and the third air floating units 169 and 75, the substrate can be carried using substrate holding frame 256 (carried in a state where the substrate is held by substrate holding frame 256) in at least one of the first and the second air floating units 169 and 70, and the first and the third air floating units 169 and 75. This allows the substrate to be moved more quickly (in the twelfth embodiment described above, carriage at a high speed is difficult because carriage is performed in a state where the substrate is not restricted in the XY direction) than the case when a belt drive method is used as in substrate feeding device 73 related to the twelfth embodiment. Accordingly, the cycle time of substrate exchange can be reduced when compared with the twelfth embodiment described above. Further, substrate feeding device 73 will not have to be provided in at least one of the substrate carry-in device 50a and substrate carry-out device 50b. More specifically, as shown in FIGS. 43A and 438, by making stator 90 of the X linear motor used to drive substrate holding frame 256 in the X-axis direction longer in at least one of the +X side and the -x side than the twelfth embodiment described above, substrate holding frame 256 can be made movable to above at least one of the second and the third air floating units 70 and 75 (in FIGS. 43A and 438, X stator 90 is extended on both the +X side and the −X side). In this case, because the control system and the measurement system of substrate holding frame 256 do not have to be changed with respect to the twelfth embodiment described above, cost increase can be suppressed. In the case of using substrate holding frame 256 at the time of carry-out of the substrate, as shown in FIG. 43A, substrate holding frame 256 holding substrate Pa subject to carry-out is moved from above the first air floating unit 169 onto the third air floating unit 75, and the holding of substrate Pa on the substrate holding frame 256 is released above the third air floating unit 75. And only substrate holding frame 256 is moved from above the air floating unit 169 onto the third air floating unit 75. In the case of using substrate holding frame 256 at the time of carry-in of the substrate, as shown in FIG. 43B, substrate holding frame 256 is moved from above the first air floating unit 169 onto the second air floating unit 70 supporting substrate Pb subject to carry-in, and substrate holding frame 256 is made to hold substrate Pb on the second air floating unit 70. And substrate holding frame 256 holding substrate Pb is moved from above the second air floating unit 70 onto the first air floating unit 169. Incidentally, in the case substrate holding frame 256 is used both at the time of substrate carry-out and at the time of substrate carry-in, for example, substrate holding frame 256 is moved from above the first air floating unit 169 onto the third air floating unit 75 in a state holding substrate Pa, and after the holding of substrate Pa is released on the third air floating unit 75, substrate holding frame 256 is moved from above the third air floating unit 75 onto the second air floating unit 70 via the first air floating unit 169, and after holding substrate Pb above the second air floating unit 70, substrate holding frame 256 is moved from above the second air floating unit 70 onto the first air floating unit 169.

In the fourteenth embodiment described above, while the substrate is carried using substrate feeding device 73 in both the first and the second air floating units 269 and 70, and the first and the third air floating units 269 and 75, the substrate can be carried using substrate holding frame 256 (carried in a state where the substrate is held by substrate holding frame 256) in at least one of the first and the second air floating units 269 and 70, and the first and the third air floating units 269 and 75. More specifically, the stator of the X linear motor used to drive substrate holding frame 256 in the X-axis direction is made longer on the +X side than the twelfth embodiment described above, and substrate holding frame 256 is moved to above at least one of the second and the third air floating units 70 and 75.

In the thirteenth embodiment described above, while the substrate is carried using substrate feeding device 73 in both the first and the second air floating units 169 and 70, and the first and the third air floating units 169 and 75, the substrate can be carried using substrate holding frame 256 (carried in a state where the substrate is held by substrate holding frame 256) in at least one of the first and the second air floating units 169 and 70, and the first and the third air floating units 169 and 75.

In each of the twelfth to fourteenth embodiments described above, while a substrate holding frame having a rectangular frame shape in a planar view is used as the substrate holding frame, besides this, for example, a frame having a U shape, an elliptical frame shape, a rhomboidal frame shape and the like in a planar view can be used. However, in any case, an opening which allows the substrate to pass in the X-axis direction has to be made in the substrate holding frame (in the case of the twelfth embodiment described above, the opening has to be made in the +X end and the −X end of the substrate holding frame, and in the case of each of the thirteenth and fourteenth embodiments, the opening has to be made in the +X end).

In the fourteenth embodiment, while in the case of carrying the substrate in and out of substrate holding frame 256, substrate holding frame 256 is moved in the Y-axis direction with respect to the second and third air floating units 70 and 75, instead of this, or in addition to this, the second and the third air floating units 70 and 75 can be moved in the Y-axis direction with respect to the substrate holding frame 256.

Incidentally, while in each of the substrate carry-in device 50a and substrate carry-out device 50b (except for the substrate carry-in device related to the ninth embodiment) related to each of the first to fourteenth embodiments (hereinafter expressed as each of the embodiments described above) described above, the substrate was carried by substrate feeding device 73 which includes belt 73a, if substrate can be driven uniaxially on the air floating unit, then the configuration of the drive device is not limited to this, and for example, other single axis actuators such as an air cylinder can be used to drive the substrate. Further, the substrate can be carried in a gripped state, using a chucking device.

Further, in each of the embodiments described above, while the substrate was supported in a non-contact manner using a plurality of air floating devices, if the lower surface of substrate can be kept from being damaged when the substrate is moved along the horizontal plane, the substrate can be moved on a rolling body such as a ball bearing and the like,

Further, the movable body apparatus (substrate stage device PST) related to each of the embodiments described above can be applied to devices other than the exposure apparatus. For example, the movable body apparatus can be used in a substrate inspection device. Further, fixed point stage 52 does not necessarily have to be provided. The substrate holding frame does not have to be rotatable in the θz direction (the holding frame can be fixed to an X mover).

Further, in each of the embodiments described above, while positional information of the substrate holding frame in the XY plane was obtained by a laser interferometer system including a laser interferometer which irradiates a measurement beam on a movable mirror provided in the substrate holding frame, the position measuring device is not limited to this, and for example, a two-dimensional encoder system can also be used. In this case, for example, a scale can be provided on the substrate holding frame, and positional information of the substrate holding frame can be obtained by a head fixed to the body or the like, or the head can be provided on the substrate holding frame, and positional information of the substrate holding frame can be obtained, for example, by a scale fixed to the body or the like.

Further, the illumination light can be an ultraviolet light such as an ArF excimer laser light (with a wavelength of 193 nm), or a KrF excimer laser light (with a wavelength of 248 nm), or a vacuum ultraviolet light such as an F₂ laser beam (with a wavelength of 157 nm). Further, as the illumination light, a harmonic wave, which is obtained by amplifying a single-wavelength laser light in the infrared or visible range emitted by a DFB semiconductor laser or fiber laser with a fiber amplifier doped with, for example, erbium (or both erbium and ytterbium), and by converting the wavelength into ultraviolet light using a nonlinear optical crystal, can also be used. Further, solid state laser (with a wavelength of 355 nm, 266 nm) or the like can also be used.

Further, while, in each of the embodiments above, the case has been described where projection optical system PL is the projection optical system by a multi-lens method that is equipped with a plurality of optical systems, the number of the projection optical systems is not limited thereto, but there should be one or more projection optical systems. Further, the projection optical system is not limited to the projection optical system by a multi-lens method, but can be a projection optical system using, for example, a large mirror of the Offner type, or the like.

Further, while the case has been described where the projection optical system whose projection magnification is equal magnification is used as projection optical system PL in each of the embodiments above, this is not intended to be limiting, and the projection optical system can be either of a magnifying system or a reduction system.

Further, in each of the embodiments above, while the case has been described where the exposure apparatus is a scanning stepper, this is not intended to be limiting, and each of the embodiments above can also be applied to a static exposure apparatus such as a stepper. Further, each of the embodiments described above can also be applied to a projection exposure apparatus by a step-and-stitch method that synthesizes a shot area and a shot area. Further, each of the embodiments above can be applied to the exposure apparatus by the proximity method which does not use a projection optical system.

Further, in each of the embodiments above, a light transmissive type mask is used, which is obtained by forming a predetermined light-shielding pattern (or a phase pattern or a light-attenuation pattern) on a light transmissive mask substrate. Instead of this mask, however, as disclosed in, for example, U.S. Pat. No. 6,778,257, an electron mask (a variable shaped mask) on which a light-transmitting pattern, a reflection pattern, or an emission pattern is formed according to electronic data of the pattern that is to be exposed, for example, a variable shaped mask that uses a DMD (Digital Micromirror Device) that is a type of a non-emission type image display element (which is also called a spatial light modulator) can also be used.

Further, the application of the exposure apparatus is not limited to the exposure apparatus for liquid crystal display elements in which a liquid crystal display element pattern is transferred onto a rectangular glass plate, but each of the embodiments above can also be widely applied, for example, to an exposure apparatus for manufacturing semiconductors, and an exposure apparatus for producing thin-film magnetic heads, micromachines, DNA chips, and the like. Further, each of the embodiments above can be applied not only to an exposure apparatus for producing microdevices such as semiconductor devices, but can also be applied to an exposure apparatus in which a circuit pattern is transferred onto a glass substrate, a silicon wafer or the like to produce a mask or a reticle used in a light exposure apparatus, an EUV exposure apparatus, an X-ray exposure apparatus, an electron-beam exposure apparatus, and the like.

Incidentally, an object that is subject to exposure is not limited to a glass plate, but for example, can be another object such as a wafer, a ceramic substrate, a film member or a mask blank . Further, in the case where an exposure subject is a substrate for flat-panel display, the thickness of the substrate is not limited in particular, and for example, a film like member (a sheet like member having flexibility) is also included.

Incidentally, the exposure apparatus related to each of the embodiments described above is especially effective in the case when a substrate whose length of one side is 500 mm or more is an exposure subject.

Incidentally, the above disclosures of all the publications, the PCT International Publications descriptions, and the U.S. patent application Publications descriptions, and the U.S. patents descriptions that are cited in the description above and related to exposure apparatuses and the like are each incorporated herein by reference.

Device Manufacturing Method

A manufacturing method of a microdevice that uses the liquid crystal exposure apparatus related to each of the embodiments above in a lithography process is described next . In the liquid crystal exposure apparatus related to each of the embodiments above, a liquid crystal display element as a microdevice can be obtained by forming a predetermined pattern (such as a circuit pattern and an electrode pattern) on a plate (a glass substrate).

Pattern Forming Process

First of all, a so-called optical lithography process in which a pattern image is formed on a photosensitive substrate (such as a glass substrate coated with a resist) is executed using the liquid crystal exposure apparatus related to each of the embodiments described above. In this optical lithography process, a predetermined pattern that includes many electrodes and the like is formed on the photosensitive substrate. After that, the exposed substrate undergoes the respective processes such as a development process, an etching process and a resist removing process, and thereby the predetermined pattern is formed on the substrate.

Color Filter Forming Process

Next, a color filter in which many sets of three dots corresponding to R (Red), G (Green) and B (blue) are disposed in a matrix shape, or a color filter in which a plurality of sets of filters of three stripes of R, G and B are disposed in horizontal scanning line directions is formed.

Cell Assembling Process

Next, a liquid crystal panel (a liquid crystal cell) is assembled using the substrate having the predetermined pattern obtained in the pattern forming process, the color filter obtained in the color filter forming process, and the like. For example, a liquid crystal panel (a liquid crystal cell) is manufacture by injecting liquid crystal between the substrate having the predetermined pattern obtained in the pattern forming process and the color filter obtained in the color filter forming process.

Module Assembling Process

After that, a liquid crystal display element is completed by attaching respective components such as an electric circuit that causes a display operation of the assembled liquid crystal panel (liquid crystal cell) to be performed, and a backlight.

In this case, since exposure of the substrate is performed with high throughput and high precision using the liquid crystal exposure apparatus related to each of the embodiments described above in the pattern forming process, the productivity of liquid crystal display elements can be improved as a consequence.

While the above-described embodiments of the present invention are the presently preferred embodiments thereof, those skilled in the art of lithography systems will readily recognize that numerous additions, modifications, and substitutions maybe made to the above-described embodiments without departing from the spirit and scope thereof. It is intended that all such modifications, additions, and substitutions fall within the scope of the present invention, which is best defined by the claims appended below.

1. A movable body apparatus, comprising:
a movable body which holds an edge of an object, and is movable with the object at least in a predetermined range within a predetermined two-dimensional plane parallel to a horizontal plane;
an object support device which has a first member having a surface whose tilt angle with respect to the two-dimensional plane is changeable in at least two steps including zero degrees, and supports the object moving with the movable body in the predetermined range from below;
a first support device which has a surface forming a first movement plane that forms a first angle with respect to the two dimensional plane together with the surface of the first member in a first state where the surface forms the first angle with respect to the two-dimensional plane, and can support the object from below;
a second support device which has a surface forming a second movement plane that forms a second angle with respect to the two dimensional plane together with the surface of the first member in a second state where the surface forms the second angle with respect to the two-dimensional plane, and can support the object from below; and
a carrier system including a first carrier system which moves the object along the first movement plane and a second carrier system which moves the object along the second movement plane, wherein
the object is carried out from above the object support device by one of the first and second carrier systems, and another object is carried in onto the object support device by the other of the first and second carrier systems.

2. The movable body apparatus according to claim 1 wherein the first angle is zero degrees, and in the first state, the surface of the first member is parallel to the two-dimensional plane.

3. The movable body apparatus according to claim 2 wherein the movable body is movable between an area over the first member and an area over the first support device, and
the first carrier system performs one of a carry-out of the object from above the first member onto the first support device and a carry-in of the object from above the first support device onto the first member, using the movable body.

4. The movable body apparatus according to claim 2 wherein
the movable body includes a main section which is placed along at least a part of an outer periphery section of the object, and a support section which supports the object.

5. The movable body apparatus according to claim 4 wherein in the main section, an opening is formed which allows the object to pass in a direction along the two-dimensional plane when the surface of the first member is set to the first state.

6. The movable body apparatus according to claim 4 wherein
the support section is movable between a support position where the object is supported and a withdrawal position where the support section withdraws from the support position.

7. The movable body apparatus according to claim 1 wherein the first angle and the second angle are angles other than zero degrees.

8. The movable body apparatus according to claim 7 wherein carry-out of the object from above the object support device and carry-in of another object onto the object support device are each performed obliquely from above downward, along one of the first and second movement planes.

9. The movable body apparatus according to claim 7 wherein
the movable body includes a main section which is placed along at least a part of an outer periphery section of the object, and a support section which supports the object.

10. The movable body apparatus according to claim 9 wherein
the object is carried in onto the object support device while being inserted into the main section obliquely from above or below, and is carried out obliquely upward or downward from inside the main section on the object support device.

11. The movable body apparatus according to claim 9 wherein
the support section is movable between a support position where the object is supported and a withdrawal position where the support section withdraws from the support position.

12. The movable body apparatus according to claim 1 wherein
the first carrier system performs one of a carry-out of the object and a carry-in of the another object using a first drive device which drives the object between an area over the first member and the area over the first support device, and
the second carrier system performs one of a carry-out of the object and a carry-in of the another object using a second drive device which drives the object between an area over the first member and the area over the second support device.

13. The movable body apparatus according to claim 1 wherein
concurrently with the carry-out operation of the object by one of the first and second carrier systems, the carry-in operation of the another object by the other of the first and second carrier systems begins.

14. The movable body apparatus according to claim 1 wherein
the first member, the first support device, and the second support device support the object in a non-contact manner.

15. The movable body apparatus according to claim 1 wherein
at least one of the first and second support device is movable in a direction parallel to the two-dimensional plane with respect to the object support device.

16. The movable body apparatus according to claim 1 wherein
the carry-in operation of the object onto the object support device and the carry-out operation of the object from over the object support device are performed at least partially concurrently.

17. The movable body apparatus according to claim 1 wherein
in at least one of the time of the carry-in operation of the object onto the object support device and the time of the carry-out operation of the object from over the object support device, the movable body and at least a part of the object support device moves relatively.

18. The movable body apparatus according to claim 1, the apparatus further comprising:
an adjustment device which is placed within the predetermined range, and adjusts a position of a part of the object in a direction intersecting the two dimensional plane while holding a part of the object.

19. The movable body apparatus according to claim 18 wherein
the adjustment device holds the object in a non-contact manner by blowing out gas to the lower surface of the object, and suctioning a gas between an opposing surface to the object and a lower surface of the object.

20. The exposure apparatus, comprising:
the movable body apparatus according to claim 18; and
a patterning device which irradiates an energy beam on a part of the object held by the adjustment device and forms a predetermined pattern on the object.

21. The exposure apparatus according to claim 20 wherein
the object is a substrate used to manufacture a flat panel display.

22. The exposure apparatus according to claim 21 wherein
a length of at least one side of the substrate is larger than 500 mm.

23. A flat-panel display manufacturing method, comprising: exposing the substrate using the exposure apparatus according to claim 21,
developing the substrate that has been exposed.

24. A device manufacturing method, comprising:
exposing the object using the exposure apparatus according to claim 20; and
developing the object that has been exposed.

25. A movable body apparatus, comprising:
a movable body which holds an edge of an object, and is movable with the object at least in a predetermined range within a predetermined two-dimensional plane parallel to a horizontal plane;
an object support device which has a first member whose surface is parallel to the two-dimensional plane, and supports the object moving with the movable body in the predetermined range from below;
a first support device and a second support device that have a surface parallel to the two-dimensional plane and can support the object, respectively, and at least one of the first movable device and the second movable device is relatively movable with respect to the first member in a direction intersecting the two-dimensional plane; and
a carrier system including a first carrier system which moves the object along a first movement plane including the surface of the first member and the surface of the first support device, and a second carrier system which moves the object along a second movement plane including the surface of the first member and the surface of the second support device, wherein
the object is carried out from above the object support device by one of the first and second carrier systems, and another object is carried in onto the object support device by the other of the first and second carrier systems.

26. The movable body apparatus according to claim 25 wherein
the surface of the first member is movable between a first position and a second position different from the first position in a direction intersecting the two-dimensional plane.

27. The movable body apparatus according to claim 26 wherein
the first movement plane is formed including the surface of the first support device and the surface of the first member at the first position.

28. The movable body apparatus according to claim 27 wherein
the movable body is movable between an area over the first member and an area over the first support device, and
the first carrier system performs one of a carry-out of the object from over the first member onto the first support device and a carry-in of the object from above the first support device onto the first member, using the movable body.

29. The movable body apparatus according to claim 26 wherein
the second movement plane is formed including the surface of the second support device and the surface of the first member at the first position.

30. The movable body apparatus according to claim 26 wherein
the second movement plane is formed including the surface of the second support device and the surface of the first member at the second position.

31. The movable body apparatus according to claim 25 wherein
the first and second movement planes are on a different plane.

32. The movable body apparatus according to claim 31 wherein
the first and the second support devices are movable in a direction intersecting the two-dimensional plane with respect to the object support device.

33. The movable body apparatus according to claim 25 wherein
the first carrier system performs one of a carry-in and a carry-out of the object using a first drive device which drives the object between an area over the first member and an area over the first support device, and
the second carrier system performs one of a carry-in and a carry-out of the object using a second drive device which drives the object between the area over the first member and the area over the second support device.

34. The movable body apparatus according to claim 25 wherein
the carry-out operation of the object by one of the first and second carrier systems is performed at least partially concurrently with the carry-in operation of the another object by the other of the first and second carrier systems.

35. The movable body apparatus according to claim 25 wherein
the first and second movement planes are coplanar.

36. The movable body apparatus according to claim 35 wherein the carry-out operation and the carry-in operation of the object are performed in a state where the first member is located adjacent to both of the first and second support devices.

37. The movable body apparatus according to claim 25 wherein
the first member, the first support device, and the second support device, support the object in a non-contact manner.

38. The movable body apparatus according to claim 25 wherein
the movable body includes a main section which is placed along at least a part of an outer periphery section of the object, and a support section which supports the object.

39. The movable body apparatus according to claim 38 wherein
in the main section, an opening is formed which allows the object to pass in a direction along at least one of the first and second movement planes.

40. The movable body apparatus according to claim 38 wherein
the support section is movable between a support position where the object is supported and a withdrawal position where the support section withdraws from the support position.

41. The movable body apparatus according to claim 25 wherein
the movable body includes a main section which is placed along at least a part of an outer periphery section of the object, and a support section which supports the object, and
in the movable body, an opening is formed which allows the first member to pass in a direction intersecting the two-dimensional plane.

42. The movable body apparatus according to claim 41 wherein
the support section is movable between a support position where the object is supported and a withdrawal position where the support section withdraws from the support position.

43. The movable body apparatus according to claim 25, the apparatus further comprising:
an adjustment device which is placed within the predetermined range, and adjusts a position in a direction intersecting the two-dimensional plane while holding a part of the object.

44. The movable body apparatus according to claim 43 wherein
the adjustment device holds the object in a non-contact manner, by blowing out gas with respect to a lower surface of the object and suctioning gas between an opposing plane with respect to the object and the lower surface of the object.

45. An exposure apparatus, comprising:
the movable body apparatus according to claim 43; and
a patterning device which forms a predetermined pattern on the object by irradiating an energy beam on a part of the object held by the adjustment device of the object.

46. The exposure apparatus according to claim 45 wherein
the object is a substrate used to manufacture a flat panel display.

47. The exposure apparatus according to claim 46 wherein
a length of at least one side of the substrate is larger than 500 mm.

48. A flat-panel display manufacturing method, comprising:
exposing the substrate using the exposure apparatus according to claim 46; and
developing the substrate that has been exposed.

49. A device manufacturing method, comprising:
exposing the object using the exposure apparatus according to claim 45; and
developing the object that has been exposed.

50. A movable body apparatus, comprising:
a movable body which holds an edge of an object, and is movable with the object at least in a predetermined range within a predetermined two-dimensional plane parallel to a horizontal plane;
an object support device which supports the object moving with the movable body in the predetermined range from below;
a first support device which forms a first movement plane at least with a part of the object support device;
a second support device which forms a second movement plane at least with a part of the object support device; and
a carrier system including a first carrier system which moves the object along the first movement plane and a second carrier system which moves the object along the second movement plane, wherein
the object is carried out from above the object support device by one of the first and second carrier systems, and another object is carried in onto the object support device by the other of the first and second carrier systems at least partially concurrently, and
in at least one of the time of the carry-out operation of the object and the time of the carry-in operation of the another object, the movable body and at least a part of the object support device moves relatively.

51. The movable body apparatus according to claim 50, the apparatus further comprising:
an adjustment device which is placed within the predetermined range, and adjusts a position in a direction intersecting the two-dimensional plane while holding a part of the object.

52. The movable body apparatus according to claim 51 wherein
the adjustment device holds the object in a non-contact manner, by blowing out gas with respect to a lower surface of the object and suctioning gas between an opposing plane with respect to the object and the lower surface of the object.

53. An exposure apparatus, comprising:
the movable body apparatus according to claim 51; and
a patterning device which forms a predetermined pattern on the object by irradiating an energy beam on a part of the object held by the adjustment device of the object.

54. The exposure apparatus according to claim 53 wherein
the object is a substrate used to manufacture a flat panel display.

55. The exposure apparatus according to claim 54 wherein a length of at least one side of the substrate is larger than 500 mm.

56. A flat-panel display manufacturing method, comprising:
exposing the substrate using the exposure apparatus according to claim 54; and
developing the substrate that has been exposed.

57. A device manufacturing method, comprising:
exposing the object using the exposure apparatus according to claim 53; and
developing the object that has been exposed.

58. A movable body apparatus, comprising:
a movable body which holds an edge of an object, and is movable with the object at least in a predetermined range within a predetermined two-dimensional plane parallel to a horizontal plane;
an object support device which has a surface opposing a lower surface of the object, and supports the object using the surface while moving with the movable body in the predetermined range from below;
a first support device which can support the object from below, having a surface that forms a first movement plane parallel to the two-dimensional plane along with the surface of the object support device;
a second support device which can support the object from below, having a surface that forms a second movement plane parallel to the two-dimensional plane along with the surface of the object support device; and
a carrier system including a first carrier system which moves the object along the first movement plane, and a second carrier system which moves the object along the second movement plane, wherein
the object is carried out from above the object support device by one of the first and second carrier systems, and another object is carried in onto the object support device by the other of the first and second carrier systems.

59. The movable body apparatus according to claim 58 wherein the movable body is movable between an area over the surface of the object support device and an area over the first support device, and
the first carrier system performs one of a carry-out the object from over the surface of the object support device onto the first support device and a carry-in of the another object from above the first support device onto the surface of the object support device, using the movable body.

60. The movable body apparatus according to claim 58 wherein
the first carrier system performs one of the carry-out of the object and the carry-in of the another object using a first drive device which drives the object between an area over the surface of the object support device and the area over the first support device, and
the second carrier system performs one of the carry-out of the object and the carry-in of the another object using a second drive device which drives the object between an area over the surface of the object support device and the area over the second support device.

61. The movable body apparatus according to claim 58 wherein
the carry-out operation of the object by one of the first and second carrier systems is performed with the carry-in operation of the another object by the other of the first and second carrier systems at least partially concurrently.

62. The movable body apparatus according to claim 58 wherein
the first and second movement planes are coplanar.

63. The movable body apparatus according to claim 62 wherein
the first and second support devices are movable in a direction parallel to the two-dimensional plane with respect to the object support device.

64. The movable body apparatus according to claim 58, the apparatus further comprising:
an adjustment device which is placed within the predetermined range, and adjusts a position in a direction intersecting the two-dimensional plane while holding a part of the object.

65. The movable body apparatus according to claim 64 wherein
the adjustment device holds the object in a non-contact manner, by blowing out gas with respect to a lower surface of the object and suctioning gas between an opposing plane with respect to the object and the lower surface of the object.

66. An exposure apparatus, comprising:
the movable body apparatus according to claim 64; and
a patterning device which forms a predetermined pattern on the object by irradiating an energy beam on a part of the object held by the adjustment device of the object.

67. The exposure apparatus according to claim 66 wherein
the object is a substrate used to manufacture a flat panel display.

68. The exposure apparatus according to claim 67 wherein
a length of at least one side of the substrate is larger than 500 mm.

69. A flat-panel display manufacturing method, comprising:
exposing the substrate using the exposure apparatus according to claim 68; and
developing the substrate that has been exposed.

70. A device manufacturing method, comprising:
exposing an object using the exposure apparatus according to claim 66; and
developing the object that has been exposed.

71. An exposure apparatus that exposes an object by irradiating an energy beam, the apparatus comprising:
a movable body which holds an edge of the object, and is movable with the object at least in a predetermined range within a predetermined two-dimensional plane parallel to a horizontal plane;
an object support device which has a first member having a surface whose tilt angle with respect to the two-dimensional plane is changeable in at least two steps including zero degrees, and supports the object moving with the movable body in the predetermined range from below;
a first support device which has a surface forming a first movement plane that forms a first angle with respect to the two dimensional plane together with the surface of the first member in a first state where the surface forms the first angle with respect to the two-dimensional plane, and can support the object from below;
a second support device which has a surface forming a second movement plane that forms a second angle with respect to the two dimensional plane together with the surface of the first member in a second state where the surface forms the second angle with respect to the two-dimensional plane, and can support the object from below;
a carrier system including a first carrier system which moves the object along the first movement plane and a second carrier system which moves the object along the second movement plane; and
a patterning device which forms a predetermined pattern by irradiating an energy beam on the object, wherein
the object is carried out from above the object support device by one of the first and second carrier systems, and another object is carried in onto the object support device by the other of the first and second carrier systems.

72. The exposure apparatus according to claim 71, the apparatus further comprising:
an adjustment device which is placed within the predetermined range, and adjusts a position of a part of the object in a direction intersecting the two-dimensional plane while holding the part of the object on which the energy beam is irradiated.

73. The exposure apparatus according to claim 72 wherein
the adjustment device holds the object in a non-contact manner, by blowing out gas with respect to a lower surface of the object and suctioning gas between an opposing plane with respect to the object and the lower surface of the object.

74. A device manufacturing method, comprising:
exposing the object using the exposure apparatus according to claim 71; and
developing the object that has been exposed.

75. An exposure apparatus that exposes an object by irradiating an energy beam, the apparatus comprising:
a movable body which holds an edge of the object, and is movable with the object at least in a predetermined range within a predetermined two-dimensional plane parallel to a horizontal plane;
an object support device which has a first member whose surface is parallel to the two-dimensional plane, and supports the object moving with the movable body in the predetermined range from below;
a first support device and a second support device that have a surface parallel to the two-dimensional plane and can support the object, respectively, and at least one of the first movable device and the second movable device is relatively movable with respect to the first member in a direction intersecting the two-dimensional plane; and
a carrier system including a first carrier system which moves the object along a first movement plane including the surface of the first member and the surface of the first support device, and a second carrier system which moves the object along a second movement plane including the surface of the first member and the surface of the second support device, and
a patterning device which forms a predetermined pattern by irradiating an energy beam on the object, wherein
the object is carried out from above the object support device by one of the first and second carrier systems, and another object is carried in onto the object support device by the other of the first and second carrier systems.

76. The exposure apparatus according to claim 75, the apparatus further comprising:
an adjustment device which is placed within the predetermined range, and adjusts a position of a part of the object in a direction intersecting the two-dimensional plane while holding the part of the object on which the energy beam is irradiated.

77. The exposure apparatus according to claim 76 wherein
the adjustment device holds the object in a non-contact manner, by blowing out gas with respect to a lower surface of the object and suctioning gas between an opposing plane with respect to the object and the lower surface of the object.

78. A device manufacturing method, comprising:
exposing the object using the exposure apparatus according to claim 75; and
developing the object that has been exposed.

79. An exposure apparatus that exposes an object by irradiating an energy beam, the apparatus comprising:
a movable body which holds an edge of the object, and is movable with the object at least in a predetermined range within a predetermined two-dimensional plane parallel to a horizontal plane;
an object support device which supports the object moving with the movable body in the predetermined range from below;
a first support device which forms a first movement plane with at least a part of the object support device;
a second support device which forms a second movement plane with at least a part of the object support device;
a carrier system including a first carrier system which moves the object along the first movement plane and a second carrier system which moves the object along the second movement plane; and
a patterning device which forms a predetermined pattern by irradiating an energy beam on the object, wherein
the object is carried out from above the object support device by one of the first and second carrier systems, and with the carry-out of the object, another object is carried in onto the object support device by the other of the first and second carrier systems at least partially concurrently, and
in at least one of the time of the carry-out operation of the object and the time of the carry-in operation of the another object, the movable body and at least a part of the object support device moves relatively.

80. The exposure apparatus according to claim 79, the apparatus further comprising:
an adjustment device which is placed within the predetermined range, and adjusts a position of a part of the object in a direction intersecting the two-dimensional plane while holding the part of the object on which the energy beam is irradiated.

81. The exposure apparatus according to claim 80 wherein
the adjustment device holds the object in a non-contact manner, by blowing out gas with respect to a lower surface of the object and suctioning gas between an opposing plane with respect to the object and the lower surface of the object.

82. A device manufacturing method, comprising:
exposing the object using the exposure apparatus according to claim 79; and
developing the object that has been exposed.

83. An exposure apparatus that exposes an object by irradiating an energy beam, the apparatus comprising:
a movable body which holds an edge of the object, and is movable with the object at least in a predetermined range within a predetermined two-dimensional plane parallel to a horizontal plane;
an object support device which has a surface opposing a lower surface of the object, and supports the object using the surface while moving with the movable body in the predetermined range from below;
a first support device which can support the object from below, having a surface that forms a first movement plane parallel to the two-dimensional plane along with the surface of the object support device;
a second support device which can support the object from below, having a surface that forms a second movement plane parallel to the two-dimensional plane along with the surface of the object support device; and
a carrier system including a first carrier system which moves the object along the first movement plane and a second carrier system which moves the object along the second movement plane; and
a patterning device which forms a predetermined pattern by irradiating an energy beam on the object, wherein
the object is carried out from above the object support device by one of the first and second carrier systems, and another object is carried in onto the object support device by the other of the first and second carrier systems.

84. The exposure apparatus according to claim 83, the apparatus further comprising:
an adjustment device which is placed within the predetermined range, and adjusts a position of a part of the object in a direction intersecting the two-dimensional plane while holding the part of the object on which the energy beam is irradiated.

85. The exposure apparatus according to claim 84 wherein
the adjustment device holds the object in a non-contact manner, by blowing out gas with respect to a lower surface of the object and suctioning gas between an opposing plane with respect to the object and the lower surface of the object.

86. A device manufacturing method, comprising:
exposing the object using the exposure apparatus according to claim 83; and
developing the object that has been exposed.

87. An object exchange method, comprising:
making a movable body which is movable along a predetermined two-dimensional plane parallel to a horizontal plane hold an edge of an object supported from below by an object support device;
making the object be located above a first member that the object support device has, using the movable body;
setting the first member to a first state in which a surface of the first member forms a first angle with respect to the two-dimensional plane;
carrying out the object from above the object support device along a first movement plane which forms the first angle with respect to the two-dimensional plane including the surface of the first member set to the first state;
setting the first member to a second state in which the surface forms a second angle with respect to the two-dimensional plane; and
carrying in another object onto the object support device along a second movement plane which forms the second angle with respect to the two-dimensional plane including the surface of the first member set to the second state.

88. The object exchange method according to claim 87 wherein one of the first and second angles is zero degrees.

89. The object exchange method according to claim 88, the method further comprising:
restoring an attitude of the first member to the first state where the surface becomes parallel to the two-dimensional plane, after a carry-in of the object when the second angle is an angle besides zero degrees.

90. The object exchange method according to claim 87 wherein the first and second angles are angles besides zero degrees.

91. The object exchange method according to claim 87 wherein
carrying out the object from above the object support device and carrying in the another object onto the object support device are partially performed concurrently.

92. An object exchange method, comprising:
making a movable body which is movable along a predetermined two-dimensional plane parallel to a horizontal plane, hold an edge of an object supported from below by an object support device that has a first member whose surface is parallel to the two-dimensional plane and is movable in an intersecting direction with the two-dimensional plane;
making the object be located above the first member which is at a first position using the movable body;
carrying out the object from above the object support device along a horizontal plane including the surface of the first member located at one of the first position and a second position distanced apart in the intersecting direction with the first position; and
carrying in another object onto the object support device along a horizontal plane including the surface of the first member located at a third position located distanced apart in the intersecting direction with the first position.

93. The object exchange method according to claim 92 wherein
the carrying out and the carrying in are performed at least partially concurrently.

94. An object exchange method, comprising:
making a movable body which is movable along a predetermined two-dimensional plane parallel to a horizontal plane, hold an edge of an object supported from below by an object support device that has a first member whose surface is parallel to the two-dimensional plane and is movable in an intersecting direction with the two-dimensional plane;
making the object be located above the first member which is at a first position using the movable body;
carrying out the object from above the object support device along a horizontal plane including the surface of the first member located at a second position distanced apart in the intersecting direction with the first position; and
carrying in another object onto the object support device along a horizontal plane including the surface of the first member located at one of the first position and a third position located distanced apart in the intersecting direction with the first position.

95. The object exchange method according to claim 94 wherein
the carrying out and the carrying in are performed at least partially concurrently.

96. An object exchange method, comprising:
making a movable body which is movable along a predetermined two-dimensional plane parallel to a horizontal plane, hold an edge of an object supported from below by an object support device that has a surface opposing a lower surface of the object and is parallel to the horizontal plane;
making the object move along the surface of the object support device using the movable body;
carrying out the object from above the object support device by making the object move on a first path which is along the surface of the object support device; and
carrying in another object onto the object support device by making the another object move on a second path which is different from the first path along the surface of the object support device.

97. The object exchange method according to claim 96 wherein
the carrying out and the carrying in are performed at least partially concurrently.

98. An object exchange method, comprising:
making a movable body which is movable along a predetermined two-dimensional plane parallel to a horizontal plane hold an edge of an object supported from below by an object support device that has a surface opposable to a lower surface of the object and is parallel to the horizontal plane;
making the object be located on the surface of the object support device using the movable body; positioning a surface of a first support member that can support the object from below on a horizontal plane including the surface of the object support device;
carrying out the object from above the object support device onto the first support device along a horizontal plane including the surface of the object support device and the surface of the first support device;
positioning a surface of a second support member that supports another object from below on a horizontal plane including the surface of the object support device; and
carrying in the another object from above the second support device onto the object support device along a horizontal plane including the surface of the second support device and the surface of the object support device.

99. The object exchange method according to claim 98 wherein
the carrying out and the carrying in are performed at least partially concurrently.
